(19) United States
(12) Patent Application Publication
(10) Pub. No.: US 2009/0167156 A1
(43) Pub. Date: Jul. 2, 2009

(54) ORGANIC ELECTROLUMINESCENCE DEVICE

(75) Inventors: Hisayuki Kawamura, Sodegaura-shi (JP); Hitoshi Kuma, Sodegaura-shi (JP); Tetsuya Inoue, Sodegaura-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Idemitsu Kosan Co., Ltd., Chiyoda-ku (JP)

(21) Appl. No.: 12/037,511

(22) Filed: Feb. 26, 2008

(30) Foreign Application Priority Data
Feb. 28, 2007 (JP) 2007-050857

(51) Int. Cl. H01J 1/62

(52) U.S. Cl. 313/504

(57) ABSTRACT

In an organic electroluminescence device including a hole injecting layer, an emitting layer, an electron transporting layer and a cathode, the hole injecting layer contains poly(alkylene dioxythiophene) and at least one type of fluorine-containing colloid-forming polymer acids. The electron transporting layer contains a nitrogen-containing heterocycle derivative represented by a formula (1) below.

HAr-L-Ar¹—Ar² (1)

(In the formula: HAr represents a substituted or unsubstituted nitrogen-containing heterocycle group having 3 to 40 carbon atoms; L represents, a single bond, a substituted or unsubstituted arylene group having 6 to 60 carbon atoms, a substituted or unsubstituted heteroarylene group having 3 to 60 carbon atoms, or a substituted or unsubstituted fluorenylene group; Ar¹ represents a substituted or unsubstituted divalent aromatic hydrocarbon group having 6 to 60 carbon atoms; and Ar² represents a substituted or unsubstituted aryl group having 3 to 60 carbon atoms.)

### BACKGROUND OF THE INVENTION

1. Field of the Invention

The present invention relates to an organic electroluminescence device.

2. Description of Related Art

Such an organic electroluminescence as described below has been conventionally known.

An organic electroluminescence device is a self-emitting device that is based on a principle according to which a fluorescent material emits lights by recombination energy caused by holes injected from an anode and electrons injected from cathode.

An organic electroluminescence device is provided by laminating functional layers such as a hole injecting layer, a hole transporting layer, an emitting layer, an electron transporting layer and an electron injecting layer. The emitting layer contains a host material and a dopant material, where an energy transmission or the like is generated from the host material to the dopant material, so that the dopant material shows a light-emitting function.

As a host material for providing an organic electroluminescence device that is excellent in lifetime, luminous efficiency and the like, an anthracene derivative is known.

According to an exemplary known arrangement of an organic electroluminescence device having a long lifetime and high luminous efficiency, a copper phthalocyanine-based compound is used as the hole injecting layer, an anthracene derivative is used as a host material for the emitting layer and aluminum (Alq) complex is used as the electron transporting layer.

However, such a device arrangement has required a high drive voltage.

Meanwhile, as a hole injecting layer material that is excellent in transporting holes and expected to decrease the drive voltage of the entire organic electroluminescence device, a composition containing polyethylenedioxythiophene (PEDOT) and polystyrene sulfonate (PSS) has been known (e.g., Document 1: JP-A-2000-91081).

In recent years, there has been an attempt to prolong the lifetime of an organic electroluminescence device by using a composition prepared by adding a perfluorinated polymer to PEDOT as the hole injecting layer (e.g., Document 2: JP-A-2003-297582, Document 3: JP-A-2005-232452, Document 4: JP-A-2006-500461, Document 5: JP-T-2006-500463, and Document 6: JP-A-2006-313931).

However, the lifetime of such an organic electroluminescence device has been much shorter than the lifetime of a conventional organic electroluminescence device, i.e., shorter than the inherent lifetime of an anthracene derivative.

Due to such problems as described above, a low voltage-driven organic electroluminescence device having high luminous efficiency and a long lifetime has been yet to be developed, a realization of which has been demanded.

### SUMMARY OF THE INVENTION

An object of the present invention is to solve the above problem(s) and to provide an organic electroluminescence device that has high luminous efficiency and a long lifetime, and that can be driven by a low voltage.

An organic electroluminescence device according to an aspect of the present invention includes an anode, a hole injecting layer, an emitting layer, an electron transporting layer and a cathode in this order, in which the hole injecting layer contains: substituted or unsubstituted poly(alkylene dioxythiophene); and a fluorine-containing colloid-forming polymer acid, and the electron transporting layer contains a compound having electron mobility of 1.0×10⁻⁴ cm²/Vs or more at an electric field intensity of 2.5×10⁵V/cm.

According to the aspect of the present invention, the electron transporting layer contains a nitrogen-containing heterocycle derivative represented by a formula (1) as follows.

HAr-L-Ar¹—Ar² (1)

In the above formula (1), HAr represents a substituted or unsubstituted nitrogen-containing heterocycle group having 3 to 40 carbon atoms.

L represents a single bond, a substituted or unsubstituted arylene group having 6 to 60 carbon atoms, a substituted or unsubstituted heteroarylene group having 3 to 60 carbon atoms, or a substituted or unsubstituted fluorenylene group.

Ar¹ represents a substituted or unsubstituted divalent aromatic hydrocarbon group having 6 to 60 carbon atoms.

Ar² represents a substituted or unsubstituted aryl group having 3 to 60 carbon atoms.

With the above-described arrangement, while exhibiting high luminous efficiency and a long lifetime, the organic electroluminescence device can be driven by a low voltage.

According to a conventionally-known arrangement of an organic electroluminescence device having a long lifetime and high luminous efficiency, a copper phthalocyanine-based compound is used as the hole injecting layer while Alq complex is used as the electron transporting layer. However, a problem of such an arrangement has been that the drive voltage is high.

On the other hand, according to a known arrangement of a low voltage-driven organic electroluminescence device having high luminous efficiency, a copper phthalocyanine-based compound is used as the hole injecting layer while a nitrogen-containing heterocycle derivative is used as the electron transporting layer (e.g., WO2004-080975). However, a problem of such an arrangement has been that the lifetime of the organic electroluminescence device is short.

In addition, according to another known arrangement of a low voltage-driven organic electroluminescence device having high luminous efficiency, a material prepared by adding PSS to PEDOT is used as the hole injecting layer while Alq complex is used as the electron transporting layer. However, a problem of such an arrangement has been that an emitting zone of the emitting layer is shifted toward the cathode, by which the luminous efficiency and the lifetime of the organic electroluminescence device are deteriorated.

In recent years, there has been an attempt to prolong the lifetime of an organic electroluminescence device by using a compound prepared by adding a perfluorinated polymer to PEDOT as the hole injecting layer (see, Documents 3, 4, 5 and 6). However, the lifetime of such an organic electroluminescence device has been much shorter than the expected lifetime of an emitting material used in an organic electroluminescence device.

In other words, a low voltage-driven organic electroluminescence device having high luminous efficiency and a long lifetime has been yet to be developed, and it has been predicted that the drive voltage and the lifetime of an organic electroluminescence device are in a tradeoff relationship.

After various studies, the inventors of the present invention have found that an organic electroluminescence device in which a compound prepared by adding a perfluorinated polymer to substituted or unsubstituted poly(alkylene dioxythiophene) is used as the hole injecting layer while a nitrogen-containing heterocycle derivative is used as the electron transporting layer can be driven by a low voltage while exhibiting high luminous efficiency and a long lifetime.

When substituted or unsubstituted poly(alkylene dioxythiophene) is used as the hole injecting layer, the emitting zone of the emitting layer tends to be shifted toward the cathode due to high hole mobility in the hole injecting layer. In general, the emitting zone is preferably located adjacent to the anode in the emitting layer. It is considered that the luminous efficiency and the lifetime of the organic electroluminescence device are deteriorated when the emitting zone is located adjacent to the cathode therein.

The inventors have found that holes and electrons can be injected in a balanced manner by using a nitrogen-containing heterocycle derivative that exhibits high charge mobility for forming the electron transporting layer, and that the lifetime of an organic electroluminescence can be prolonged while high luminous efficiency and low-voltage drivability obtained by using poly(alkylene dioxythiophene) as the hole injecting layer are retained, and have reached the present invention.

Electron mobility of the electron transporting material is preferably 1.0×10⁻⁴ cm²/Vs, an exemplary upper limit of which is set around 1.0×10⁻².

According to the aspect of the present invention, it is preferable that the emitting layer contains a host and a dopant, and the host is formed of a material having a molecular weight of 4000 or less.

With the above arrangement, not only the combination of the hole transporting layer and the electron transporting layer but also characteristics of the emitting layer can contribute to a longer lifetime and higher luminous efficiency of the organic electroluminescence device. Accordingly, performance of the organic electroluminescence device can be further enhanced.

According to the aspect of the present invention, it is preferable that the host contains a condensed-ring compound having at least three rings.

With the above arrangement, characteristics of the host can contribute to a longer lifetime and higher luminous efficiency of the device, thereby further enhancing performance of the organic electroluminescence device.

According to the aspect of the present invention, it is preferable that the condensed-ring compound having at least three rings is an anthracene derivative.

An anthracene derivative is known as a host material that is excellent in the lifetime, the luminous efficiency and the like. By using an anthracene derivative, the lifetime of the device can be further prolonged while the luminous efficiency of the device can be enhanced, thereby further enhancing performance of the organic electroluminescence device.

According to the aspect of the present invention, it is preferable that the anthracene derivative is represented by a formula (2) as follows.

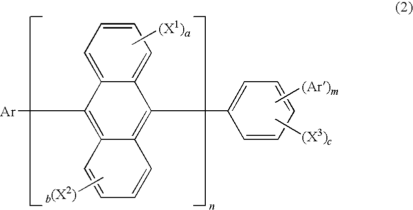

In the above formula (2), Ar represents a substituted or unsubstituted condensed aromatic group having 10 to 50 carbon atoms forming the aromatic ring.

Ar′ represents a substituted or unsubstituted aromatic group having 6 to 50 carbon atoms forming the aromatic ring.

X¹ to X³ each represent a substituted or unsubstituted aromatic group having 6 to 50 carbon atoms forming the aromatic ring, a substituted or unsubstituted aromatic heterocyclic group having 5 to 50 carbon atoms forming the aromatic ring, a substituted or unsubstituted alkyl group having 1 to 50 carbon atoms, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 carbon atoms, a substituted or unsubstituted arylthio group having 5 to 50 carbon atoms, a substituted or unsubstituted alkoxycarbonyl group having 1 to 50 carbon atoms, a carboxyl group, a halogen group, a cyano group, a nitro group and a hydroxyl group.

a, b and c are each an integer in a range of 0 to 4. A plurality of X¹ may be mutually the same or different when a is 2 or more. A plurality of X² may be mutually the same or different when b is 2 or more. A plurality of X³ may be mutually the same or different when c is 2 or more.

n is an integer in a range of 1 to 3 while m is 0 or 1, a plurality of such structures shown in the brackets [ ] as represented by a formula below being mutually the same or different when n is 2 or more.

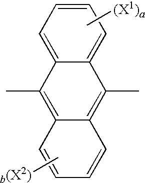

According to the above arrangement, since a compound having an asymmetry specific structure represented by the above formula (2) is used as the host, the luminous efficiency of the organic electroluminescence device can be further enhanced while the lifetime of the device can be further prolonged.

According to the aspect of the present invention, it is preferable that the anthracene derivative is an asymmetric monoanthracene derivative represented by a formula (3) as follows.

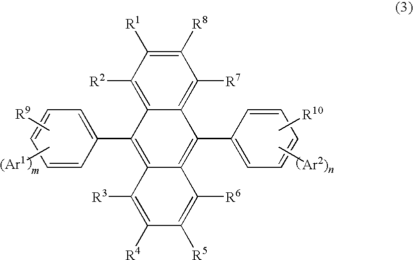

In the above formula (3), Ar¹ and Ar² are each a substituted or unsubstituted aromatic ring group having 6 to 50 carbon atoms forming the aromatic ring while m and n are each an integer in a range of 1 to 4. Ar¹ and Ar² are mutually different when: m and n are both equal to 1; and positions at which Ar¹ and Ar² are respectively bonded to benzene rings are symmetric. m and n are mutually different when m or n is an integer in a range of 2 to 4.

R¹ to R¹⁰ are each a hydrogen atom, a substituted or unsubstituted aromatic ring group having 6 to 50 carbon atoms forming the aromatic ring, a substituted or unsubstituted aromatic heterocycle group having 5 to 50 atoms forming the aromatic ring, a substituted or unsubstituted alkyl group having 1 to 50 carbon atoms, a substituted or unsubstituted cycloalkyl group, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 atoms forming the aromatic ring, a substituted or unsubstituted arylthio group having 5 to 50 atoms forming the aromatic ring, a substituted or unsubstituted alkoxycarbonyl group having 1 to 50 carbon atoms, substituted or unsubstituted silyl group, a carboxyl group, a halogen atom, a cyano group, a nitro group and a hydroxy group.

According to the aspect of the present invention, it is preferable that the anthracene derivative is represented by a formula (4) as follows.

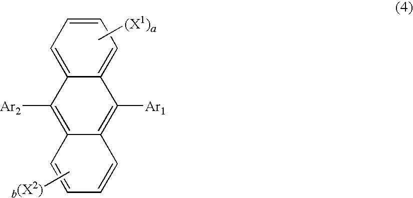

In the above formula (4), at least either one of Ar¹ and Ar² is a substituent having a substituted or unsubstituted condensed ring group with 10 to 30 carbon atoms forming the aromatic ring.

X¹ and X² are each a substituted or unsubstituted aromatic group having 6 to 50 carbon atoms forming the aromatic ring, a substituted or unsubstituted aromatic heterocycle group having 5 to 50 carbon atoms forming the aromatic ring, a substituted or unsubstituted alkyl group having 1 to 50 carbon atoms, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 carbon atoms, a substituted or unsubstituted arylthio group having 5 to 50 carbon atoms, a substituted or unsubstituted alkoxycarbonyl group having 1 to 50 carbon atoms, a carboxyl group, a halogen group, a cyano group, a nitro group and hydroxyl group.

a and b are each an integer in a range of 0 to 4. A plurality of X¹ may be mutually the same or different when a is 2 or more. A plurality of X² may be mutually the same or different when b is 2 or more.

According to the aspect of the present invention, it is preferable that the substituted or unsubstituted poly(alkylene dioxythiophene) is poly(3,4-ethylenedioxythiophene).

According to the aspect of the present invention, it is preferable that the fluorine-containing colloid-forming polymer acid is selected from a group consisting of a fluorine-containing polymer sulfonic acid, a fluorine-containing polymer carboxylic acid, a fluorine-containing polymer phosphoric acid, a fluorine-containing polymer acrylic acid and a mixture of the acids.

By adding such fluorine-containing colloid-forming polymer acid(s) to substituted or unsubstituted poly(alkylene dioxythiophene) in the hole transporting layer, the lifetime of the organic electroluminescence device is expected to be prolonged. With this arrangement, the lifetime of the organic electroluminescence device can be further prolonged.

According to the aspect of the present invention, it is preferable that the fluorine-containing colloid-forming polymer acid is a perfluorinated polymer sulfonic acid.

By adding a perfluorinated polymer to substituted or unsubstituted poly(alkylene dioxythiophene) in the hole transporting layer, the lifetime of the organic electroluminescence device can be prolonged.

### DETAILED DESCRIPTION OF PREFERRED EMBODIMENT(S)

Embodiment(s) of the present invention will be described.

### (Arrangement of Organic Electroluminescence Device)

An arrangement of an organic electroluminescence device will be described below.

### (1) Arrangement of Organic Electroluminescence Device

Typical arrangement of the organic electroluminescence device may be exemplified by the following arrangements:

(a) anode/emitting layer/cathode;
(b) anode/hole injecting layer/emitting layer/cathode;
(c) anode/emitting layer/electron injecting layer/cathode;
(d) anode/hole injecting layer/emitting layer/electron injecting layer/cathode;
(e) anode/organic semiconductor layer/emitting layer/cathode;
(f) anode/organic semiconductor layer/electron blocking layer/emitting layer/cathode;
(g) anode/organic semiconductor layer/emitting layer/adhesion improving layer/cathode;
(h) anode/hole injecting layer/hole transporting layer/emitting layer/electron injecting layer/cathode;
(i) anode/insulating layer/emitting layer/insulating layer/cathode;
(j) anode/inorganic semiconductor layer/insulating layer/emitting layer/insulating layer/cathode;
(k) anode/organic semiconductor layer/insulating layer/emitting layer/insulating layer/cathode;
(l) anode/insulating layer/hole injecting layer/hole transporting layer/emitting layer/insulating layer/cathode; and
(m) anode/insulating layer/hole injecting layer/hole transporting layer/emitting layer/electron injecting layer/cathode.

The organic electroluminescence device according to the present embodiment at least includes an anode, an emitting layer, an electron transporting layer and a cathode in this order.

### (2) Light-Transmissive Substrate

The organic electroluminescence device is formed on a light-transmissive substrate. The light-transmissive plate, which supports the organic electroluminescence device, is preferably a smoothly-shaped substrate that transmits 50% or more of light in a visible region of 400 nm to 700 nm.

The light-transmissive plate is exemplarily a glass plate, a polymer plate or the like.

For the glass plate, such materials as soda-lime glass, barium/strontium-containing glass, lead glass, aluminosilicate glass, borosilicate glass, barium borosilicate glass, quartz and the like can be used.

For the polymer plate, such materials as polycarbonate, acryl, polyethylene terephthalate, polyether sulfide, polysulfone and the like can be used.

### (3) Anode

The anode of the organic electroluminescence device is used for injecting holes into the hole transporting layer or the emitting layer. It is effective that the anode includes a work function of 4.5 eV or more. Exemplary materials for the anode are indium-tin oxide (ITO), tin oxide (NESA), indium zinc oxide (IZO), gold, silver, platinum and copper. In order to inject electrons into the electron transporting layer or the emitting layer, materials having smaller work function is more preferably used for the anode.

The anode may be made by forming a thin film from these electrode materials through methods such as vapor deposition and sputtering.

When light emission from the emitting layer is provided through the anode, the anode preferably transmits more than 10% of the emitted light. Sheet resistance of the anode is preferably several hundreds Ω/square or lower. Although depending on the material of the anode, thickness of the anode is typically in a range from 10 nm to 1 μm, and preferably in a range from 10 to 200 nm.

### (4) Emitting Layer

The emitting layer of the organic electroluminescence device has functions described below.

The emitting layer specifically performs: an injecting function for allowing the holes to be injected thereinto from the anode or the hole injecting layer and allowing the electrons to be injected thereinto from the cathode or the electron injecting layer when electric field is impressed; a transporting function for transporting injected charge (the electrons and the holes) by a force of electric field; and an emitting function for providing conditions for recombination of the electrons and the holes for light emission.

Although injectability of the holes may differ from that of the electrons and transporting capabilities of the hole and the electrons (represented by mobilities of the holes and the electrons) may differ from each other, the emitting layer preferably transports either one of the electric charges.

As a method of forming the emitting layer, known methods such as vapor deposition, spin coating and an LB method may be employed.

The emitting layer is preferably a molecular deposit film.

The molecular deposit film means a thin film formed by depositing a material compound in gas phase or a film formed by solidifying a material compound in a solution state or in liquid phase. The molecular deposit film is generally different from a thin film formed by the LB method (molecular accumulation film) in aggregation structures, higher order structures and functional differences arising therefrom.

As disclosed in JP-A-57-51781, the emitting layer can be formed by preparing a solution by dissolving a binder (e.g. a resin) and the material compound in a solvent and forming a thin film from the solution by spin coating or the like.

The thickness of the emitting layer is preferably in the range from 5 to 50 nm, more preferably in the range from 7 to 50 nm and most preferably in the range 10 to 50 nm. The thickness below 5 nm may cause difficulty in forming the emitting layer and in controlling chromaticity, while the thickness above 50 nm may increase driving voltage.

In the organic electroluminescence device according to the present embodiment, the emitting layer contains a host and a dopant.

The host, which is formed of a material having a molecular weight of 4000 or less, contains a condensed-ring compound having at least three rings. The condensed-ring compound having at least three rings is an anthracene derivative represented by a formula (2) as follows.

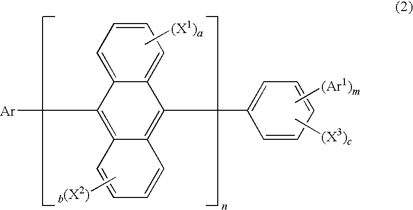

In the above formula (2); Ar represents a substituted or unsubstituted condensed aromatic group having 10 to 50 carbon atoms forming the aromatic ring;

Ar′ represents a substituted or unsubstituted aromatic group having 6 to 50 carbon atoms forming the aromatic ring;

X¹ to X³ each represent a substituted or unsubstituted aromatic group having 6 to 50 carbon atoms forming the aromatic ring, a substituted or unsubstituted aromatic heterocyclic group having 5 to 50 carbon atoms forming the aromatic ring, a substituted or unsubstituted alkyl group having 1 to 50 carbon atoms, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 carbon atoms, a substituted or unsubstituted arylthio group having 5 to 50 carbon atoms, a substituted or unsubstituted alkoxycarbonyl group having 1 to 50 carbon atoms, a carboxyl group, a halogen group, a cyano group, a nitro group and a hydroxyl group;

a, b and c are each an integer in a range of 0 to 4, a plurality of X¹ being mutually the same or different when a is 2 or more, a plurality of X² being mutually the same or different when b is 2 or more, a plurality of X³ being mutually the same or different when c is 2 or more; and

n is an integer in a range of 1 to 3 while m is 0 or 1, a plurality of such structures shown in the brackets [ ] as represented by a formula below being mutually the same or different when n is 2 or more.

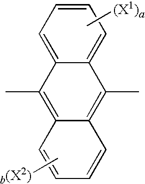

Examples of such an anthracene derivative are as follows.

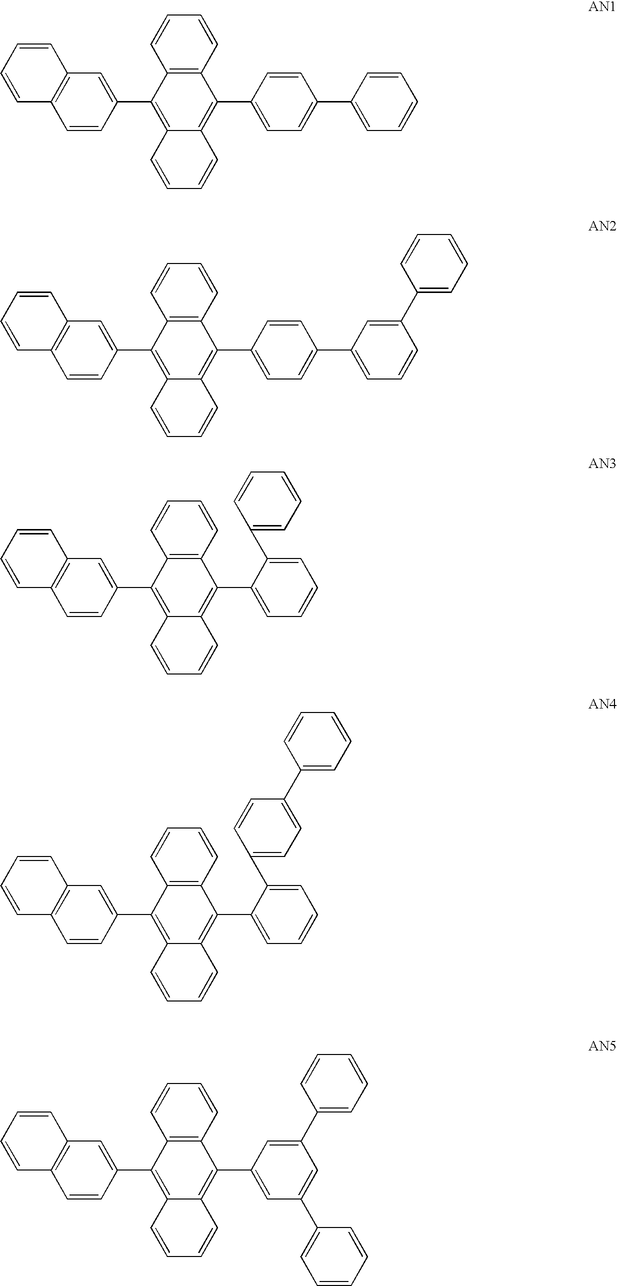

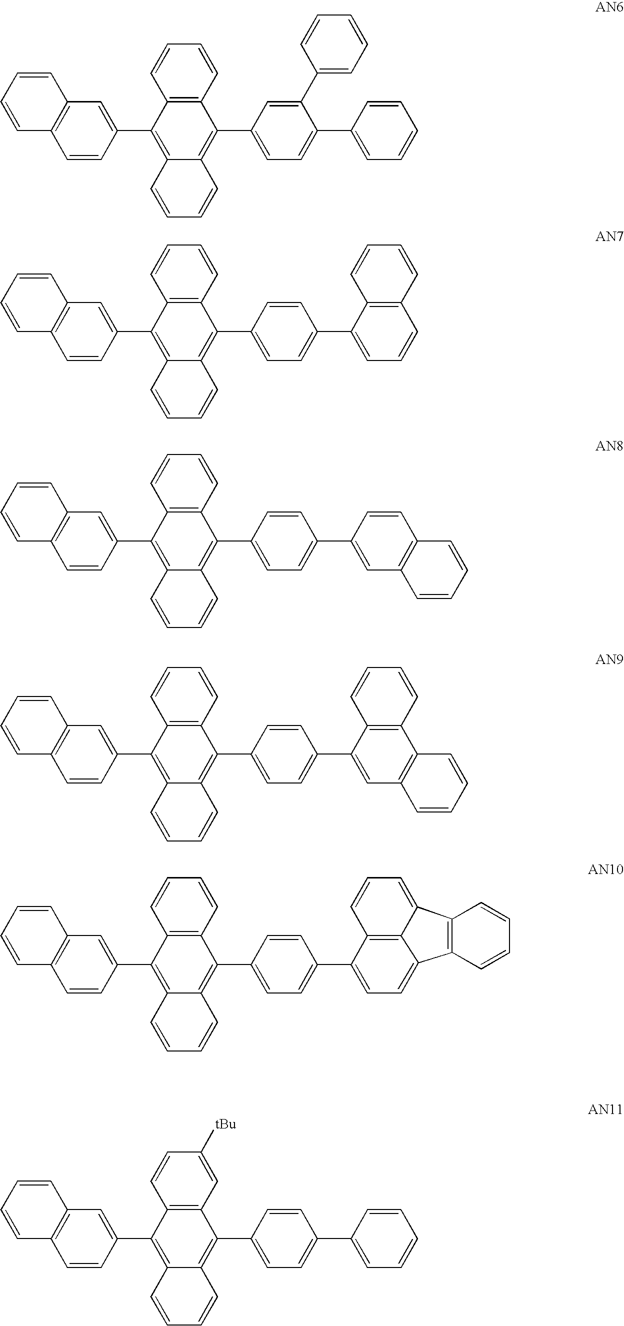

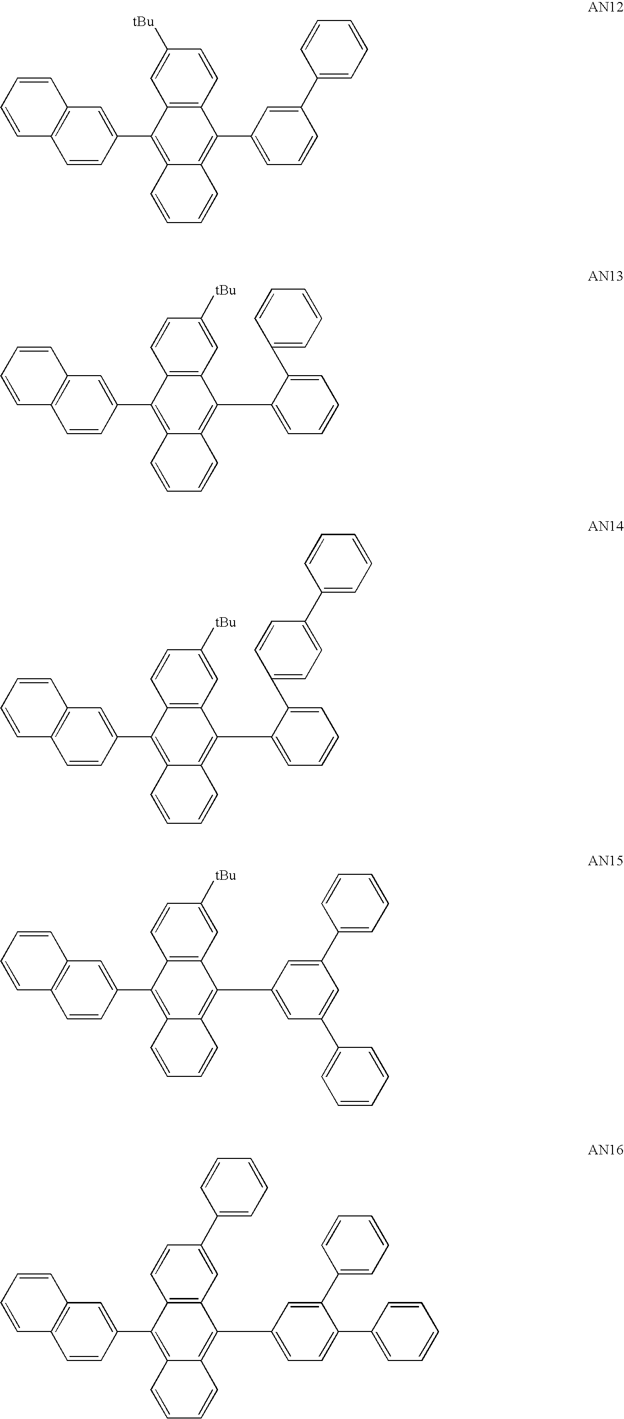

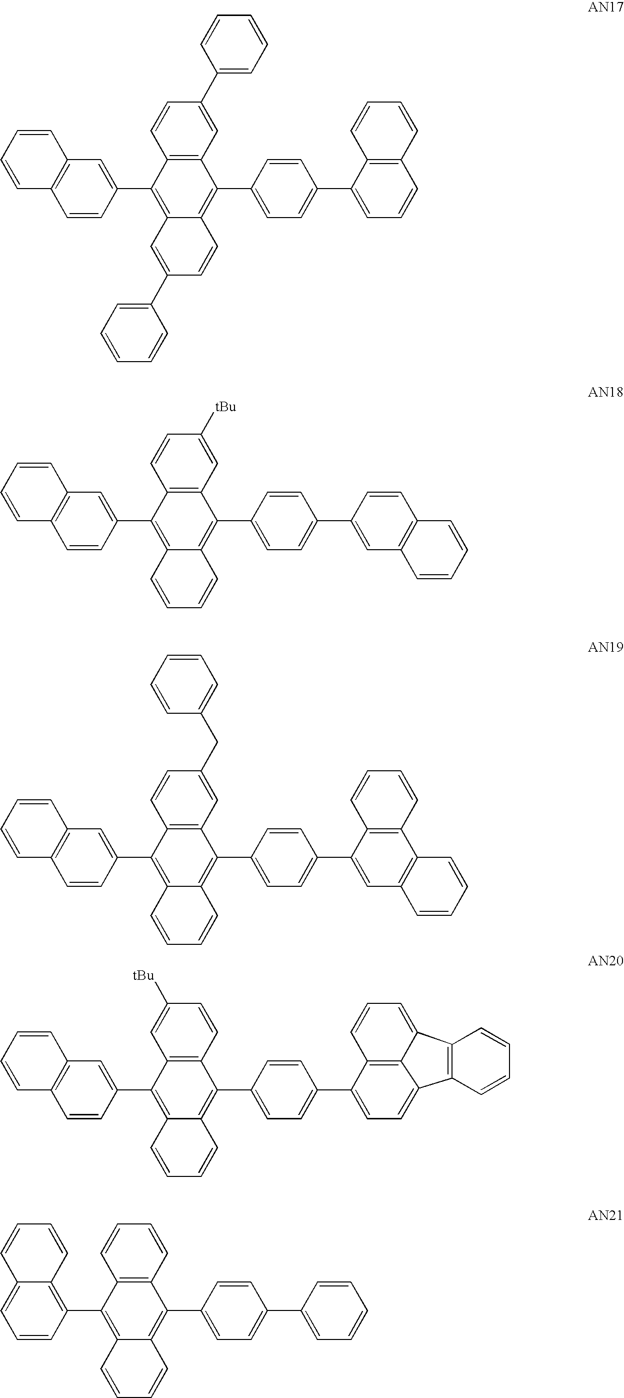

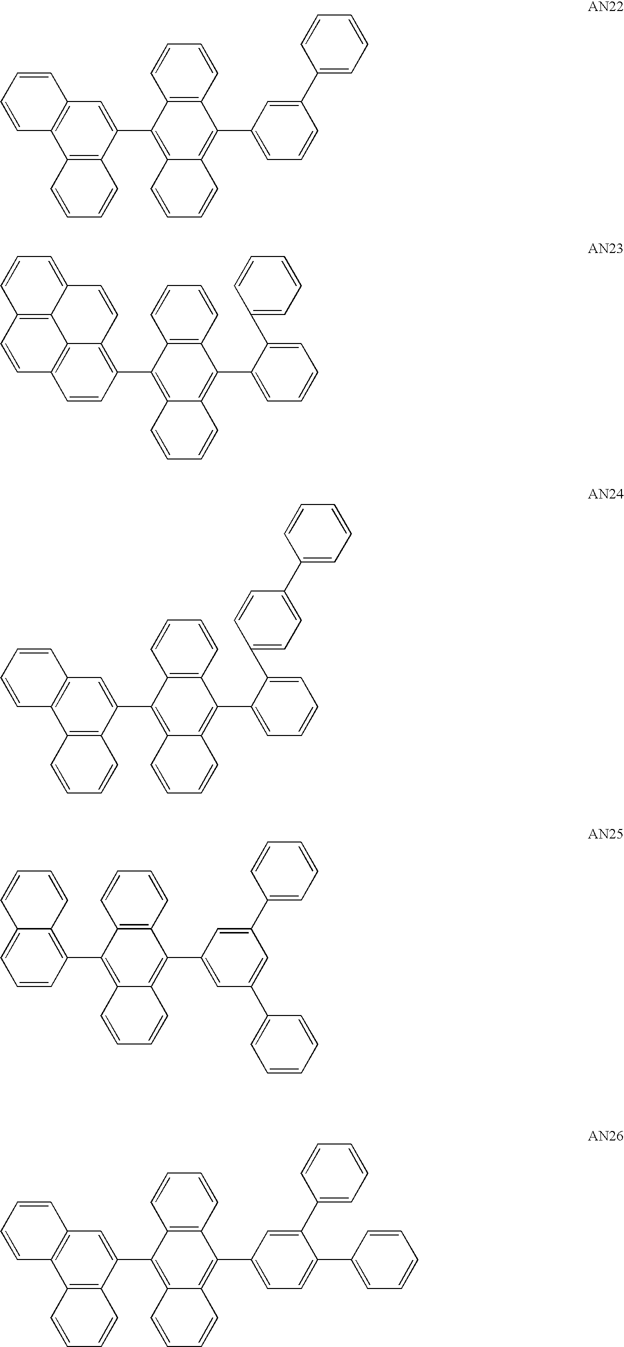

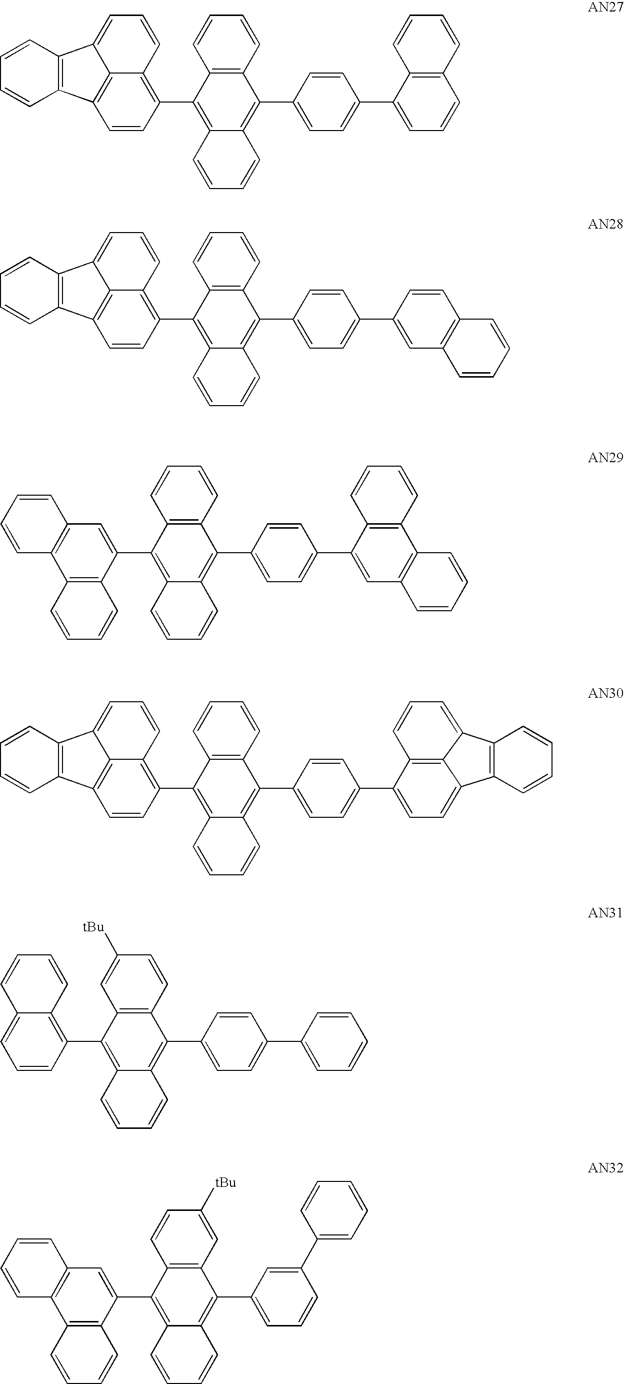

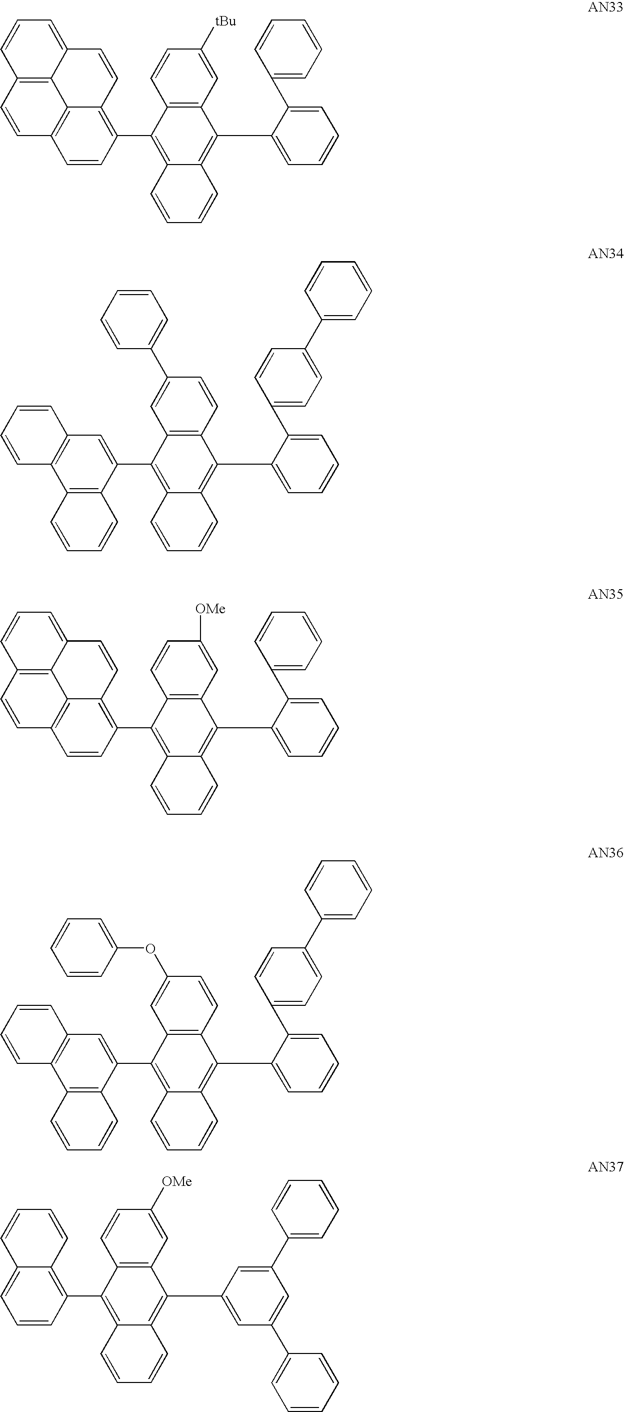

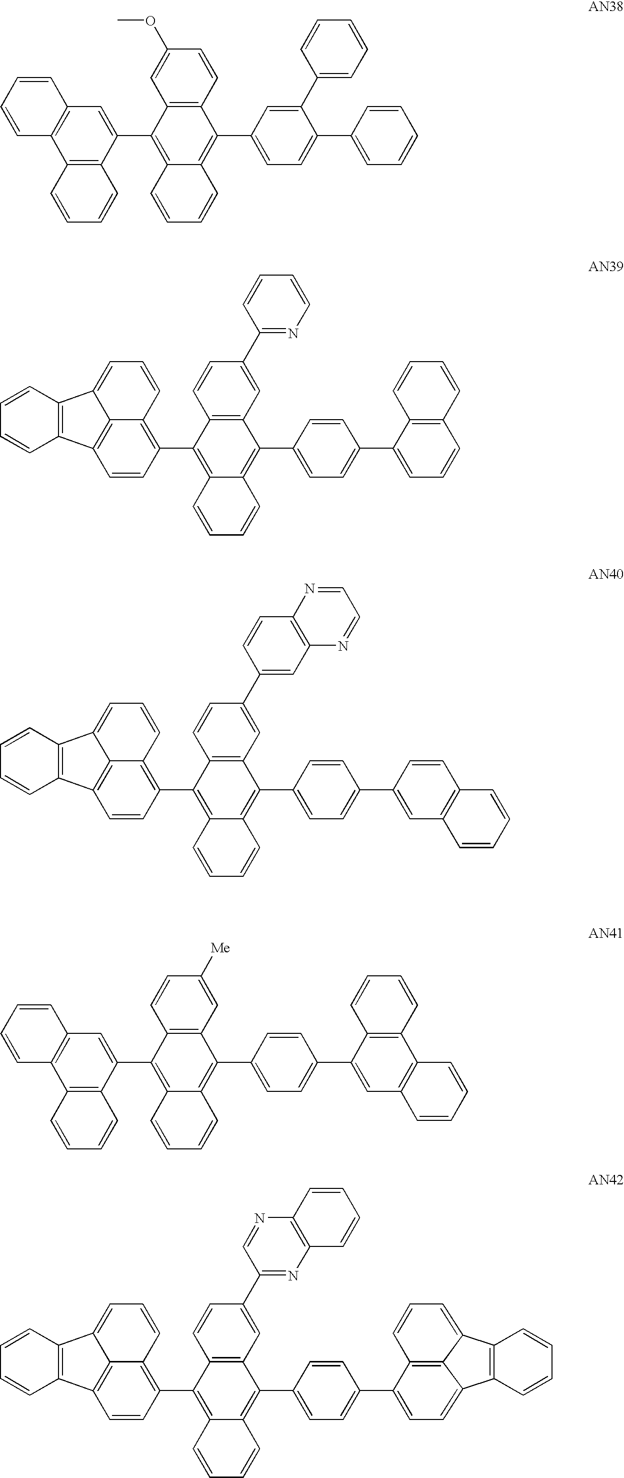

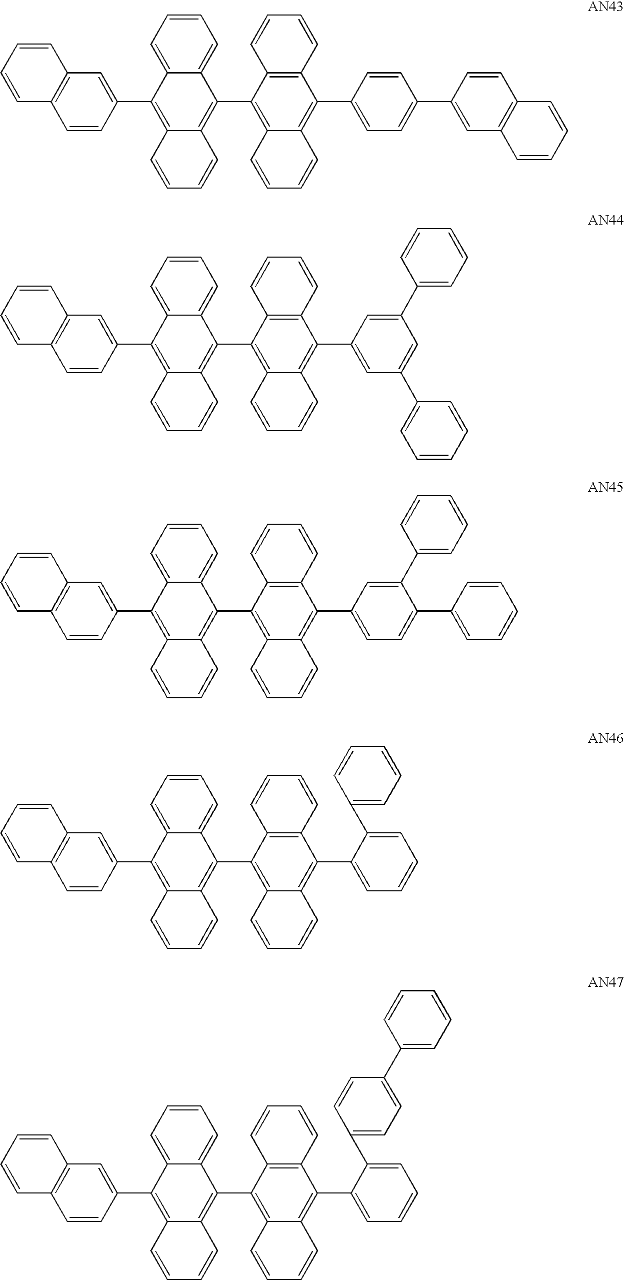

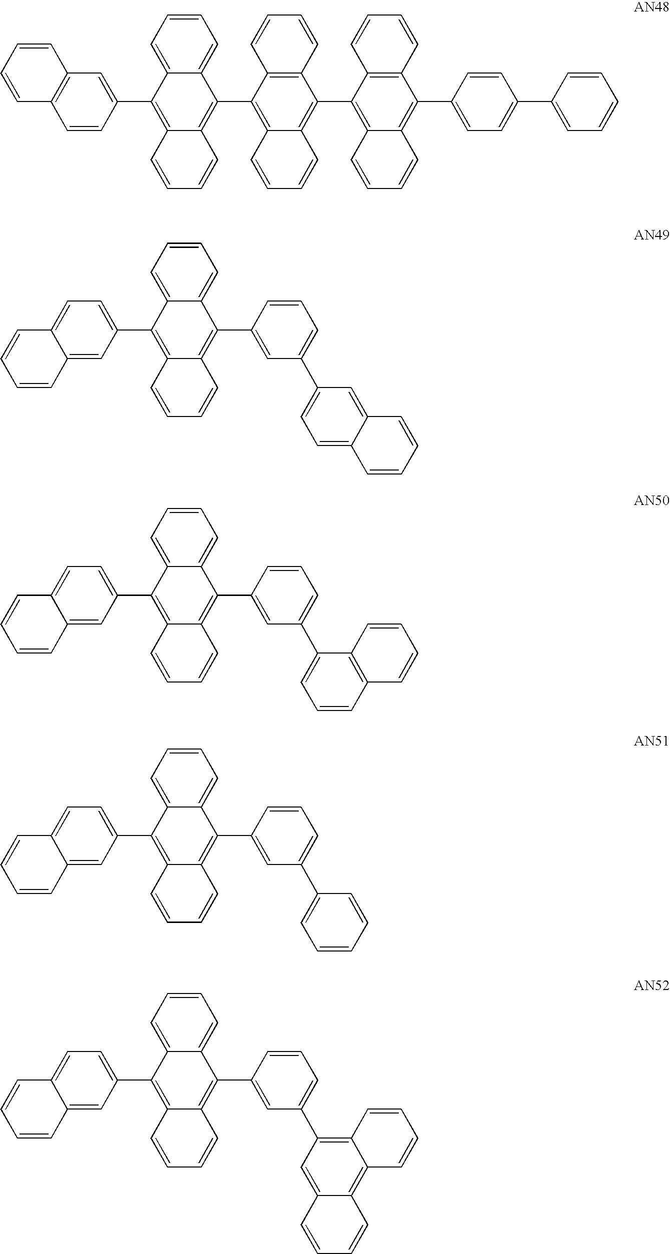

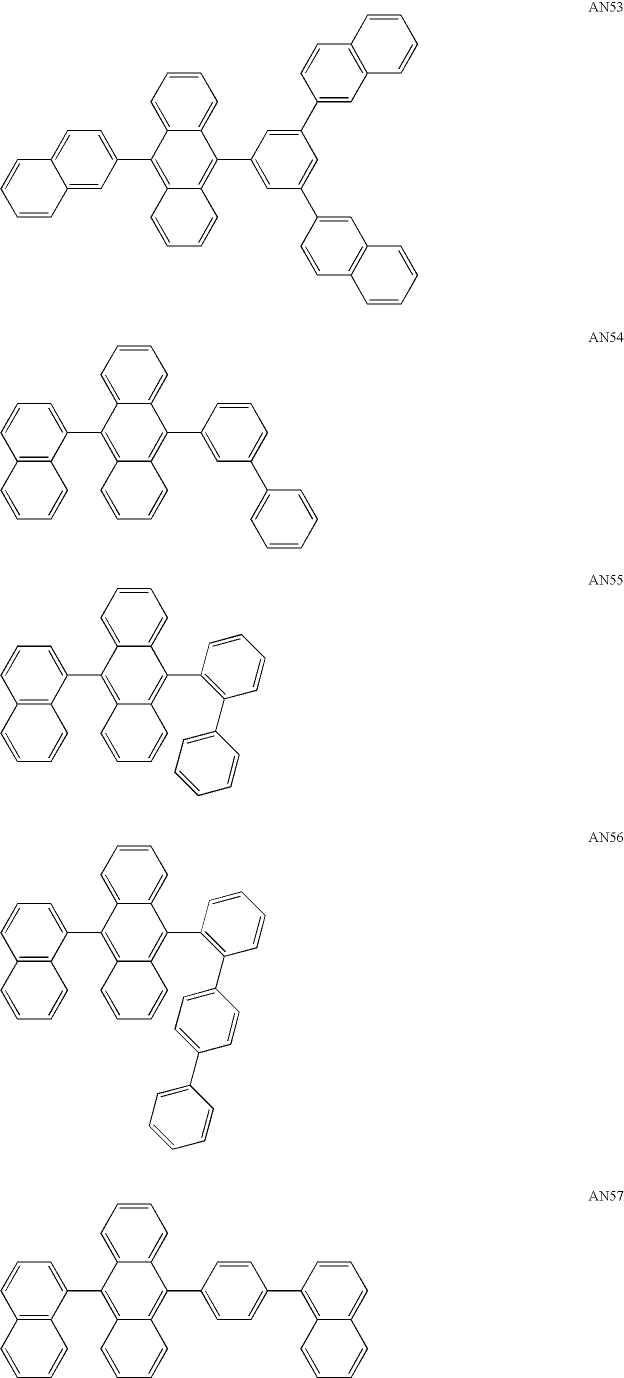

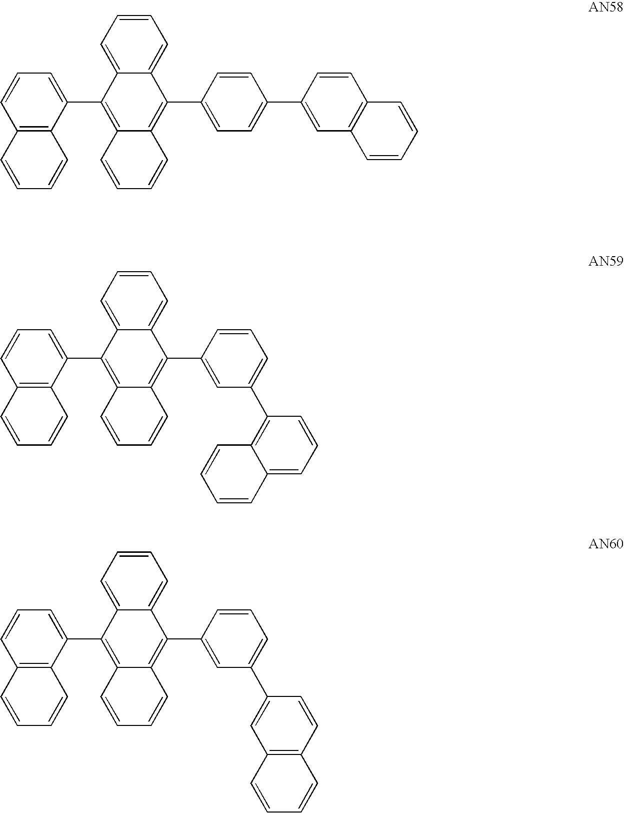

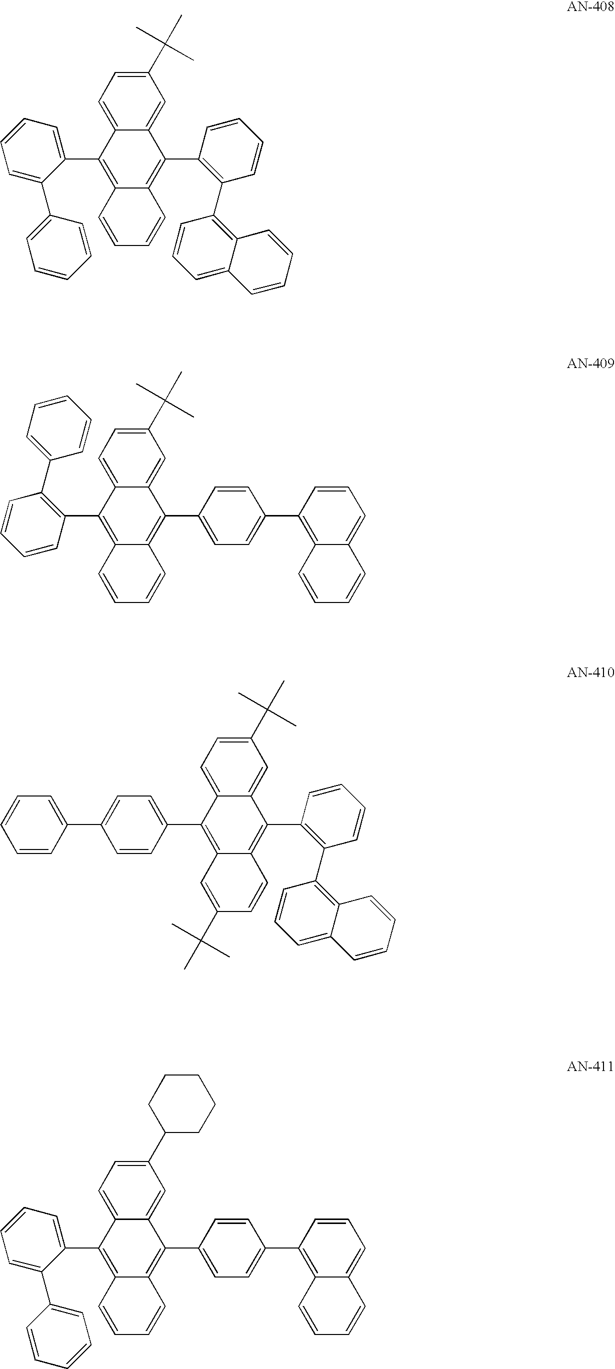

The anthracene derivative may be an asymmetric monoanthracene derivative represented by a formula (3) as follows.

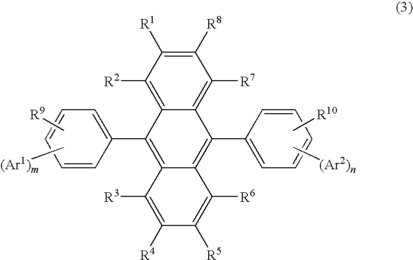

In the above formula (3); Ar¹ and Ar² are each a substituted or unsubstituted aromatic ring group having 6 to 50 carbon atoms forming the aromatic ring while m and n are each an integer in a range of 1 to 4, Ar¹ and Ar² being mutually different when: m and n are both equal to 1; and positions at which Ar¹ and Ar² are respectively bonded to benzene rings are symmetric, m and n being mutually different when m or n is an integer in a range of 2 to 4; and

R¹ to R¹⁰ are each a hydrogen atom, a substituted or unsubstituted aromatic ring group having 6 to 50 carbon atoms forming the aromatic ring, a substituted or unsubstituted aromatic heterocycle group having 5 to 50 atoms forming the aromatic ring, a substituted or unsubstituted alkyl group having 1 to 50 carbon atoms, a substituted or unsubstituted cycloalkyl group, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 atoms forming the aromatic ring, a substituted or unsubstituted arylthio group having 5 to 50 atoms forming the aromatic ring, a substituted or unsubstituted alkoxycarbonyl group having 1 to 50 carbon atoms, substituted or unsubstituted silyl group, a carboxyl group, a halogen atom, a cyano group, a nitro group and a hydroxy group.

Examples of such an anthracene derivative are as follows.

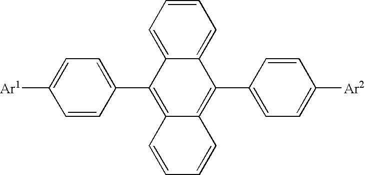

| Compound | Ar¹ | Ar² |
|---|---|---|
| AN-1 | 1-naphthyl | 9-phenanthryl |
| AN-2 | 1-naphthyl | 1-pyrenyl |
| AN-3 | 1-naphthyl | phenyl |
| AN-4 | 1-naphthyl | 2-biphenyl |
| AN-5 | 1-naphthyl | 3-biphenyl |
| AN-6 | 1-naphthyl | 4-biphenyl |
| AN-7 | 1-naphthyl | 2-p-ta-phenyl |
| AN-8 | 2-naphthyl | 1-naphthyl |
| AN-9 | 2-naphthyl | 9-phenanthryl |
| AN-10 | 2-naphthyl | 1-pyrenyl |
| AN-11 | 2-naphthyl | phenyl |
| AN-12 | 2-naphthyl | 2-biphenyl |
| AN-13 | 2-naphthyl | 3-biphenyl |
| AN-14 | 2-naphthyl | 4-biphenyl |
| AN-15 | 2-naphthyl | 2-p-ta-phenyl |
| AN-16 | 9-phenanthryl | 1-pyrenyl |
| AN-17 | 9-phenanthryl | phenyl |
| AN-18 | 9-phenanthryl | 2-biphenyl |
| AN-19 | 9-phenanthryl | 3-biphenyl |
| AN-20 | 9-phenanthryl | 4-biphenyl |
| AN-21 | 9-phenanthryl | 2-p-ta-phenyl |
| AN-22 | 1-biphenyl | phenyl |
| AN-23 | 1-biphenyl | 2-biphenyl |
| AN-24 | 1-biphenyl | 3-biphenyl |
| AN-25 | 1-biphenyl | 4-biphenyl |
| AN-26 | 1-biphenyl | 2-p-ta-phenyl |
| AN-27 | phenyl | 2-biphenyl |
| AN-28 | phenyl | 3-biphenyl |
| AN-29 | phenyl | 4-biphenyl |
| AN-30 | phenyl | 2-p-ta-phenyl |
| AN-31 | 2-biphenyl | 3-biphenyl |
| AN-32 | 2-biphenyl | 4-biphenyl |
| AN-33 | 2-biphenyl | 2-p-ta-phenyl |
| AN-34 | 3-biphenyl | 4-biphenyl |
| AN-35 | 3-biphenyl | 2-p-ta-phenyl |

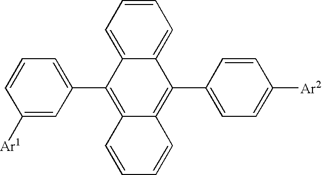

| Compound | Ar¹ | Ar² |
|---|---|---|
| AN-36 | 1-naphthyl | 1-naphthyl |
| AN-37 | 1-naphthyl | 2-naphthyl |
| AN-38 | 1-naphthyl | 9-phenanthryl |
| AN-39 | 1-naphthyl | 1-pyrenyl |
| AN-40 | 1-naphthyl | phenyl |
| AN-41 | 1-naphthyl | 2-biphenyl |
| AN-42 | 1-naphthyl | 3-biphenyl |
| AN-43 | 1-naphthyl | 4-biphenyl |
| AN-44 | 1-naphthyl | 2-p-ta-phenyl |
| AN-45 | 2-naphthyl | 1-naphthyl |
| AN-46 | 2-naphthyl | 2-naphthyl |
| AN-47 | 2-naphthyl | 9-phenanthryl |
| AN-48 | 2-naphthyl | 1-pyrenyl |
| AN-49 | 2-naphthyl | phenyl |
| AN-50 | 2-naphthyl | 2-biphenyl |
| AN-51 | 2-naphthyl | 3-biphenyl |
| AN-52 | 2-naphthyl | 4-biphenyl |
| AN-53 | 2-naphthyl | 2-p-ta-phenyl |
| AN-54 | 9-phenanthryl | 1-naphthyl |
| AN-55 | 9-phenanthryl | 2-naphthyl |
| AN-56 | 9-phenanthryl | 9-phenanthryl |
| AN-57 | 9-phenanthryl | 1-pyrenyl |
| AN-58 | 9-phenanthryl | phenyl |
| AN-59 | 9-phenanthryl | 2-biphenyl |
| AN-60 | 9-phenanthryl | 3-biphenyl |
| AN-61 | 9-phenanthryl | 4-biphenyl |
| AN-62 | 9-phenanthryl | 2-p-ta-phenyl |
| AN-63 | 1-pyrenyl | 1-naphthyl |
| AN-64 | 1-pyrenyl | 2-naphthyl |
| AN-65 | 1-pyrenyl | 9-phenanthryl |
| AN-66 | 1-pyrenyl | 1-pyrenyl |
| AN-67 | 1-pyrenyl | phenyl |
| AN-68 | 1-pyrenyl | 2-biphenyl |
| AN-69 | 1-pyrenyl | 3-biphenyl |
| AN-70 | 1-pyrenyl | 4-biphenyl |
| AN-71 | 1-pyrenyl | 2-p-ta-phenyl |
| AN-72 | phenyl | 1-naphthyl |
| AN-73 | phenyl | 2-naphthyl |
| AN-74 | phenyl | 9-phenanthryl |
| AN-75 | phenyl | 1-pyrenyl |
| AN-76 | phenyl | phenyl |
| AN-77 | phenyl | 2-biphenyl |
| AN-78 | phenyl | 3-biphenyl |
| AN-79 | phenyl | 4-biphenyl |
| AN-80 | phenyl | 2-p-ta-phenyl |
| AN-81 | 2-biphenyl | 1-naphthyl |
| AN-82 | 2-biphenyl | 2-naphthyl |
| AN-83 | 2-biphenyl | 9-phenanthryl |
| AN-84 | 2-biphenyl | 1-pyrenyl |
| AN-85 | 2-biphenyl | phenyl |
| AN-86 | 2-biphenyl | 2-biphenyl |
| AN-87 | 2-biphenyl | 3-biphenyl |
| AN-88 | 2-biphenyl | 4-biphenyl |
| AN-89 | 2-biphenyl | 2-p-ta-phenyl |
| AN-90 | 3-biphenyl | 1-naphthyl |
| AN-91 | 3-biphenyl | 2-naphthyl |
| AN-92 | 3-biphenyl | 9-phenanthryl |
| AN-93 | 3-biphenyl | 1-pyrenyl |
| AN-94 | 3-biphenyl | phenyl |
| AN-95 | 3-biphenyl | 2-biphenyl |
| AN-96 | 3-biphenyl | 3-biphenyl |
| AN-97 | 3-biphenyl | 4-biphenyl |
| AN-98 | 3-biphenyl | 2-p-ta-phenyl |
| AN-99 | 4-biphenyl | 1-naphthyl |
| AN-100 | 4-biphenyl | 2-naphthyl |
| AN-101 | 4-biphenyl | 9-phenanthryl |
| AN-102 | 4-biphenyl | 1-pyrenyl |
| AN-103 | 4-biphenyl | phenyl |
| AN-104 | 4-biphenyl | 2-biphenyl |
| AN-105 | 4-biphenyl | 3-biphenyl |
| AN-106 | 4-biphenyl | 4-biphenyl |
| AN-107 | 4-biphenyl | 2-p-ta-phenyl |

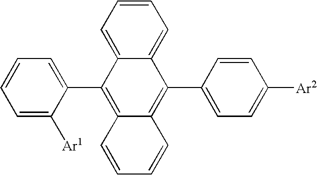

| Compound | Ar¹ | Ar² |
|---|---|---|
| AN-108 | 1-naphthyl | 1-naphthyl |
| AN-109 | 1-naphthyl | 2-naphthyl |
| AN-110 | 1-naphthyl | 9-phenanthryl |
| AN-111 | 1-naphthyl | 1-pyrenyl |
| AN-112 | 1-naphthyl | phenyl |
| AN-113 | 1-naphthyl | 2-biphenyl |
| AN-114 | 1-naphthyl | 3-biphenyl |
| AN-115 | 1-naphthyl | 4-biphenyl |
| AN-116 | 1-naphthyl | 2-p-ta-phenyl |
| AN-117 | 2-naphthyl | 1-naphthyl |
| AN-118 | 2-naphthyl | 2-naphthyl |
| AN-119 | 2-naphthyl | 9-phenanthryl |
| AN-120 | 2-naphthyl | 1-pyrenyl |
| AN-121 | 2-naphthyl | phenyl |
| AN-122 | 2-naphthyl | 2-biphenyl |
| AN-123 | 2-naphthyl | 3-biphenyl |
| AN-124 | 2-naphthyl | 4-biphenyl |
| AN-125 | 2-naphthyl | 2-p-ta-phenyl |
| AN-126 | 9-phenanthryl | 1-naphthyl |
| AN-127 | 9-phenanthryl | 2-naphthyl |
| AN-128 | 9-phenanthryl | 9-phenanthryl |
| AN-129 | 9-phenanthryl | 1-pyrenyl |
| AN-130 | 9-phenanthryl | phenyl |
| AN-131 | 9-phenanthryl | 2-biphenyl |
| AN-132 | 9-phenanthryl | 3-biphenyl |
| AN-133 | 9-phenanthryl | 4-biphenyl |
| AN-134 | 9-phenanthryl | 2-p-ta-phenyl |
| AN-135 | 1-pyrenyl | 1-naphthyl |
| AN-136 | 1-pyrenyl | 2-naphthyl |
| AN-137 | 1-pyrenyl | 9-phenanthryl |
| AN-138 | 1-pyrenyl | 1-pyrenyl |
| AN-139 | 1-pyrenyl | phenyl |
| AN-140 | 1-pyrenyl | 2-biphenyl |
| AN-141 | 1-pyrenyl | 3-biphenyl |
| AN-142 | 1-pyrenyl | 4-biphenyl |
| AN-143 | 1-pyrenyl | 2-p-ta-phenyl |
| AN-144 | phenyl | 1-naphthyl |
| AN-145 | phenyl | 2-naphthyl |
| AN-146 | phenyl | 9-phenanthryl |
| AN-147 | phenyl | 1-pyrenyl |
| AN-148 | phenyl | phenyl |
| AN-149 | phenyl | 2-biphenyl |
| AN-150 | phenyl | 3-biphenyl |
| AN-151 | phenyl | 4-biphenyl |
| AN-152 | phenyl | 2-p-ta-phenyl |
| AN-153 | 2-biphenyl | 1-naphthyl |
| AN-154 | 2-biphenyl | 2-naphthyl |
| AN-155 | 2-biphenyl | 9-phenanthryl |
| AN-156 | 2-biphenyl | 1-pyrenyl |
| AN-157 | 2-biphenyl | phenyl |
| AN-158 | 2-biphenyl | 2-biphenyl |
| AN-159 | 2-biphenyl | 3-biphenyl |
| AN-160 | 2-biphenyl | 4-biphenyl |
| AN-161 | 2-biphenyl | 2-p-ta-phenyl |
| AN-162 | 3-biphenyl | 1-naphthyl |
| AN-163 | 3-biphenyl | 2-naphthyl |
| AN-164 | 3-biphenyl | 9-phenanthryl |
| AN-165 | 3-biphenyl | 1-pyrenyl |
| AN-166 | 3-biphenyl | phenyl |
| AN-167 | 3-biphenyl | 2-biphenyl |
| AN-168 | 3-biphenyl | 3-biphenyl |
| AN-169 | 3-biphenyl | 4-biphenyl |
| AN-170 | 3-biphenyl | 2-p-ta-phenyl |
| AN-171 | 4-biphenyl | 1-naphthyl |
| AN-172 | 4-biphenyl | 2-naphthyl |
| AN-173 | 4-biphenyl | 9-phenanthryl |
| AN-174 | 4-biphenyl | 1-pyrenyl |
| AN-175 | 4-biphenyl | phenyl |
| AN-176 | 4-biphenyl | 2-biphenyl |
| AN-177 | 4-biphenyl | 3-biphenyl |
| AN-178 | 4-biphenyl | 4-biphenyl |
| AN-179 | 4-biphenyl | 2-p-ta-phenyl |

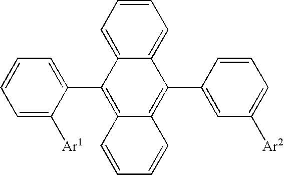

| Compound | Ar¹ | Ar² |
|---|---|---|
| AN-180 | 1-naphthyl | 1-naphthyl |
| AN-181 | 1-naphthyl | 2-naphthyl |
| AN-182 | 1-naphthyl | 9-phenanthryl |
| AN-183 | 1-naphthyl | 1-pyrenyl |
| AN-184 | 1-naphthyl | phenyl |
| AN-185 | 1-naphthyl | 2-biphenyl |
| AN-186 | 1-naphthyl | 3-biphenyl |
| AN-187 | 1-naphthyl | 4-biphenyl |
| AN-188 | 2-naphthyl | 1-naphthyl |
| AN-189 | 2-naphthyl | 2-naphthyl |
| AN-190 | 2-naphthyl | 9-phenanthryl |
| AN-191 | 2-naphthyl | 1-pyrenyl |
| AN-192 | 2-naphthyl | phenyl |
| AN-193 | 2-naphthyl | 2-biphenyl |
| AN-194 | 2-naphthyl | 3-biphenyl |
| AN-195 | 2-naphthyl | 4-biphenyl |
| AN-196 | 9-phenanthryl | 1-naphthyl |
| AN-197 | 9-phenanthryl | 2-naphthyl |
| AN-198 | 9-phenanthryl | 9-phenanthryl |
| AN-199 | 9-phenanthryl | 1-pyrenyl |
| AN-200 | 9-phenanthryl | phenyl |
| AN-201 | 9-phenanthryl | 2-biphenyl |
| AN-202 | 9-phenanthryl | 3-biphenyl |
| AN-203 | 9-phenanthryl | 4-biphenyl |
| AN-204 | 1-pyrenyl | 1-naphthyl |
| AN-205 | 1-pyrenyl | 2-naphthyl |
| AN-206 | 1-pyrenyl | 9-phenanthryl |
| AN-207 | 1-pyrenyl | 1-pyrenyl |
| AN-208 | 1-pyrenyl | phenyl |
| AN-209 | 1-pyrenyl | 2-biphenyl |
| AN-210 | 1-pyrenyl | 3-biphenyl |
| AN-211 | 1-pyrenyl | 4-biphenyl |
| AN-212 | phenyl | 1-naphthyl |
| AN-213 | phenyl | 2-naphthyl |
| AN-214 | phenyl | 9-phenanthryl |
| AN-215 | phenyl | 1-pyrenyl |
| AN-216 | phenyl | phenyl |
| AN-217 | phenyl | 2-biphenyl |
| AN-218 | phenyl | 3-biphenyl |
| AN-219 | phenyl | 4-biphenyl |
| AN-220 | 2-biphenyl | 1-naphthyl |
| AN-221 | 2-biphenyl | 2-naphthyl |
| AN-222 | 2-biphenyl | 9-phenanthryl |
| AN-223 | 2-biphenyl | 1-pyrenyl |
| AN-224 | 2-biphenyl | phenyl |
| AN-225 | 2-biphenyl | 2-biphenyl |
| AN-226 | 2-biphenyl | 3-biphenyl |
| AN-227 | 2-biphenyl | 4-biphenyl |
| AN-228 | 3-biphenyl | 1-naphthyl |
| AN-229 | 3-biphenyl | 2-naphthyl |
| AN-230 | 3-biphenyl | 9-phenanthryl |
| AN-231 | 3-biphenyl | 1-pyrenyl |
| AN-232 | 3-biphenyl | phenyl |
| AN-233 | 3-biphenyl | 2-biphenyl |
| AN-234 | 3-biphenyl | 3-biphenyl |
| AN-235 | 3-biphenyl | 4-biphenyl |
| AN-236 | 4-biphenyl | 1-naphthyl |
| AN-237 | 4-biphenyl | 2-naphthyl |
| AN-238 | 4-biphenyl | 9-phenanthryl |
| AN-239 | 4-biphenyl | 1-pyrenyl |
| AN-240 | 4-biphenyl | phenyl |
| AN-241 | 4-biphenyl | 2-biphenyl |
| AN-242 | 4-biphenyl | 3-biphenyl |
| AN-243 | 4-biphenyl | 4-biphenyl |

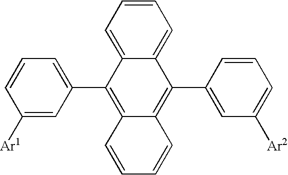

| Compound | Ar¹ | Ar² |
|---|---|---|
| AN-244 | 1-naphthyl | 2-naphthyl |
| AN-245 | 1-naphthyl | 9-phenanthryl |
| AN-246 | 1-naphthyl | 1-pyrenyl |
| AN-247 | 1-naphthyl | phenyl |
| AN-248 | 1-naphthyl | 2-biphenyl |
| AN-249 | 1-naphthyl | 3-biphenyl |
| AN-250 | 1-naphthyl | 4-biphenyl |
| AN-251 | 2-naphthyl | 9-phenanthryl |
| AN-252 | 2-naphthyl | 1-pyrenyl |
| AN-253 | 2-naphthyl | phenyl |
| AN-254 | 2-naphthyl | 2-biphenyl |
| AN-255 | 2-naphthyl | 3-biphenyl |
| AN-256 | 2-naphthyl | 4-biphenyl |
| AN-257 | 9-phenanthryl | 1-pyrenyl |
| AN-258 | 9-phenanthryl | phenyl |
| AN-259 | 9-phenanthryl | 2-biphenyl |
| AN-260 | 9-phenanthryl | 3-biphenyl |
| AN-261 | 9-phenanthryl | 4-biphenyl |
| AN-262 | 1-pyrenyl | phenyl |
| AN-263 | 1-pyrenyl | 2-biphenyl |
| AN-264 | 1-pyrenyl | 3-biphenyl |
| AN-265 | 1-pyrenyl | 4-biphenyl |
| AN-266 | phenyl | 2-biphenyl |
| AN-267 | phenyl | 3-biphenyl |
| AN-268 | phenyl | 4-biphenyl |
| AN-269 | 2-biphenyl | 3-biphenyl |
| AN-270 | 2-biphenyl | 4-biphenyl |
| AN-271 | 3-biphenyl | 4-biphenyl |

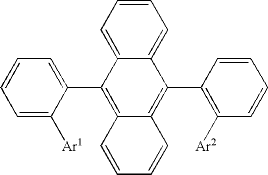

| Compound | Ar¹ | Ar² |
|---|---|---|
| AN-272 | 1-naphthyl | 2-naphthyl |
| AN-273 | 1-naphthyl | 9-phenanthryl |
| AN-274 | 1-naphthyl | 1-pyrenyl |
| AN-275 | 1-naphthyl | phenyl |
| AN-276 | 1-naphthyl | 2-biphenyl |
| AN-277 | 1-naphthyl | 3-biphenyl |
| AN-278 | 1-naphthyl | 4-biphenyl |
| AN-279 | 2-naphthyl | 9-phenanthryl |
| AN-280 | 2-naphthyl | 1-pyrenyl |
| AN-281 | 2-naphthyl | phenyl |
| AN-282 | 2-naphthyl | 2-biphenyl |
| AN-283 | 2-naphthyl | 3-biphenyl |
| AN-284 | 2-naphthyl | 4-biphenyl |
| AN-285 | 9-phenanthryl | 1-pyrenyl |
| AN-286 | 9-phenanthryl | phenyl |
| AN-287 | 9-phenanthryl | 2-biphenyl |
| AN-288 | 9-phenanthryl | 3-biphenyl |
| AN-289 | 9-phenanthryl | 4-biphenyl |
| AN-290 | 1-pyrenyl | phenyl |
| AN-291 | 1-pyrenyl | 2-biphenyl |
| AN-292 | 1-pyrenyl | 3-biphenyl |
| AN-293 | 1-pyrenyl | 4-biphenyl |
| AN-294 | phenyl | 2-biphenyl |
| AN-295 | phenyl | 3-biphenyl |
| AN-296 | phenyl | 4-biphenyl |
| AN-297 | 2-biphenyl | 3-biphenyl |
| AN-298 | 2-biphenyl | 4-biphenyl |
| AN-299 | 3-biphenyl | 4-biphenyl |

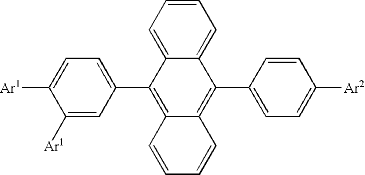

| Compound | Ar¹ | Ar² |
|---|---|---|
| AN-300 | 1-naphthyl | 1-naphthyl |
| AN-301 | 1-naphthyl | 2-naphthyl |
| AN-302 | 1-naphthyl | 9-phenanthryl |
| AN-303 | 1-naphthyl | 1-pyrenyl |
| AN-304 | 1-naphthyl | phenyl |
| AN-305 | 1-naphthyl | 2-biphenyl |
| AN-306 | 1-naphthyl | 3-biphenyl |
| AN-307 | 1-naphthyl | 4-biphenyl |
| AN-308 | 1-naphthyl | 2-p-ta-phenyl |
| AN-309 | 2-naphthyl | 1-naphthyl |
| AN-310 | 2-naphthyl | 2-naphthyl |
| AN-311 | 2-naphthyl | 9-phenanthryl |
| AN-312 | 2-naphthyl | 1-pyrenyl |
| AN-313 | 2-naphthyl | phenyl |
| AN-314 | 2-naphthyl | 2-biphenyl |
| AN-315 | 2-naphthyl | 3-biphenyl |
| AN-316 | 2-naphthyl | 4-biphenyl |
| AN-317 | 2-naphthyl | 2-p-ta-phenyl |

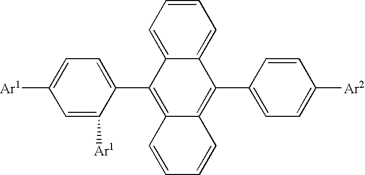

| Compound | Ar¹ | Ar² |
|---|---|---|
| AN-318 | 1-naphthyl | 1-naphthyl |
| AN-319 | 1-naphthyl | 2-naphthyl |
| AN-320 | 1-naphthyl | 9-phenanthryl |
| AN-321 | 1-naphthyl | 1-pyrenyl |
| AN-322 | 1-naphthyl | phenyl |
| AN-323 | 1-naphthyl | 2-biphenyl |
| AN-324 | 1-naphthyl | 3-biphenyl |
| AN-325 | 1-naphthyl | 4-biphenyl |
| AN-326 | 1-naphthyl | 2-p-ta-phenyl |
| AN-327 | 2-naphthyl | 1-naphthyl |
| AN-328 | 2-naphthyl | 2-naphthyl |
| AN-329 | 2-naphthyl | 9-phenanthryl |
| AN-330 | 2-naphthyl | 1-pyrenyl |
| AN-331 | 2-naphthyl | phenyl |
| AN-332 | 2-naphthyl | 2-biphenyl |
| AN-333 | 2-naphthyl | 3-biphenyl |
| AN-334 | 2-naphthyl | 4-biphenyl |
| AN-335 | 2-naphthyl | 2-p-ta-phenyl |

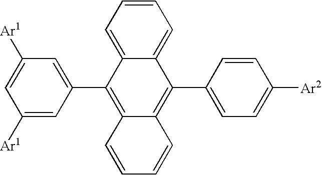

| Compound | Ar¹ | Ar² |
|---|---|---|
| AN-336 | 1-naphthyl | 1-naphthyl |
| AN-337 | 1-naphthyl | 2-naphthyl |
| AN-338 | 1-naphthyl | 9-phenanthryl |
| AN-339 | 1-naphthyl | 1-pyrenyl |
| AN-340 | 1-naphthyl | phenyl |
| AN-341 | 1-naphthyl | 2-biphenyl |
| AN-342 | 1-naphthyl | 3-biphenyl |
| AN-343 | 1-naphthyl | 4-biphenyl |
| AN-344 | 1-naphthyl | 2-p-ta-phenyl |
| AN-345 | 2-naphthyl | 1-naphthyl |
| AN-346 | 2-naphthyl | 2-naphthyl |
| AN-347 | 2-naphthyl | 9-phenanthryl |
| AN-348 | 2-naphthyl | 1-pyrenyl |
| AN-349 | 2-naphthyl | phenyl |
| AN-350 | 2-naphthyl | 2-biphenyl |
| AN-351 | 2-naphthyl | 3-biphenyl |
| AN-352 | 2-naphthyl | 4-biphenyl |
| AN-353 | 2-naphthyl | 2-p-ta-phenyl |

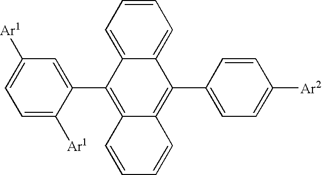

| Compound | Ar¹ | Ar² |
|---|---|---|
| AN-354 | 1-naphthyl | 1-naphthyl |
| AN-355 | 1-naphthyl | 2-naphthyl |
| AN-356 | 1-naphthyl | 9-phenanthryl |
| AN-357 | 1-naphthyl | 1-pyrenyl |
| AN-358 | 1-naphthyl | phenyl |
| AN-359 | 1-naphthyl | 2-biphenyl |
| AN-360 | 1-naphthyl | 3-biphenyl |
| AN-361 | 1-naphthyl | 4-biphenyl |
| AN-362 | 1-naphthyl | 2-p-ta-phenyl |
| AN-363 | 2-naphthyl | 1-naphthyl |
| AN-364 | 2-naphthyl | 2-naphthyl |
| AN-365 | 2-naphthyl | 9-phenanthryl |
| AN-366 | 2-naphthyl | 1-pyrenyl |
| AN-367 | 2-naphthyl | phenyl |
| AN-368 | 2-naphthyl | 2-biphenyl |
| AN-369 | 2-naphthyl | 3-biphenyl |
| AN-370 | 2-naphthyl | 4-biphenyl |
| AN-371 | 2-naphthyl | 2-p-ta-phenyl |

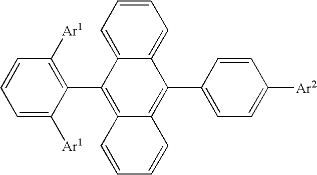

| Compound | Ar¹ | Ar² |
|---|---|---|
| AN-372 | 1-naphthyl | 1-naphthyl |
| AN-373 | 1-naphthyl | 2-naphthyl |
| AN-374 | 1-naphthyl | 9-phenanthryl |
| AN-375 | 1-naphthyl | 1-pyrenyl |
| AN-376 | 1-naphthyl | phenyl |
| AN-377 | 1-naphthyl | 2-biphenyl |
| AN-378 | 1-naphthyl | 3-biphenyl |
| AN-379 | 1-naphthyl | 4-biphenyl |
| AN-380 | 1-naphthyl | 2-p-ta-phenyl |
| AN-381 | 2-naphthyl | 1-naphthyl |
| AN-382 | 2-naphthyl | 2-naphthyl |
| AN-383 | 2-naphthyl | 9-phenanthryl |
| AN-384 | 2-naphthyl | 1-pyrenyl |
| AN-385 | 2-naphthyl | phenyl |
| AN-386 | 2-naphthyl | 2-biphenyl |
| AN-387 | 2-naphthyl | 3-biphenyl |
| AN-388 | 2-naphthyl | 4-biphenyl |
| AN-389 | 2-naphthyl | 2-p-ta-phenyl |

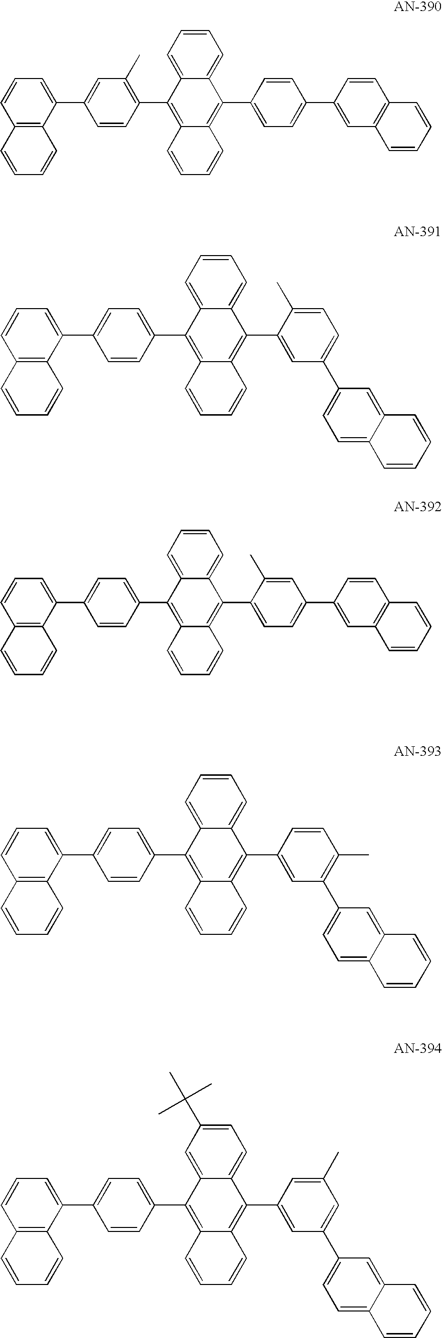

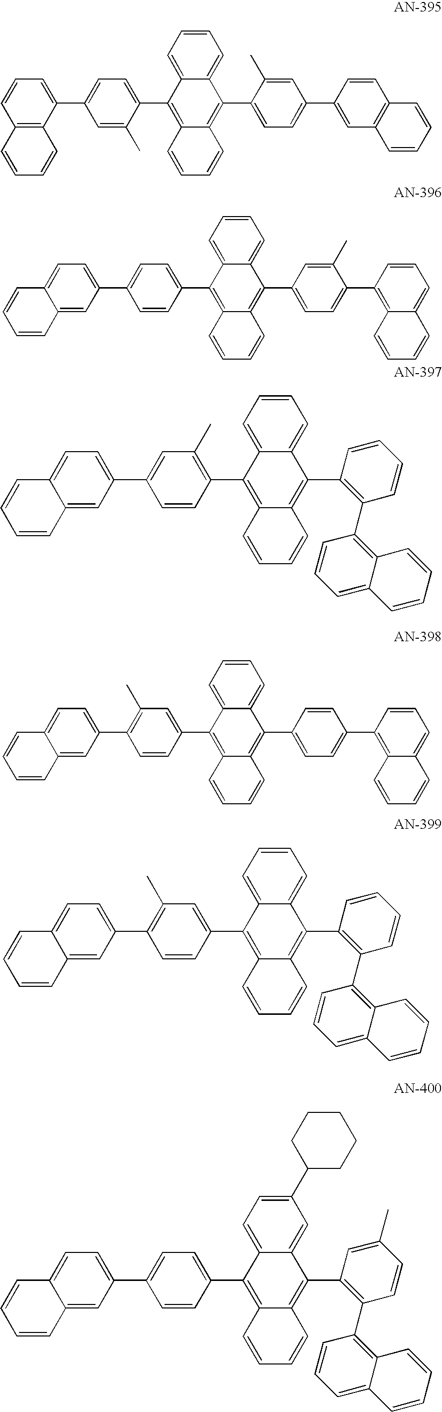

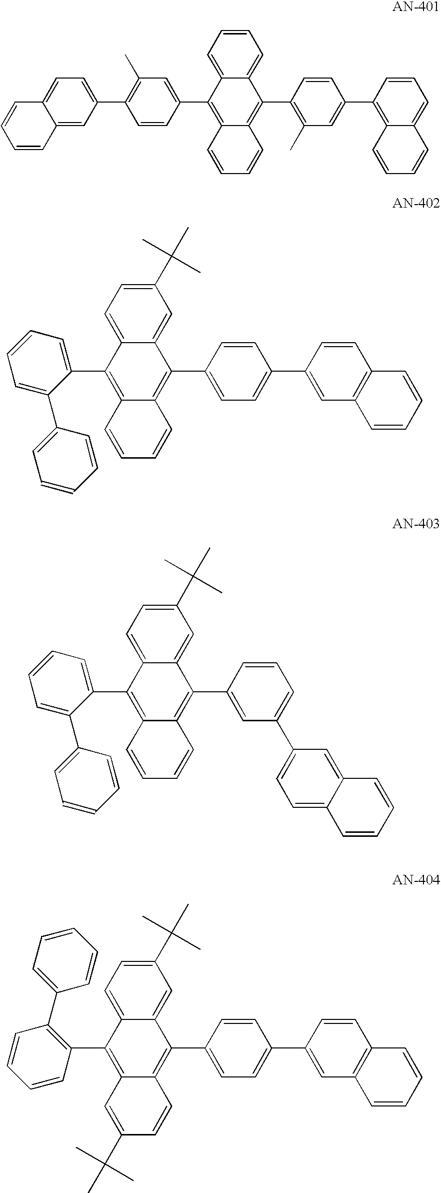

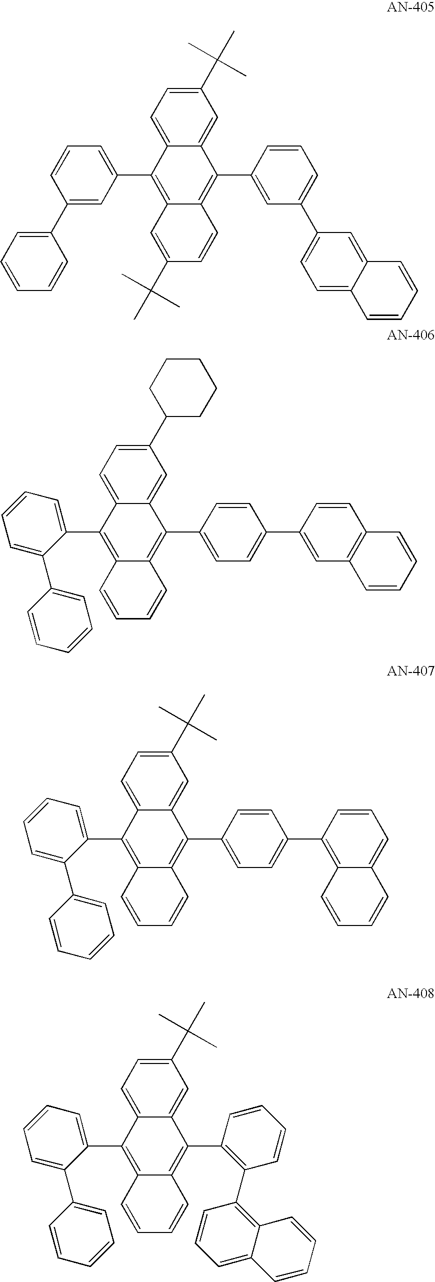

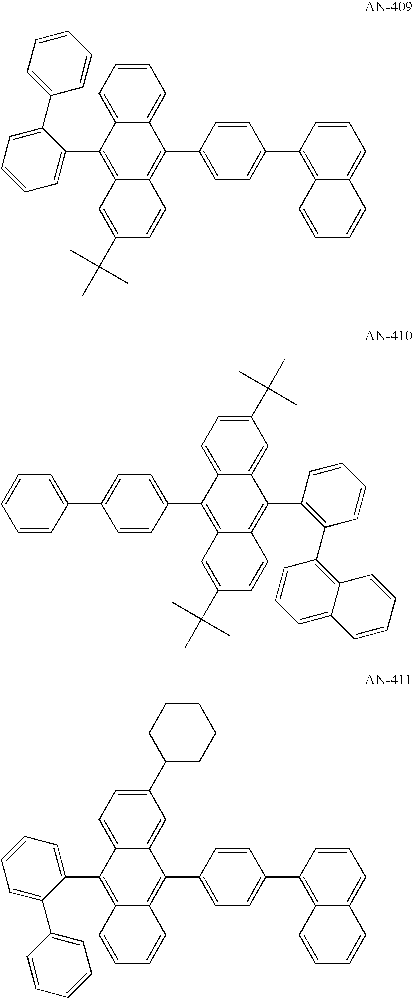

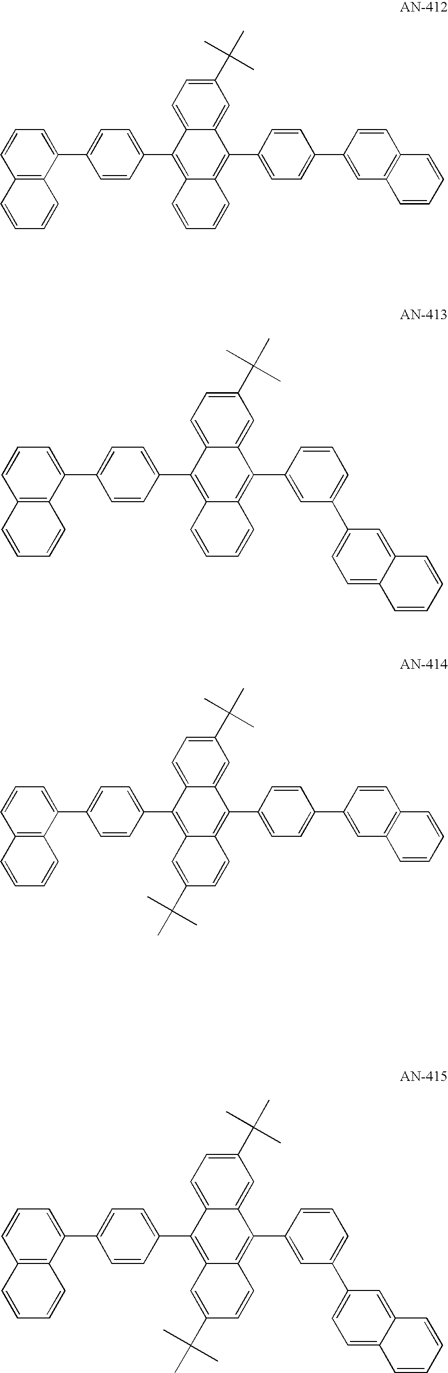

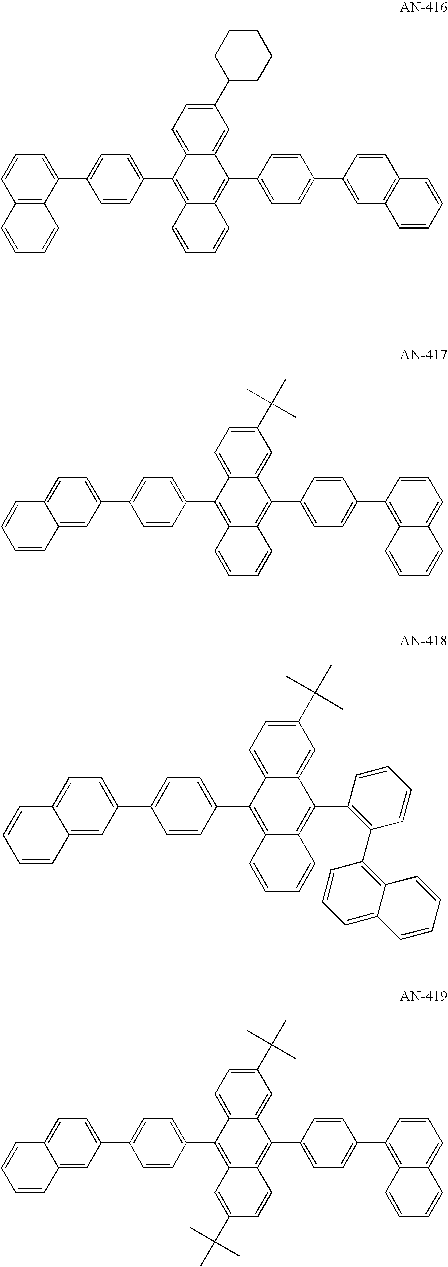

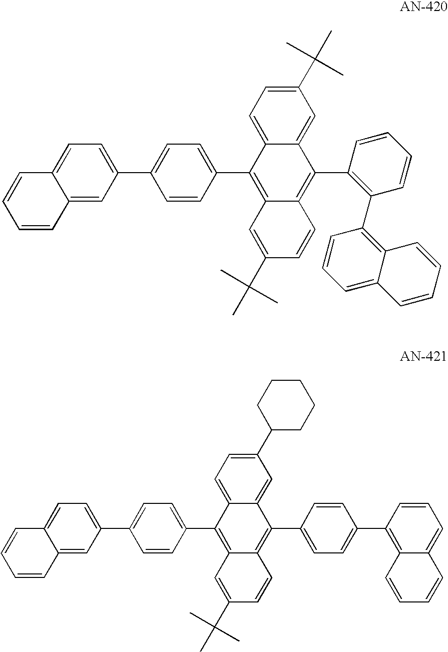

The anthracene derivative may be a compound represented by a formula (4) as follows.

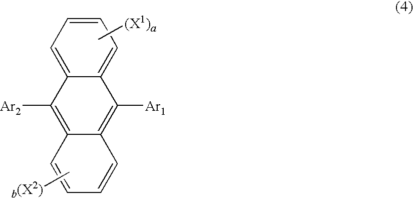

In the above formula (4); at least either one of Ar¹ and Ar² is a substituent having a substituted or unsubstituted condensed ring group with 10 to 30 carbon atoms forming the aromatic ring;

X¹ and X² are each a substituted or unsubstituted aromatic group having 6 to 50 carbon atoms forming the aromatic ring, a substituted or unsubstituted aromatic heterocycle group having 5 to 50 carbon atoms forming the aromatic ring, a substituted or unsubstituted alkyl group having 1 to 50 carbon atoms, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 carbon atoms, a substituted or unsubstituted arylthio group having 5 to 50 carbon atoms, a substituted or unsubstituted alkoxycarbonyl group having 1 to 50 carbon atoms, a carboxyl group, a halogen group, a cyano group, a nitro group and hydroxyl group; and

a and b are each an integer in a range of 0 to 4, a plurality of X¹ being mutually the same or different when a is 2 or more, a plurality of X² being mutually the same or different when b is 2 or more.

Examples of a substituent group of Ar¹ and Ar² in the formula (4), the substituent group including a condensed ring group with 10 to 30 carbon atoms forming the aromatic ring, are a substituted or unsubstituted α-naphthyl group, a substituted or unsubstituted β-naphthyl group, a substituted or unsubstituted phenanthryl group, a substituted or unsubstituted crycenyl group, a substituted or unsubstituted tetracenyl group, a substituted or unsubstituted pyrenyl group, a substituted or unsubstituted phenylnaphthyl group, a substituted or unsubstituted naphthylnaphthyl group, a substituted or unsubstituted napthylphenyl group, a substituted or unsubstituted phenylpyrenyl group, a substituted or unsubstituted pyrenylphenyl group, a substituted or unsubstituted naphthylnaphthylnaphthyl group, a substituted or unsubstituted naphthylnaphthylphenyl group, a substituted or unsubstituted naphthylphenylnaphthyl group, a substituted or unsubstituted phenylnaphthylnaphthyl group, a substituted or unsubstituted phenylnaphthylphenyl group, a substituted or unsubstituted phenylphenylnaphthyl group.

A preferable group among the above is a substituted or unsubstituted α-naphthyl group, a substituted or unsubstituted β-naphthyl group, a substituted or unsubstituted phenylnaphthyl group, a substituted or unsubstituted naphthylnaphthyl group or a substituted or unsubstituted napthylphenyl group.

Examples of such an anthracene derivative are as follows.

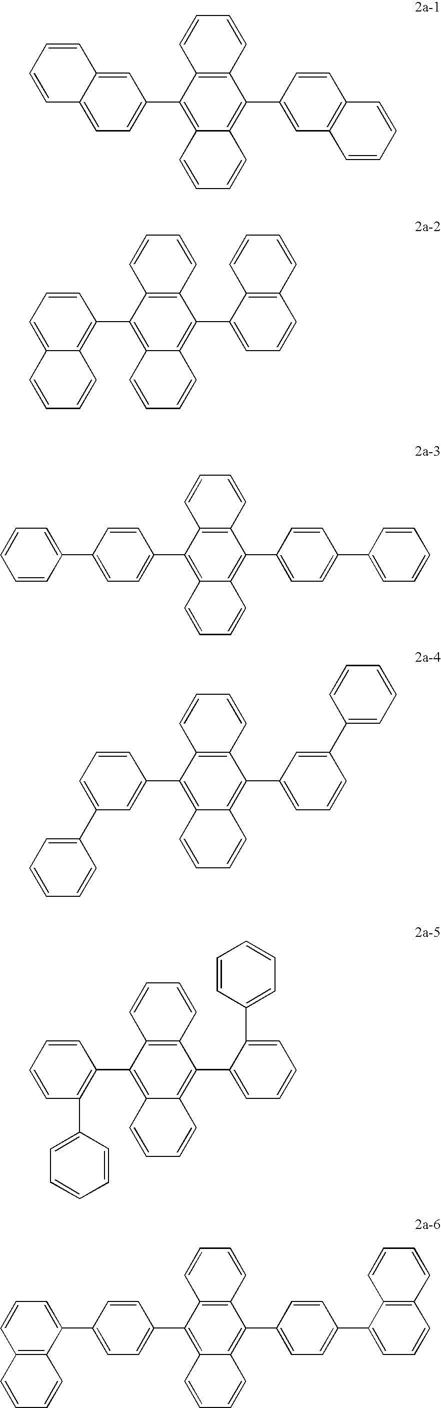

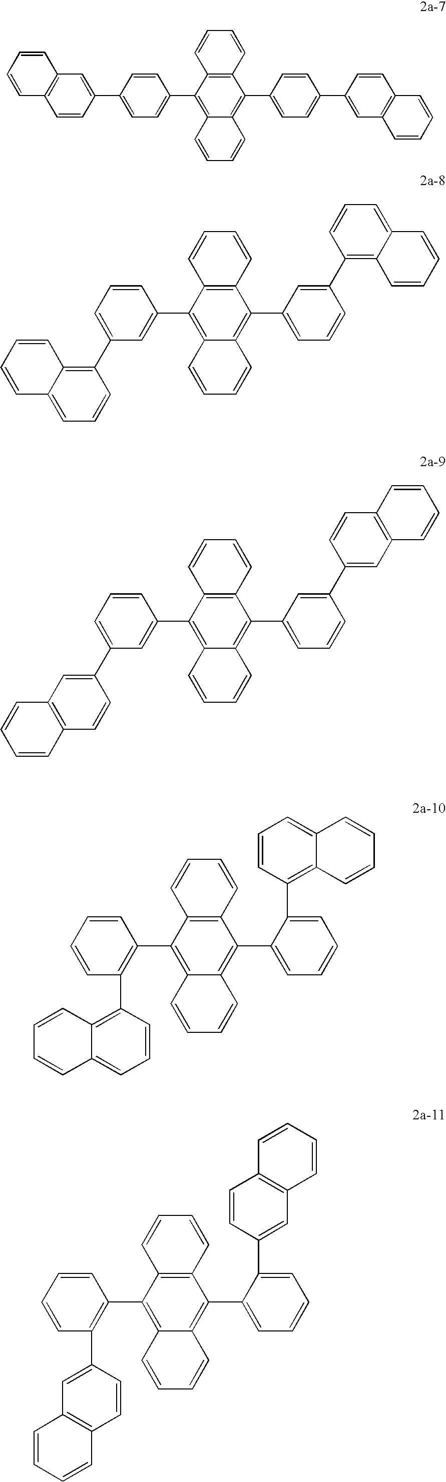

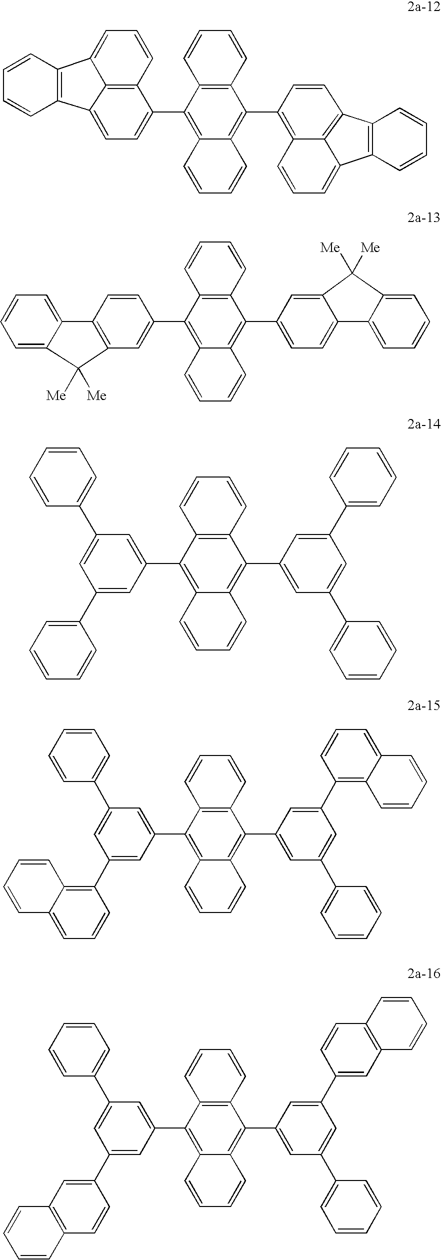

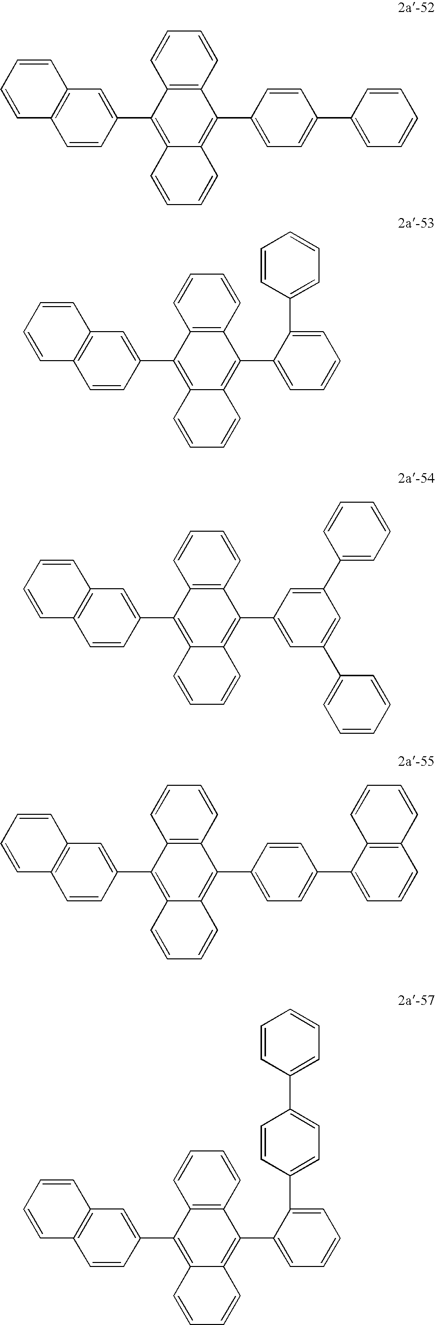

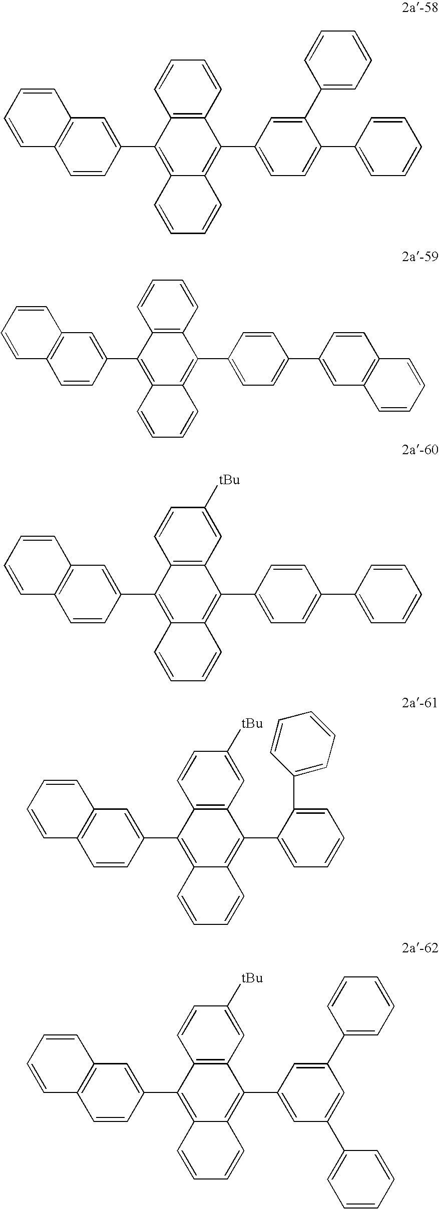

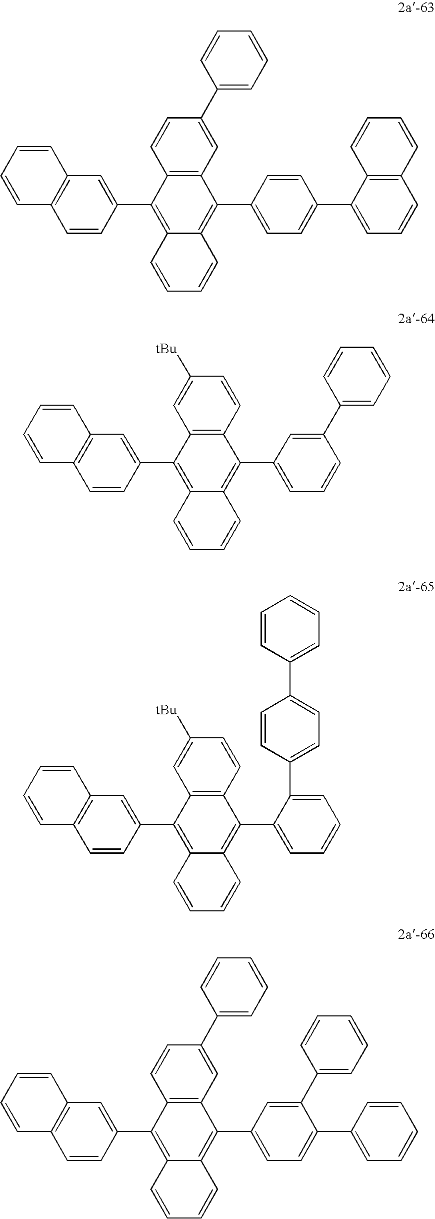

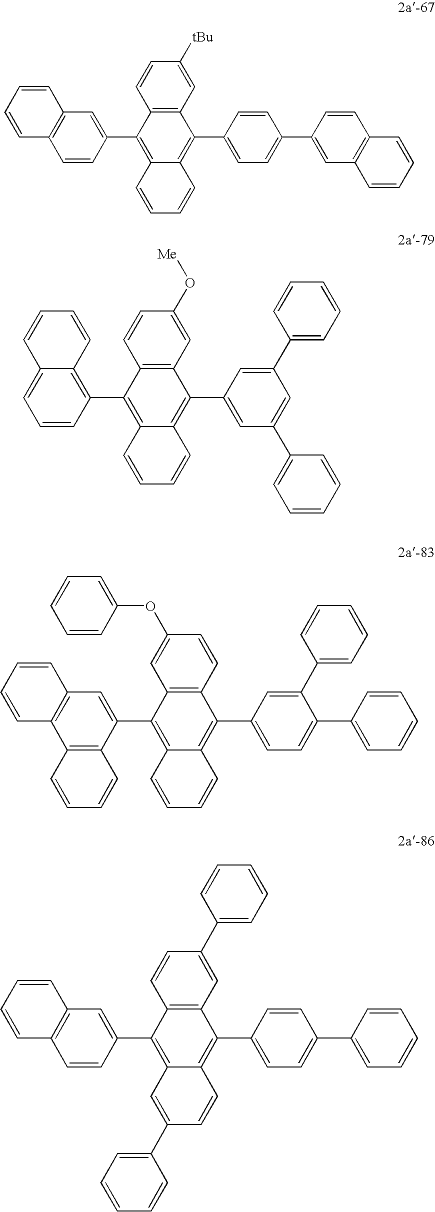

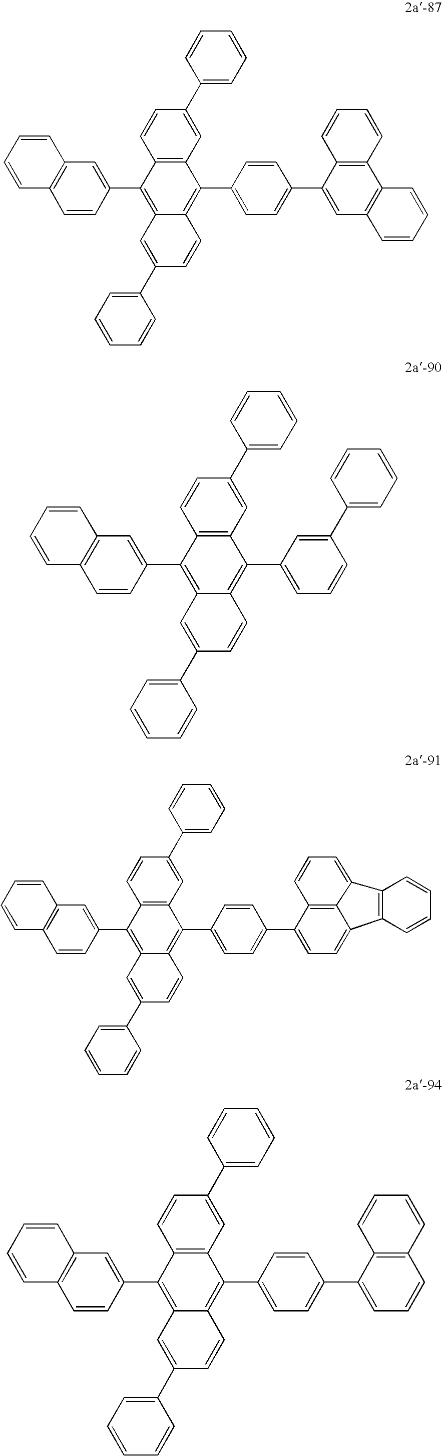

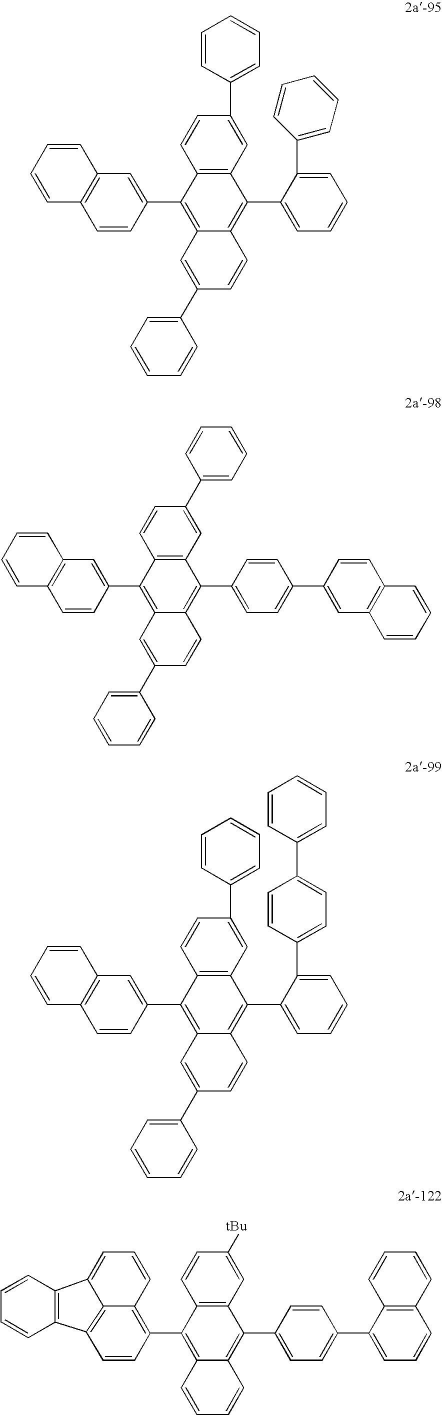

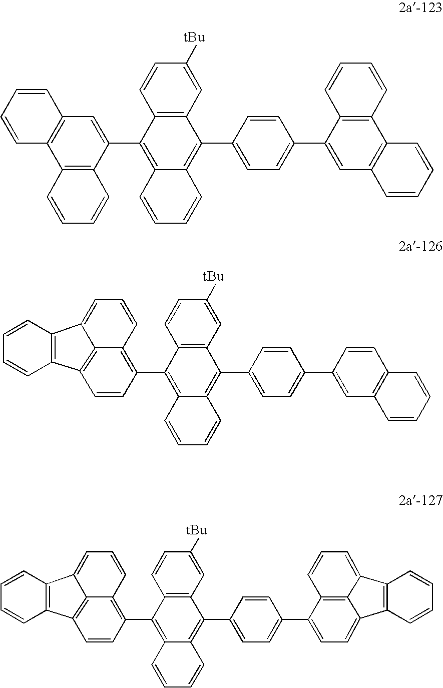

Examples of a dopant used together with the host containing the above anthracene derivative are a styrylamine derivative represented by a formula (5) as follows and a substituted derivative of arylamine represented by a formula (6) as follows.

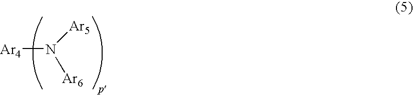

In the formula (5), at least one of Ar₄ to Ar₆ includes a styryl group. Preferably, Ar₄ is selected from a group consisting of a phenyl group, a biphenyl group, a terphenyl group, a stilbene group and a distyryl-aryl group while Ar₅ and Ar₆ are either one of a hydrogen atom and an aromatic group having 6 to 20 carbon atoms. P′ represents an integer in a range of 1 to 4.

The aromatic group having 6 to 20 carbon atoms is preferably a phenyl group, a naphthyl group, an anthracenyl group, a phenanthryl group, a terphenyl group or the like.

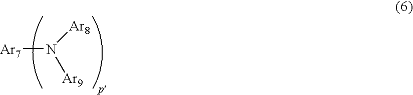

In the formula (6) above, Ar₇ to Ar₉ each represent a substituted or unsubstituted aryl group with 5 to 40 carbon atoms forming the aromatic ring. q′ is an integer in a range of 1 to 4.

In the formula above, the aryl group having 5 to 40 ring atoms is preferably phenyl, naphthyl, anthracenyl, phenanthryl, pyrenyl, chrysenyl, coronyl, biphenyl, terphenyl, pyrrolyl, furanyl, thiophenyl, benzothiophenyl, oxadiazolyl, diphenyl anthracenyl, indolyl, carbazolyl, pyridyl, benzoquinolyl, fluorenyl, fluoranthenyl, acenaphthofluoranthenyl, stilbene, a group represented by a general formula (A) or (B) below or the like.

In the general formula (A), r is an integer in a range of 1 to 3.

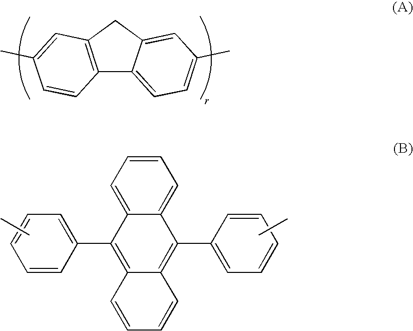

The aryl group having 5 to 40 ring atoms may be substituted by a substituent group, in which the substituent group is preferably an alkyl group having 2 to 6 carbon atoms (e.g., an ethyl group, a methyl group, an isopropyl group, an n-propyl group, an s-butyl group, a t-butyl group, a pentyl group, a hexyl group, a cyclopentyl group and a cyclohexyl group).

Examples of the dopant are compounds shown below.

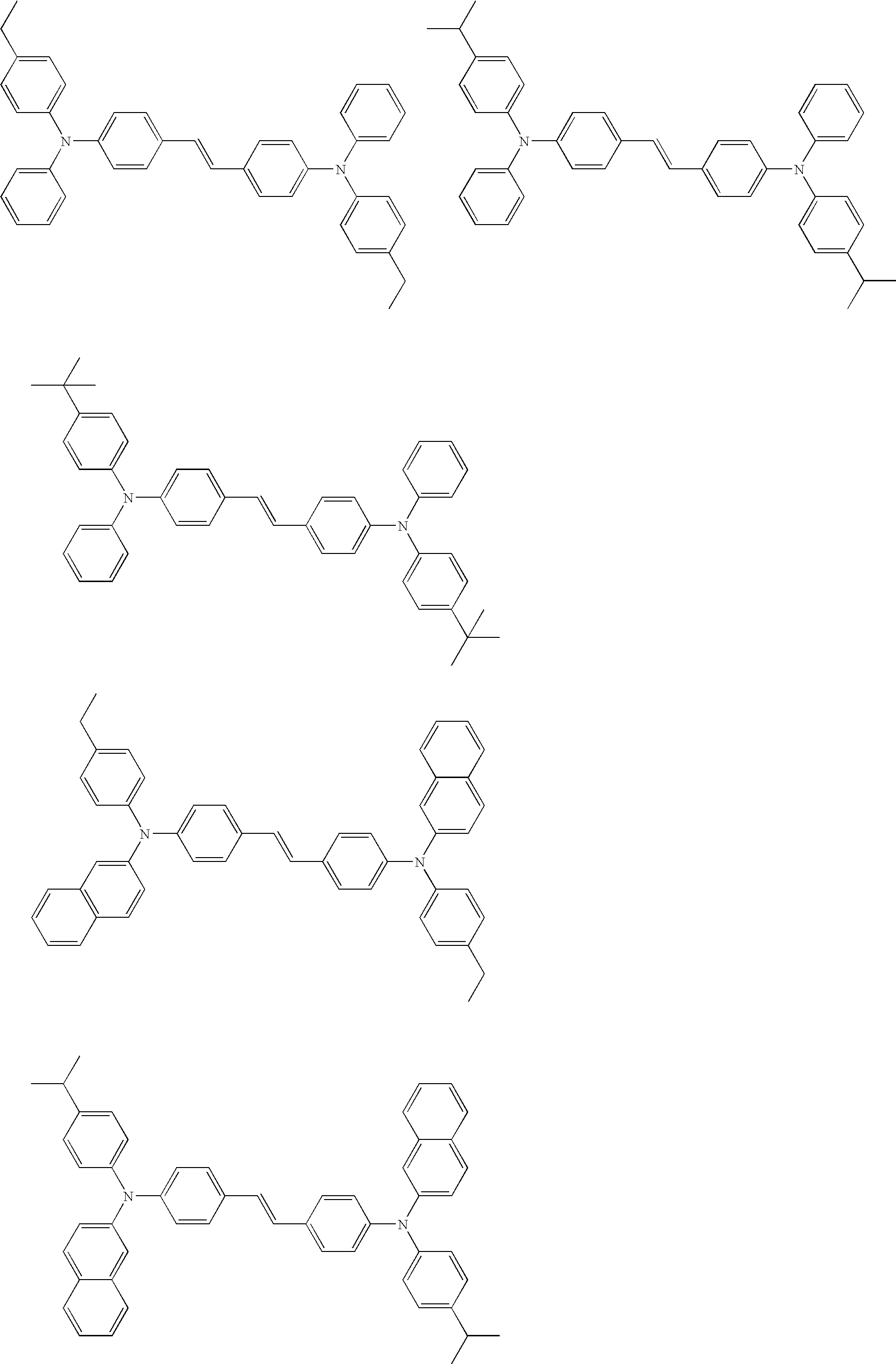

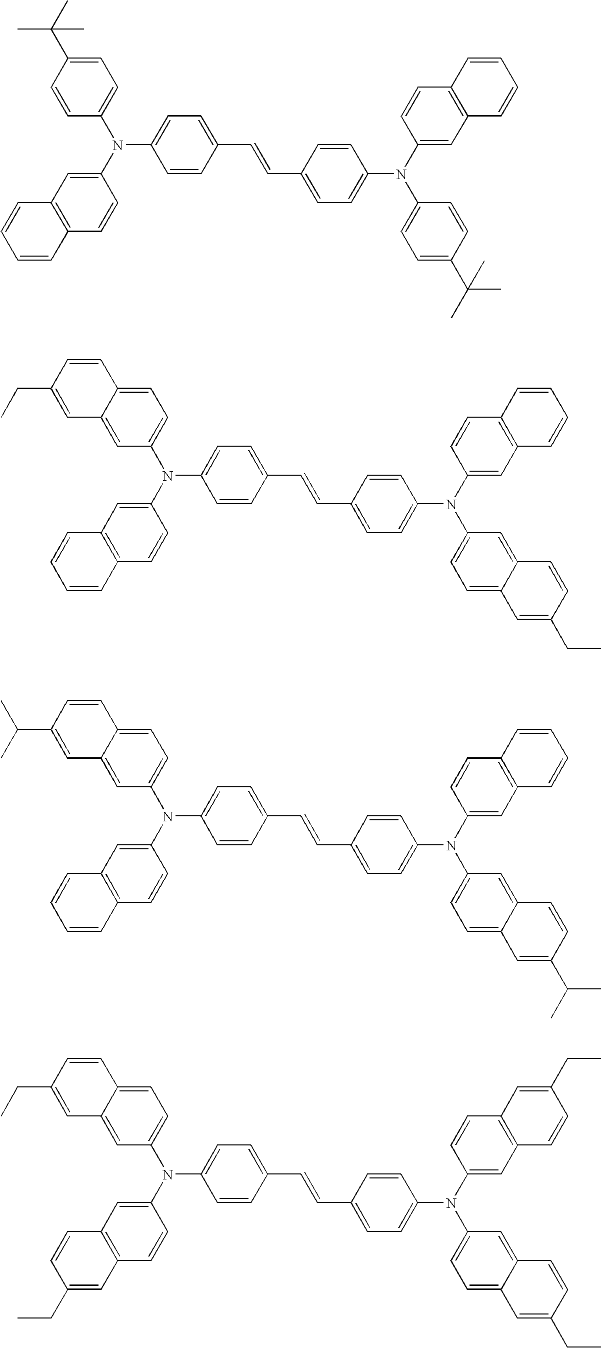

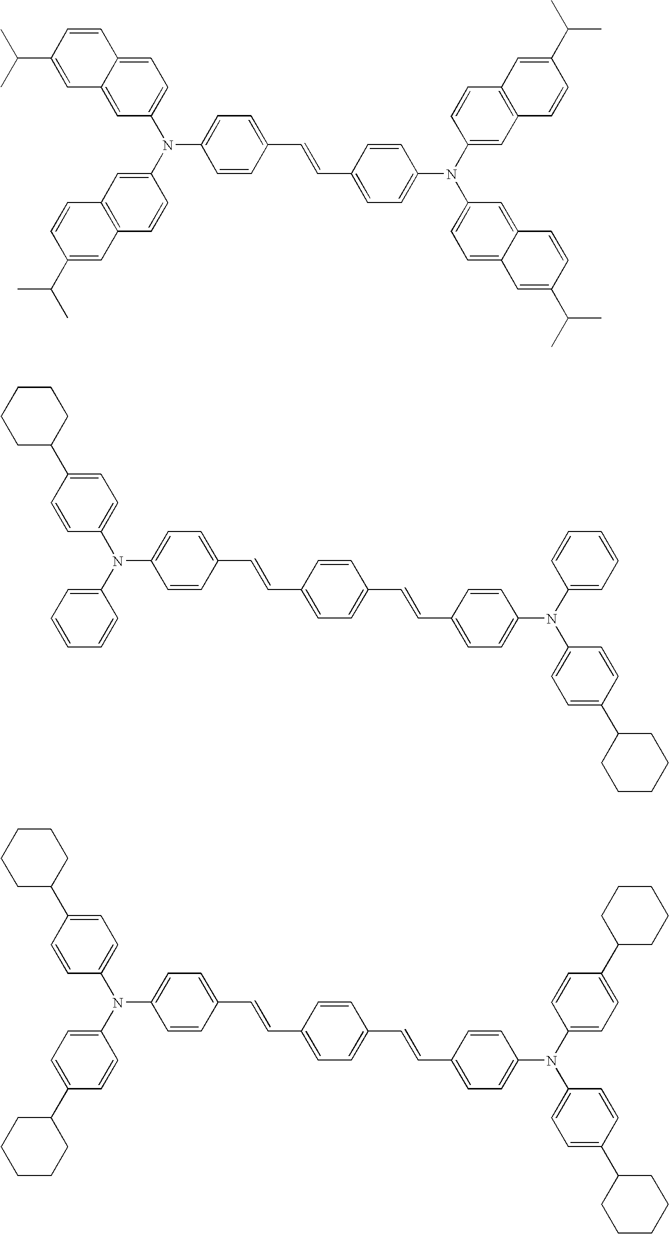

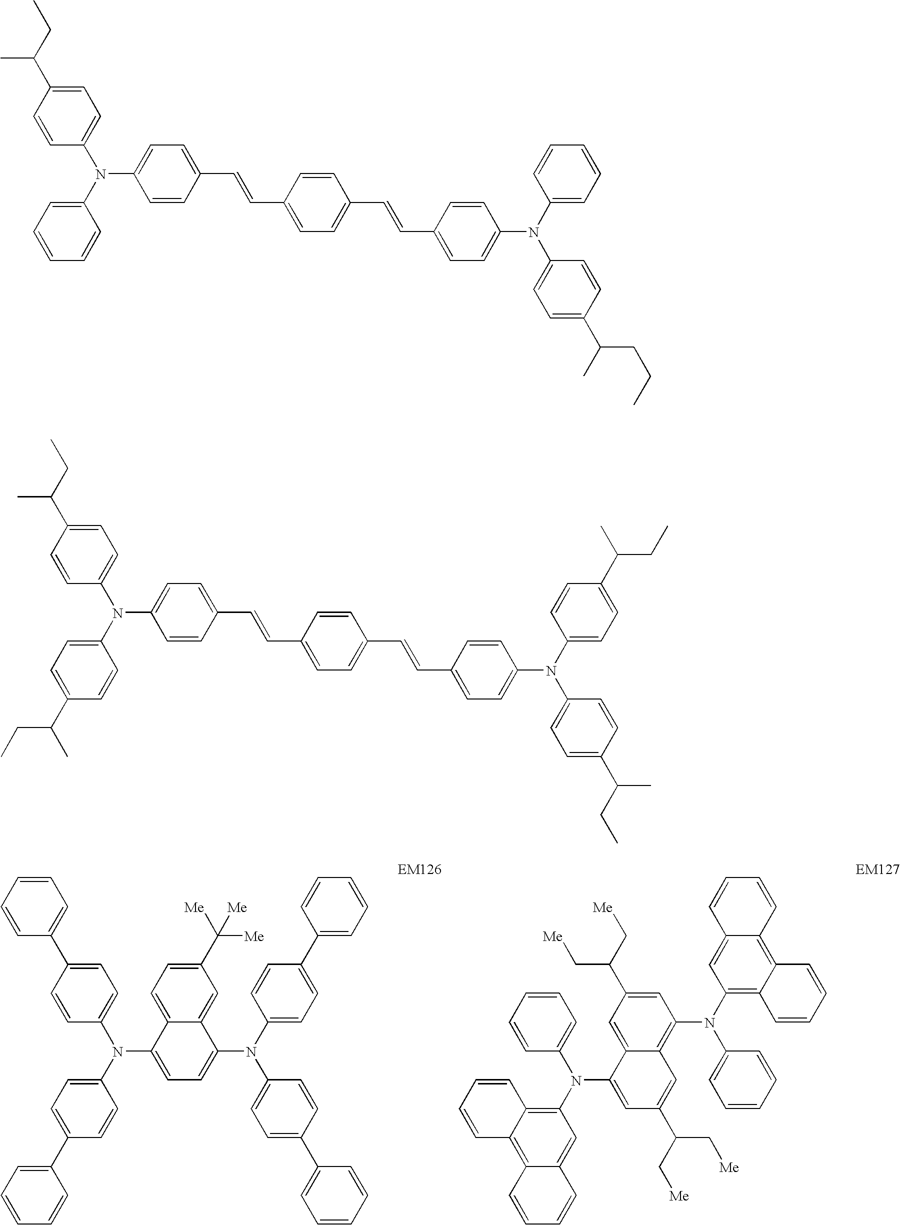

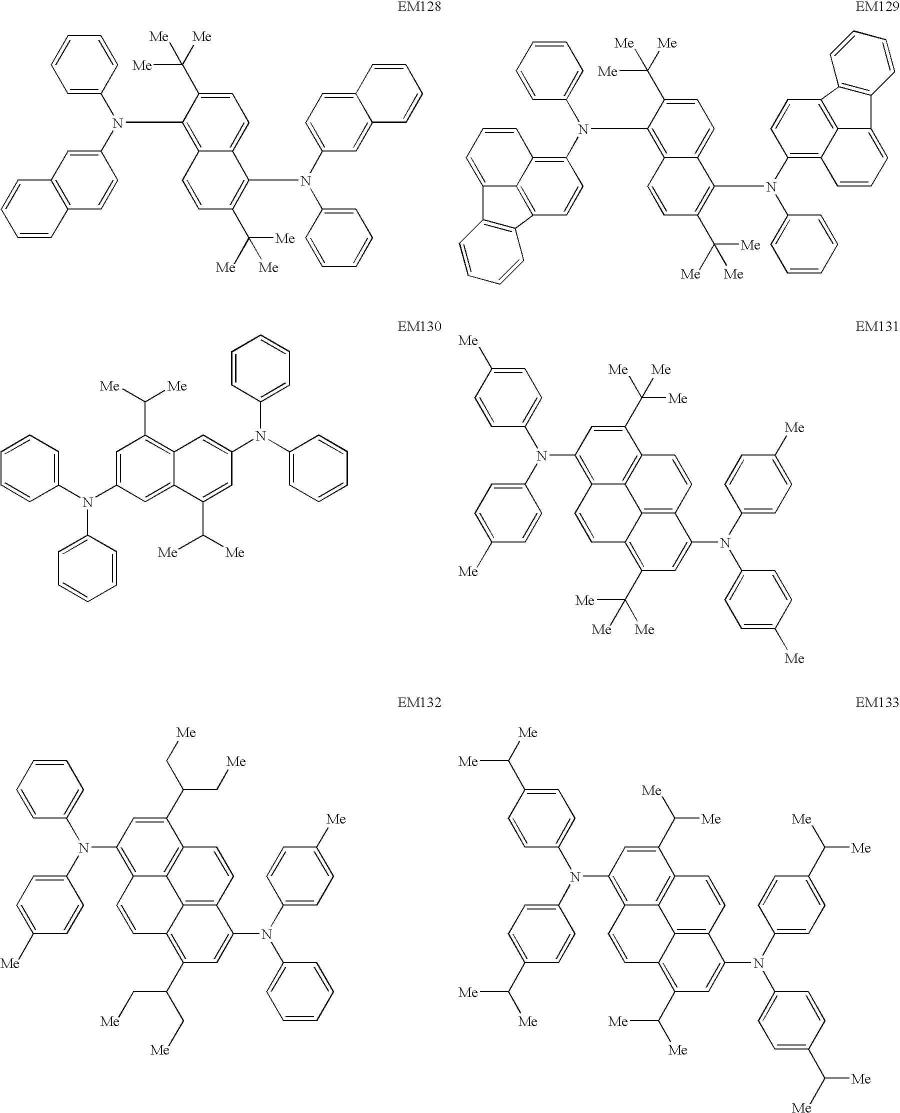

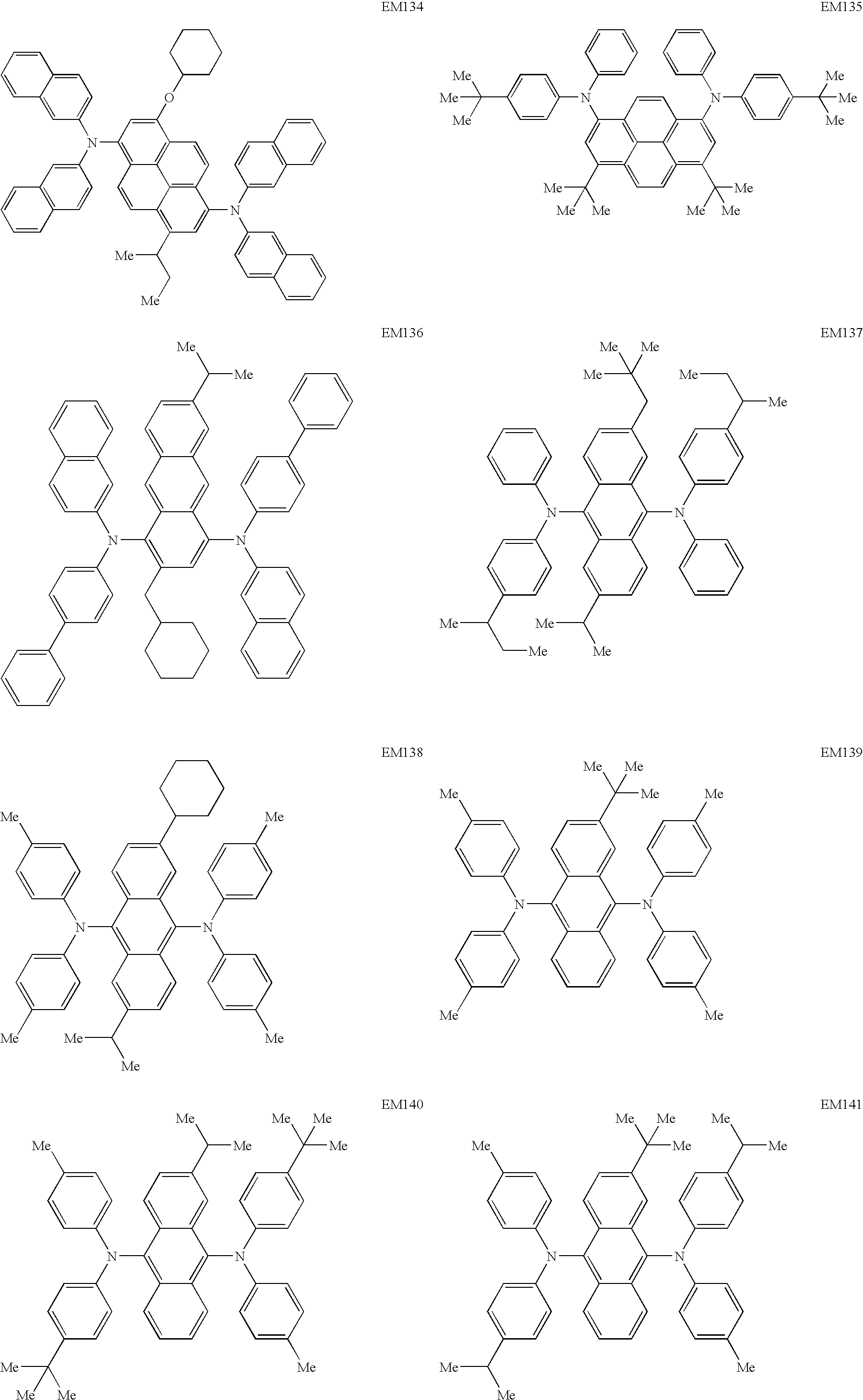

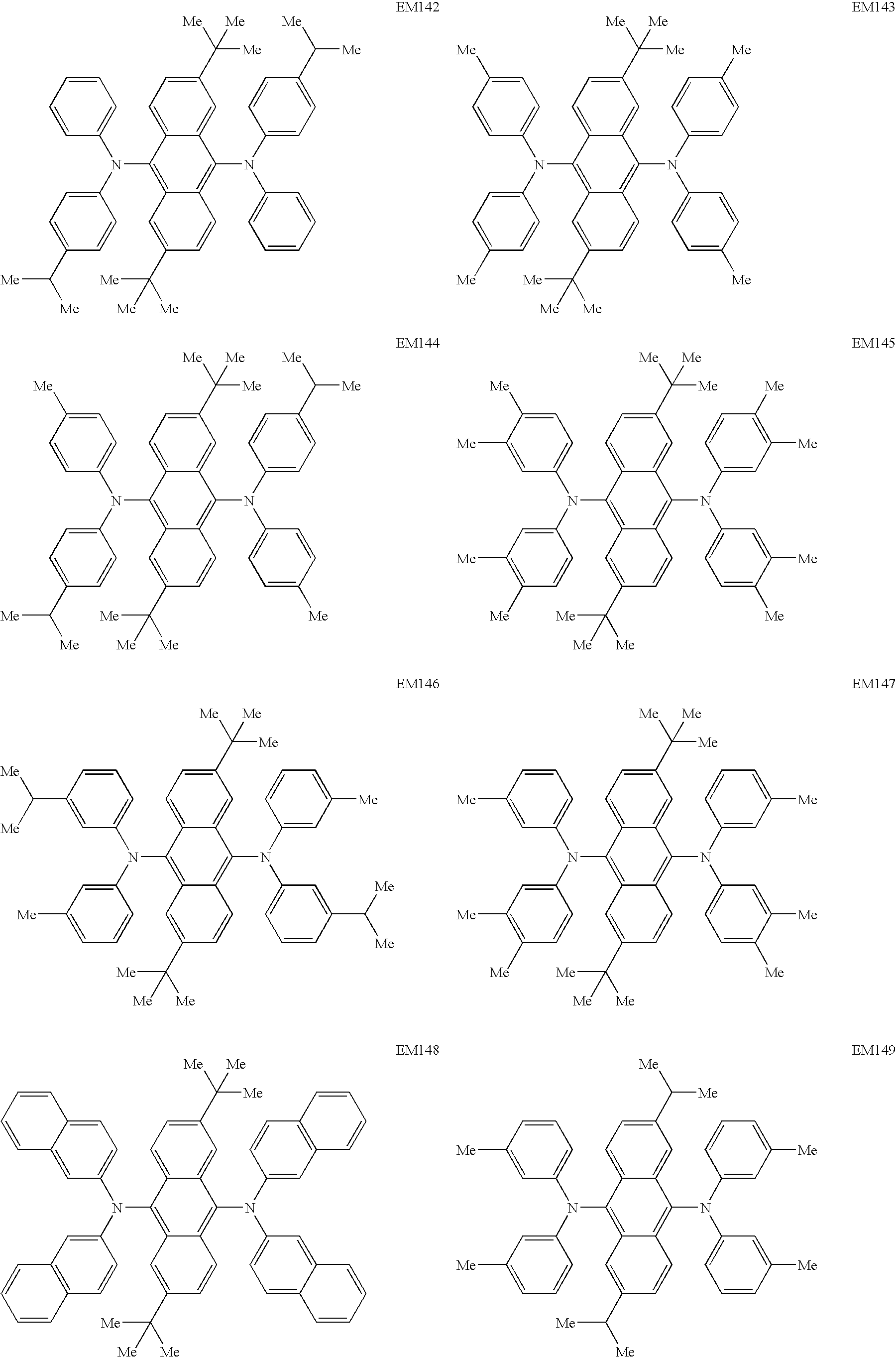

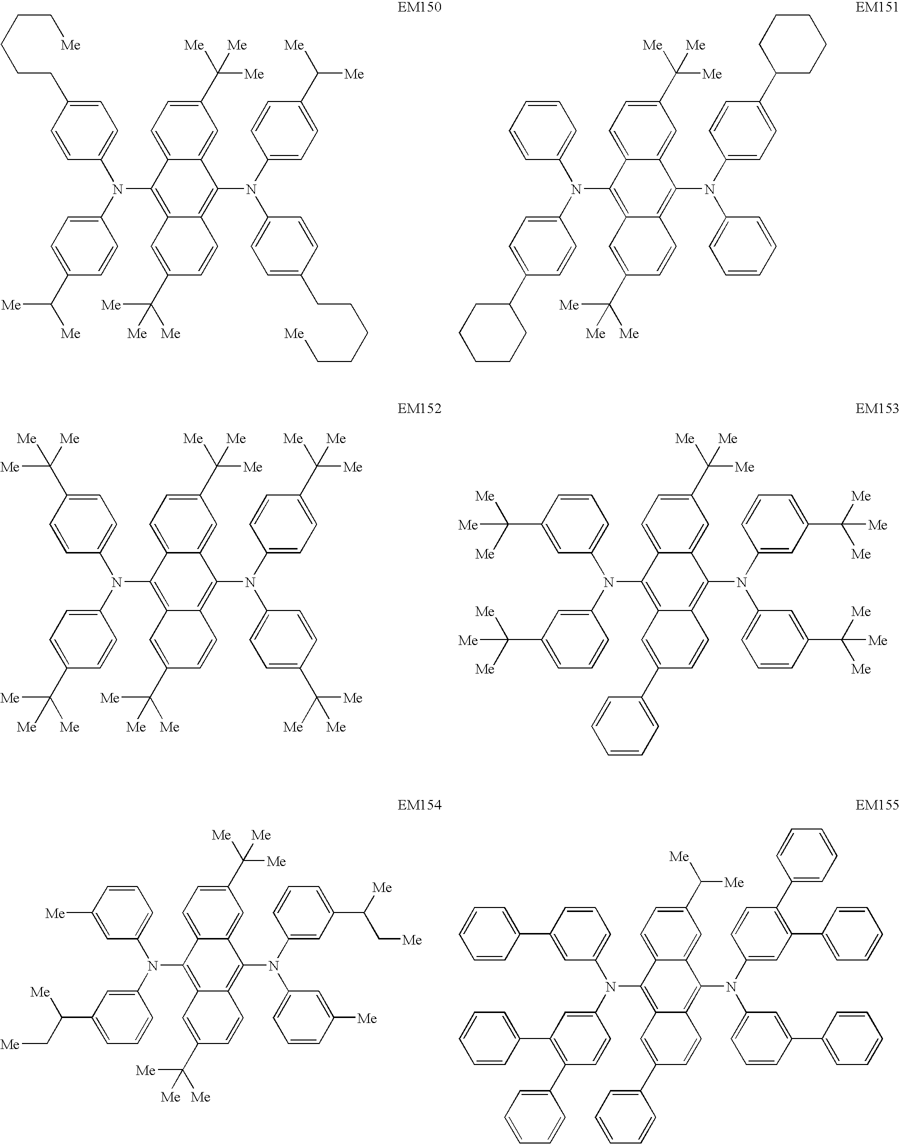

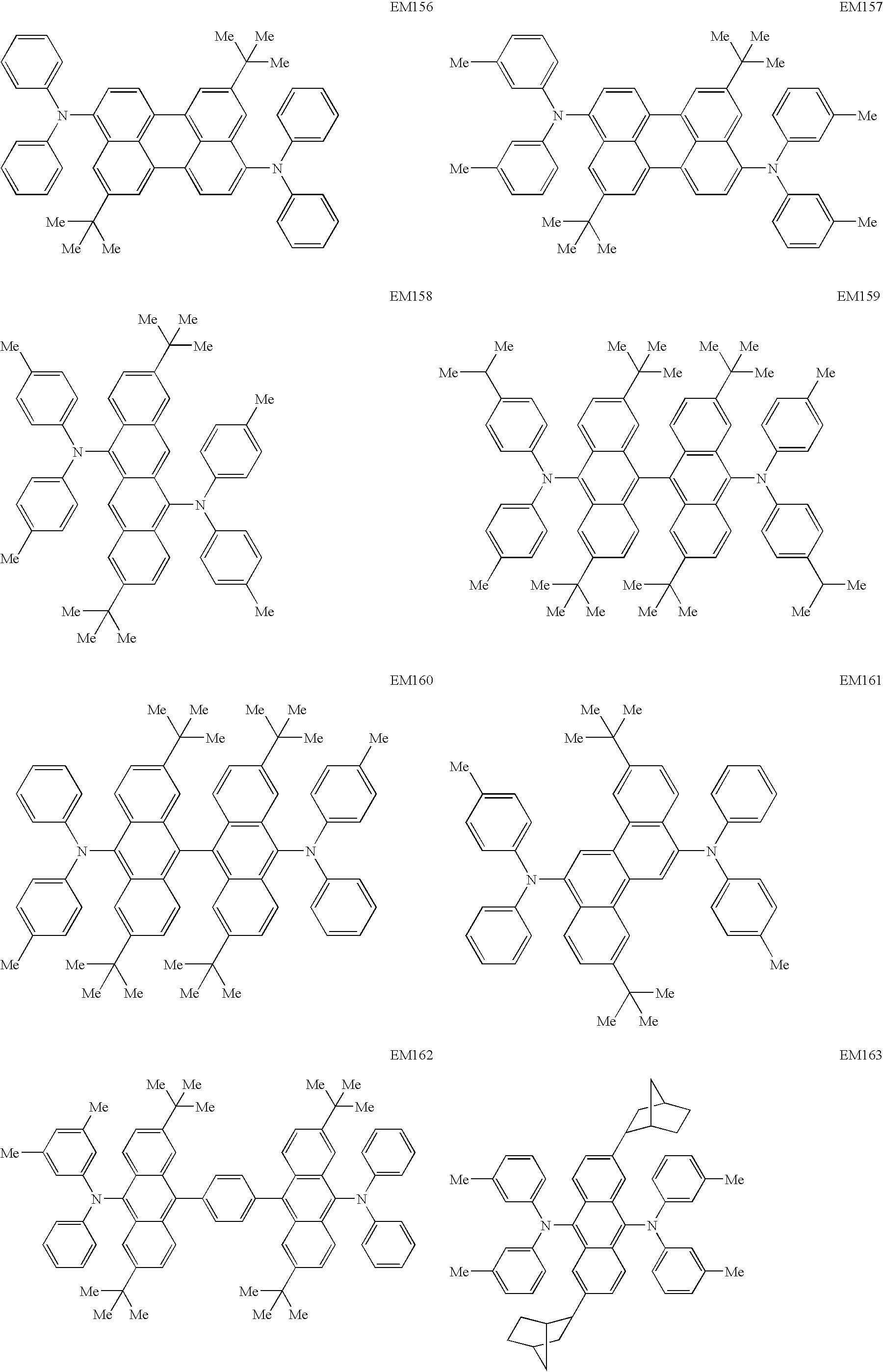

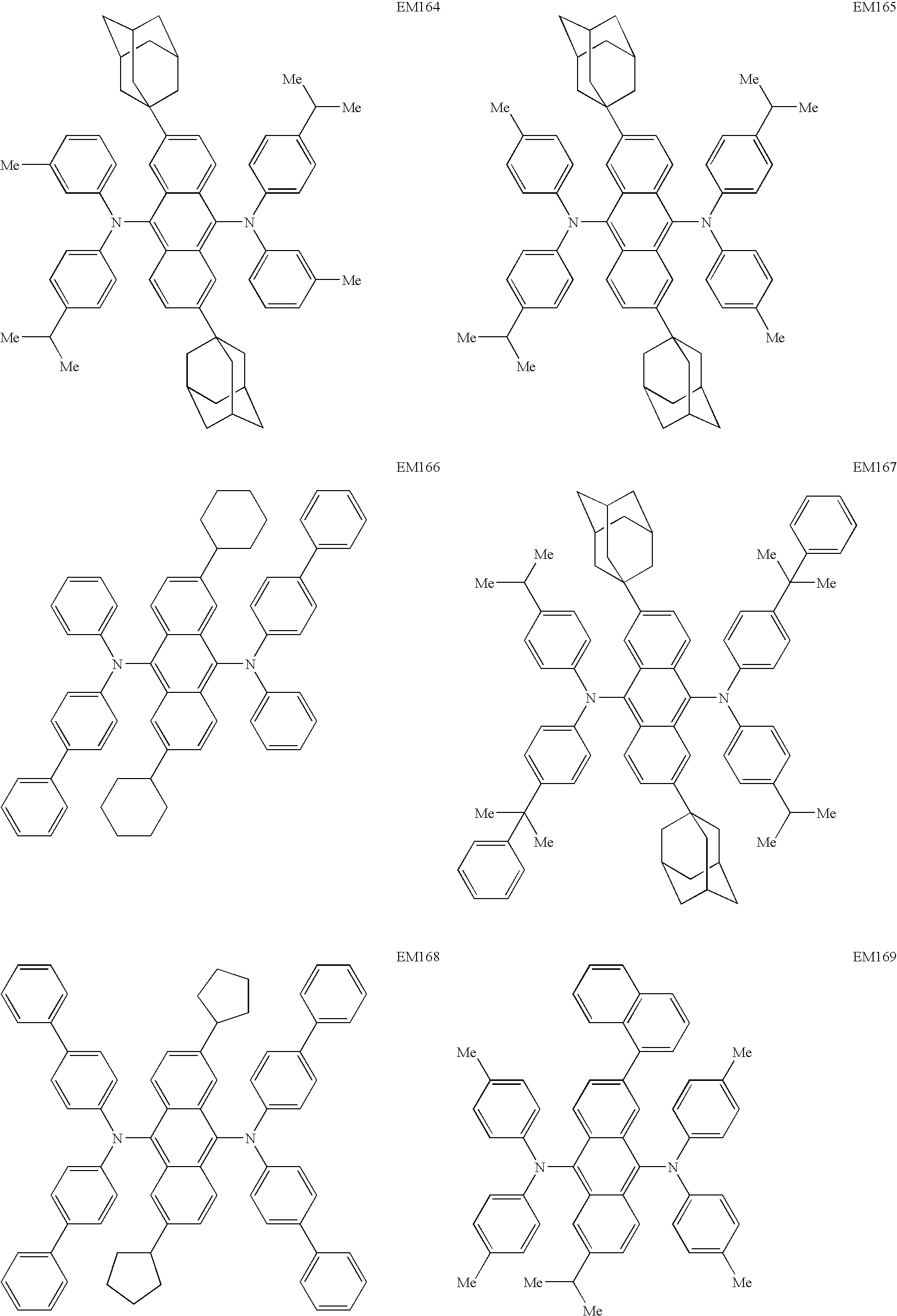

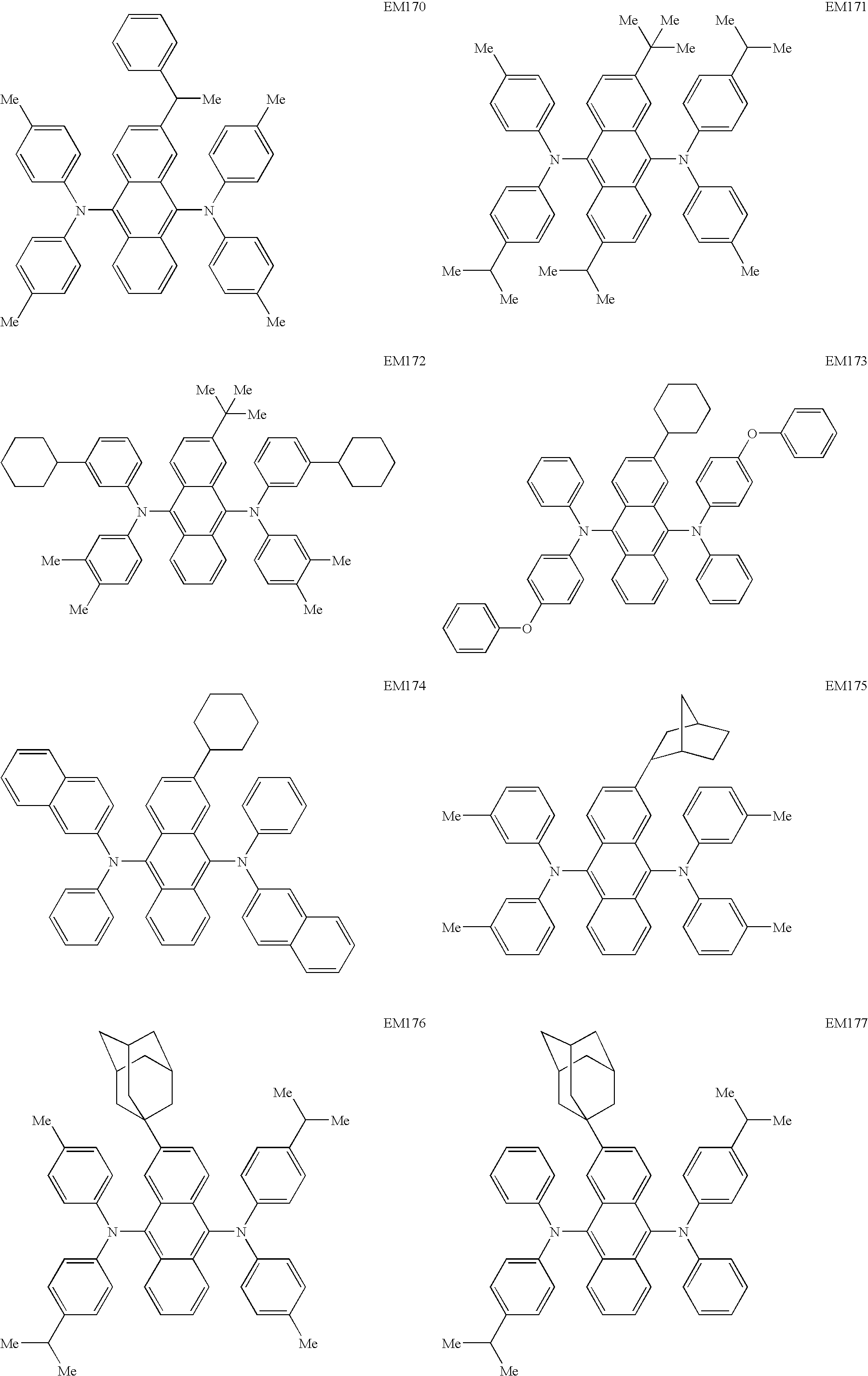

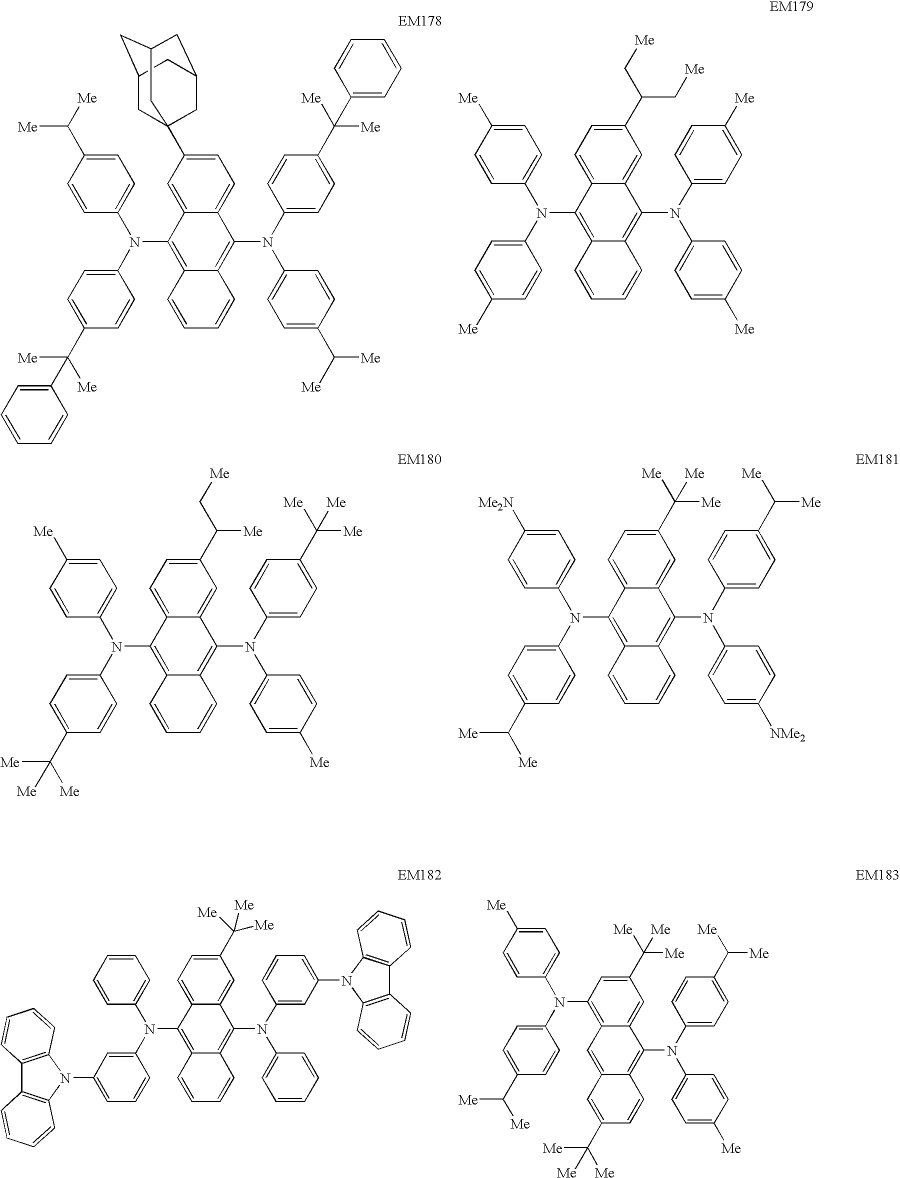

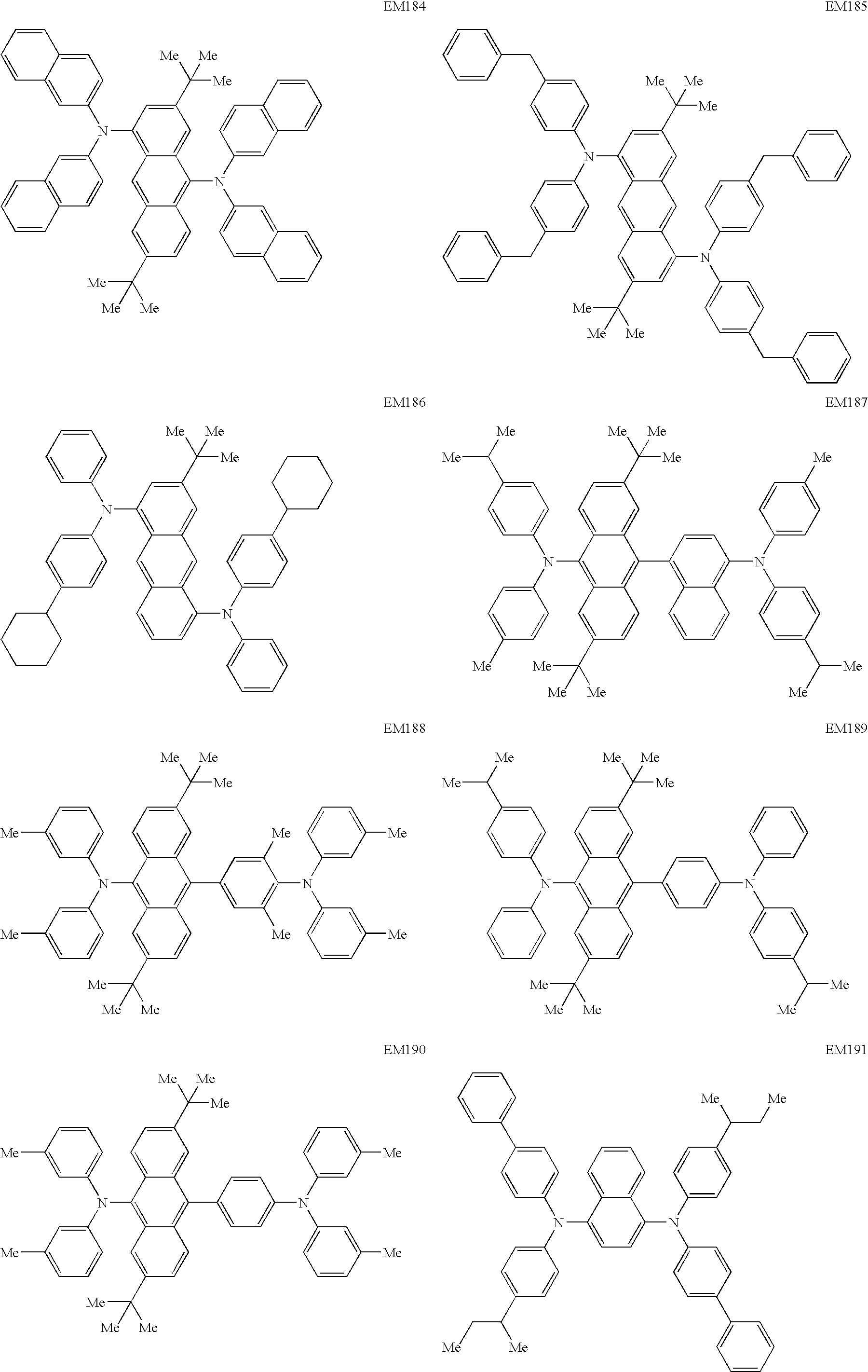

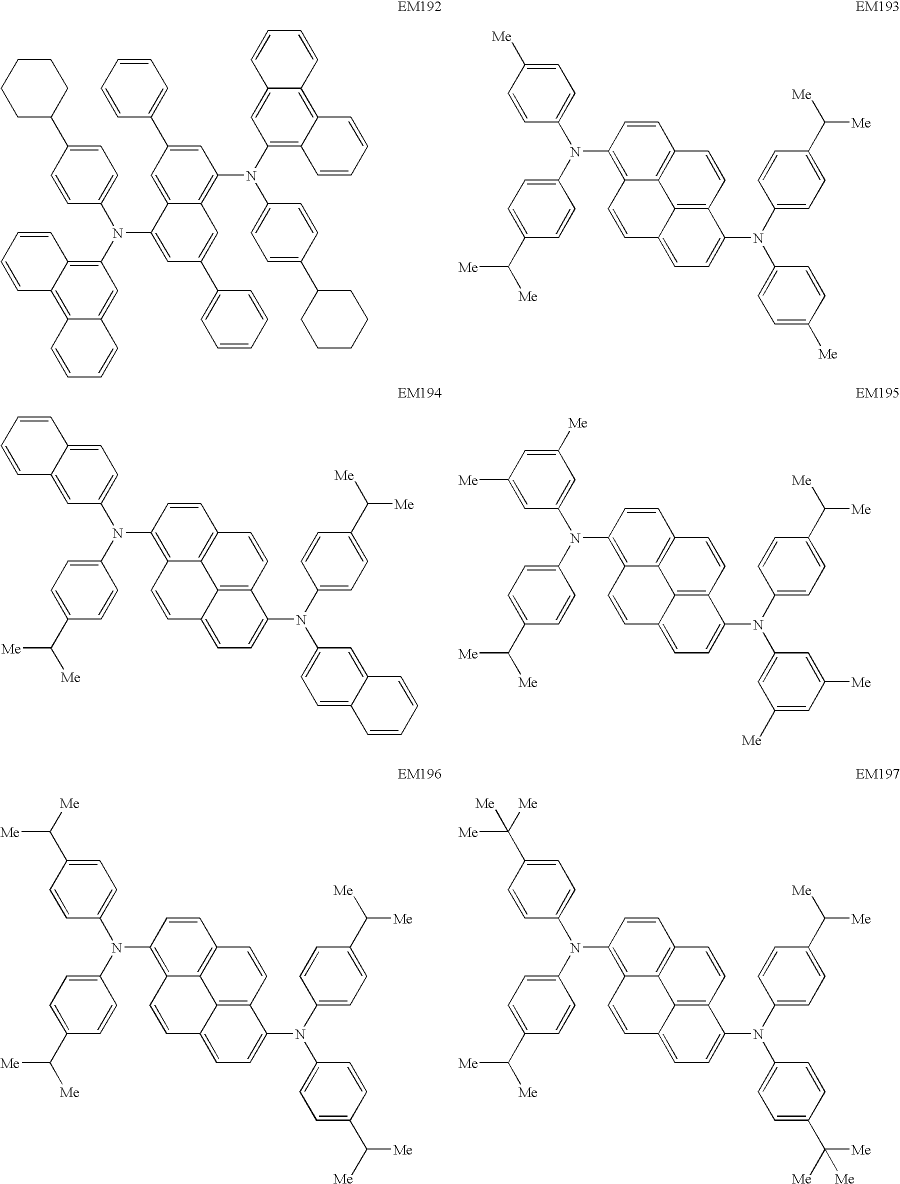

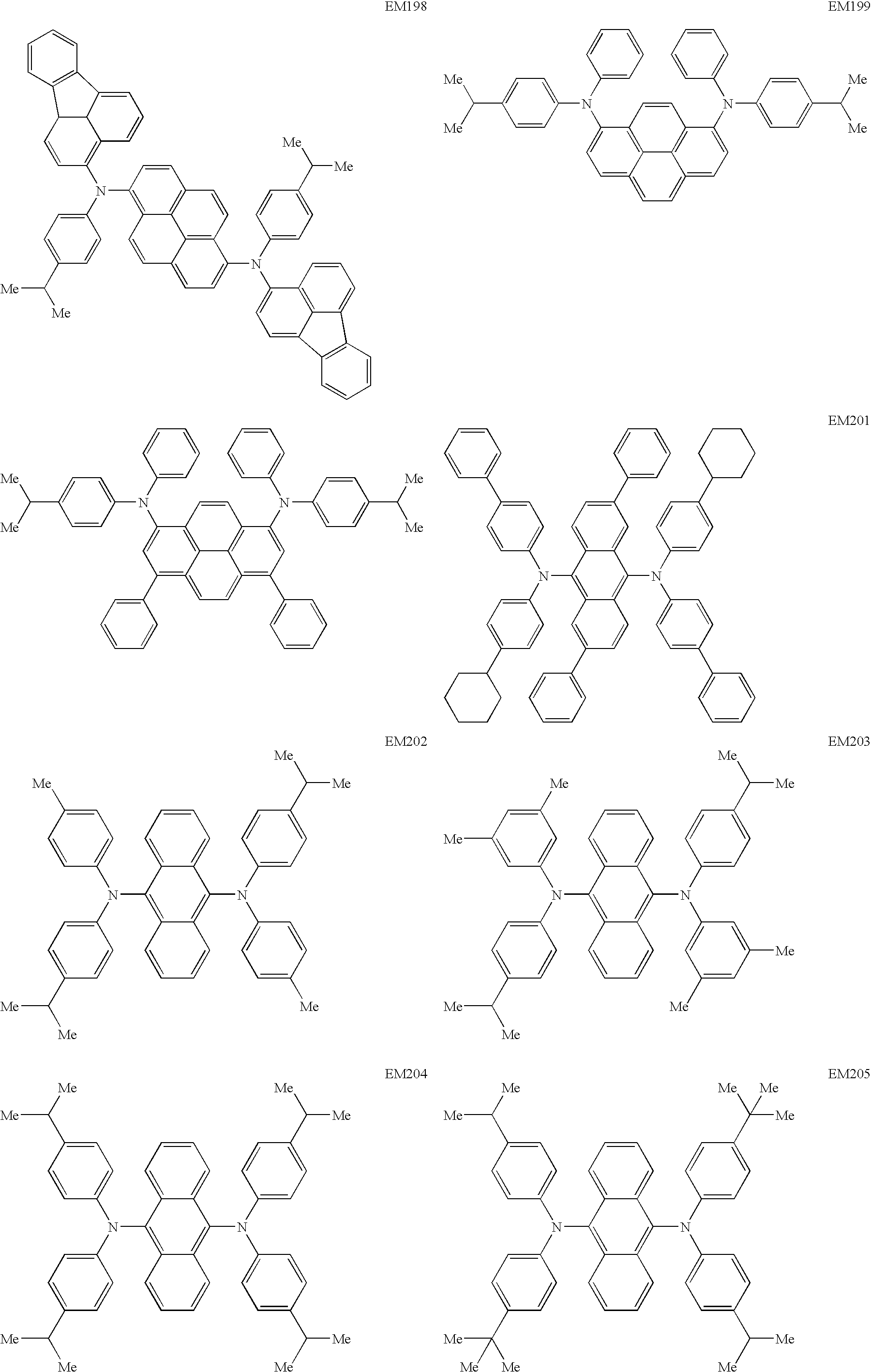

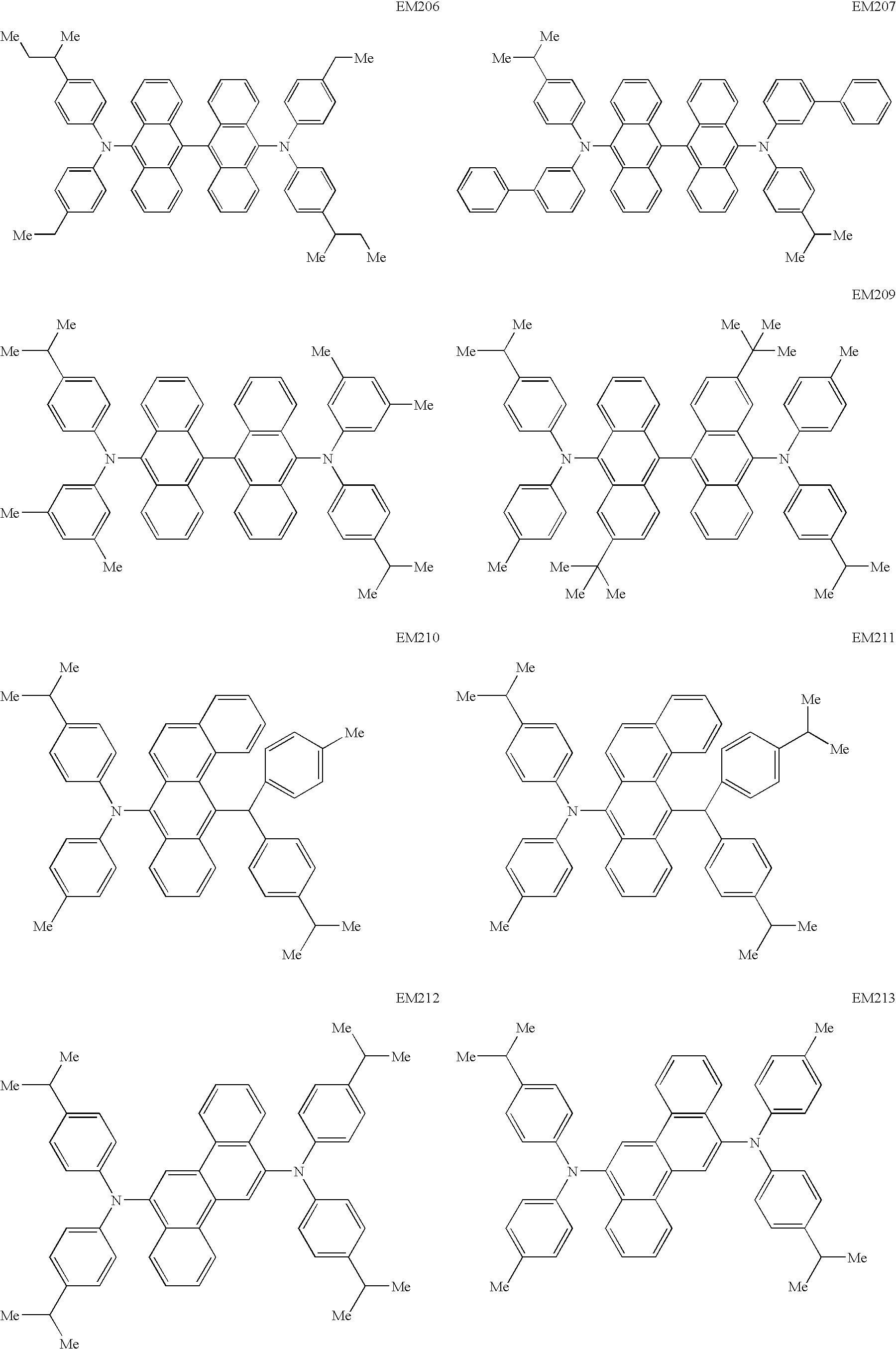

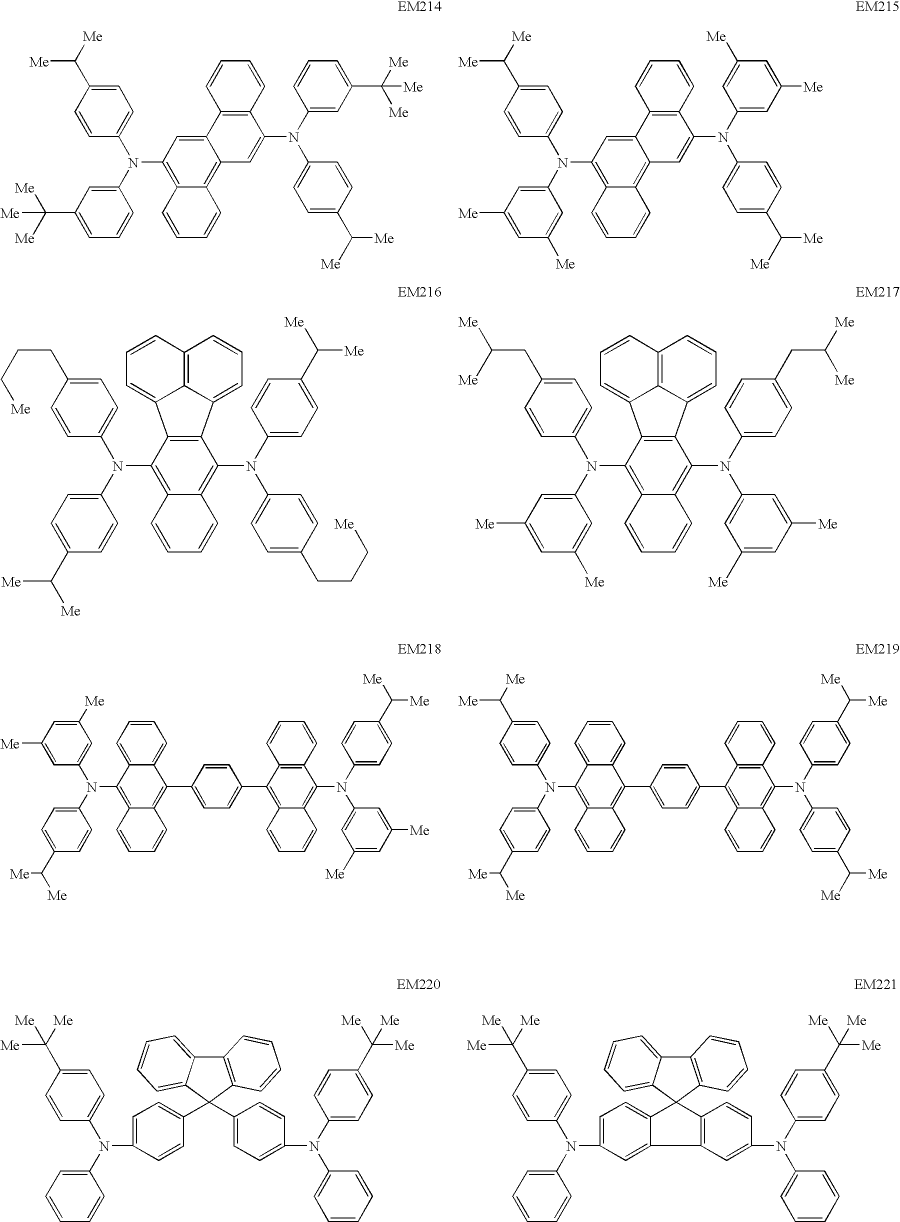

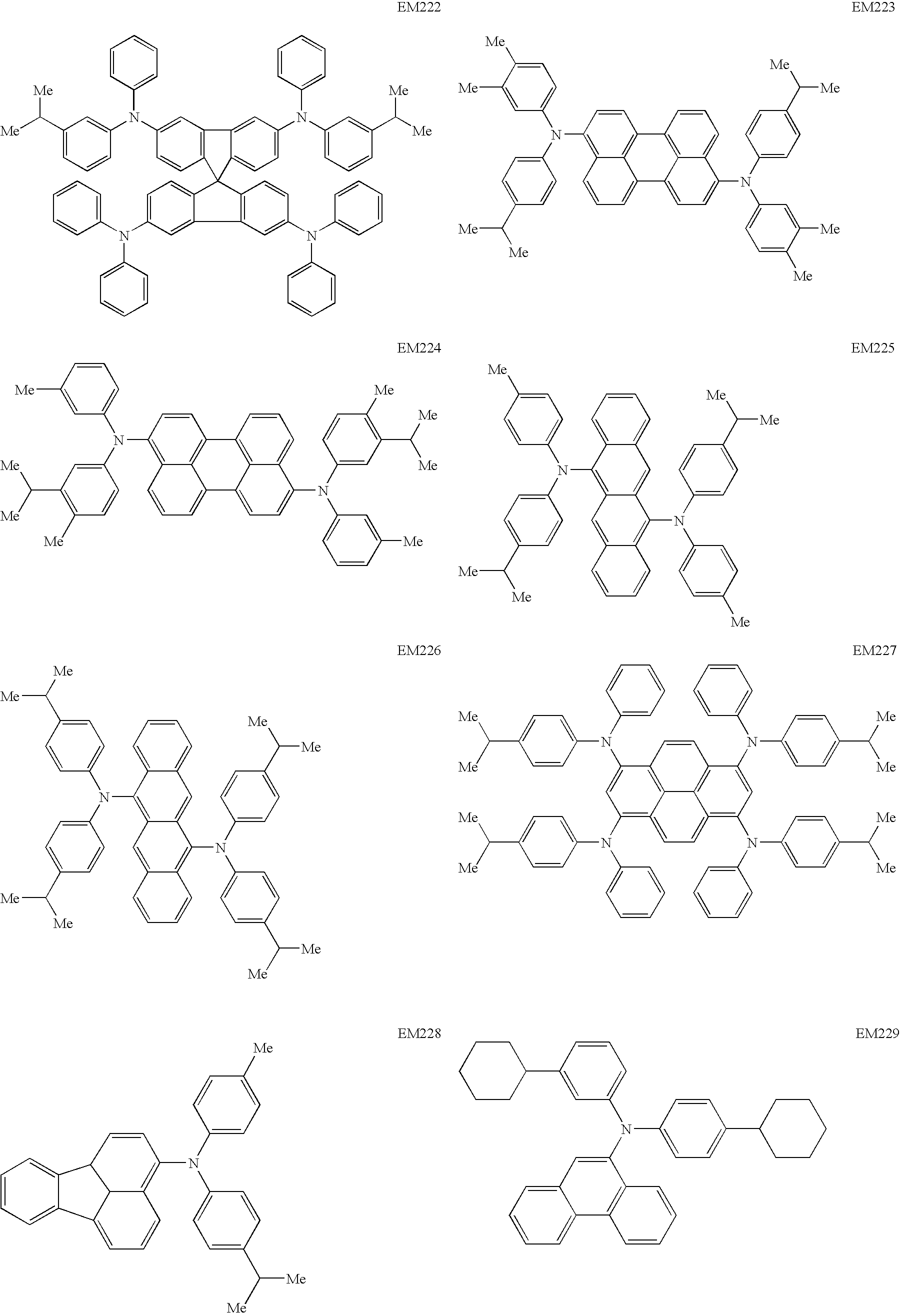

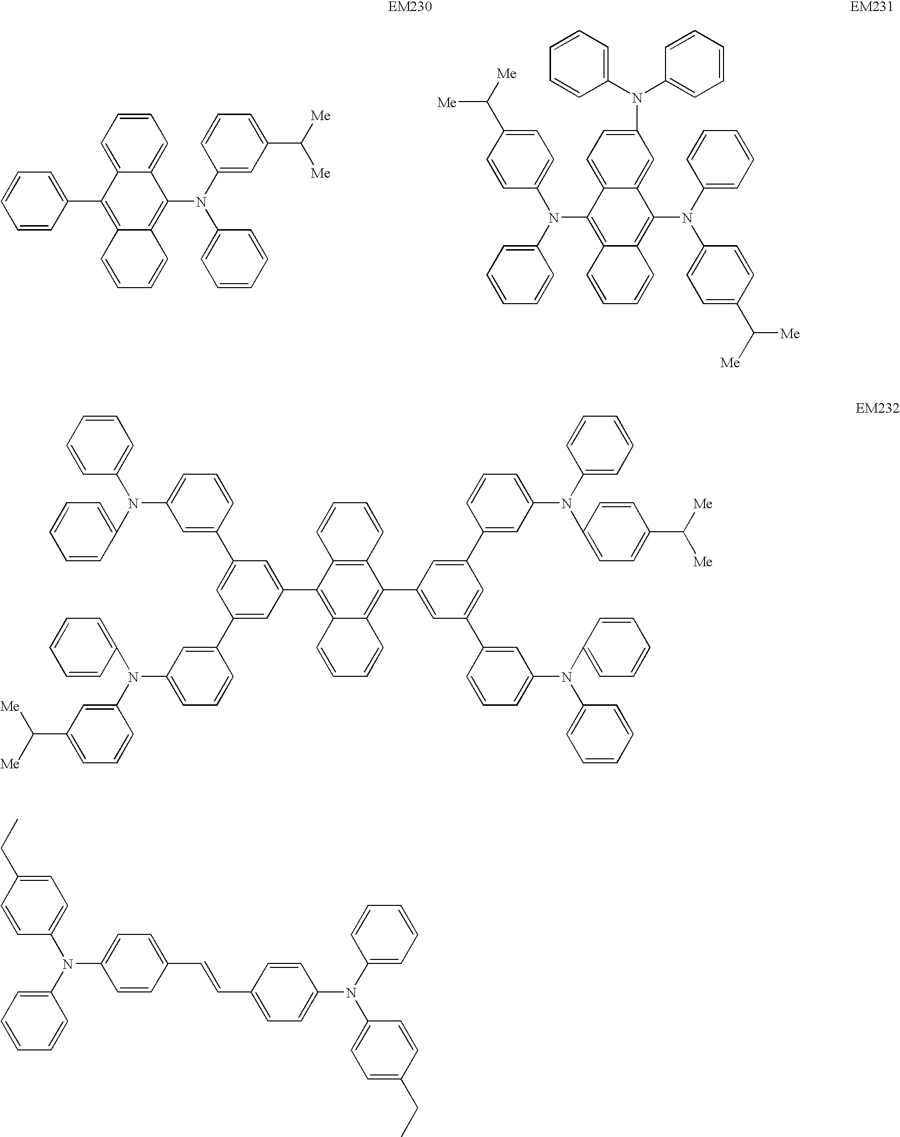

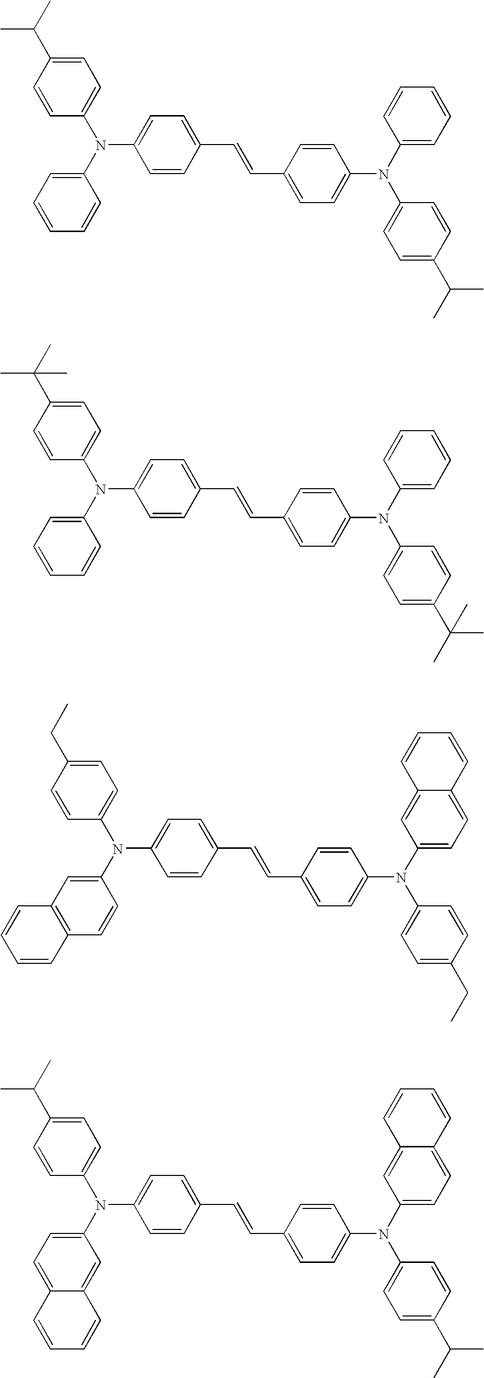

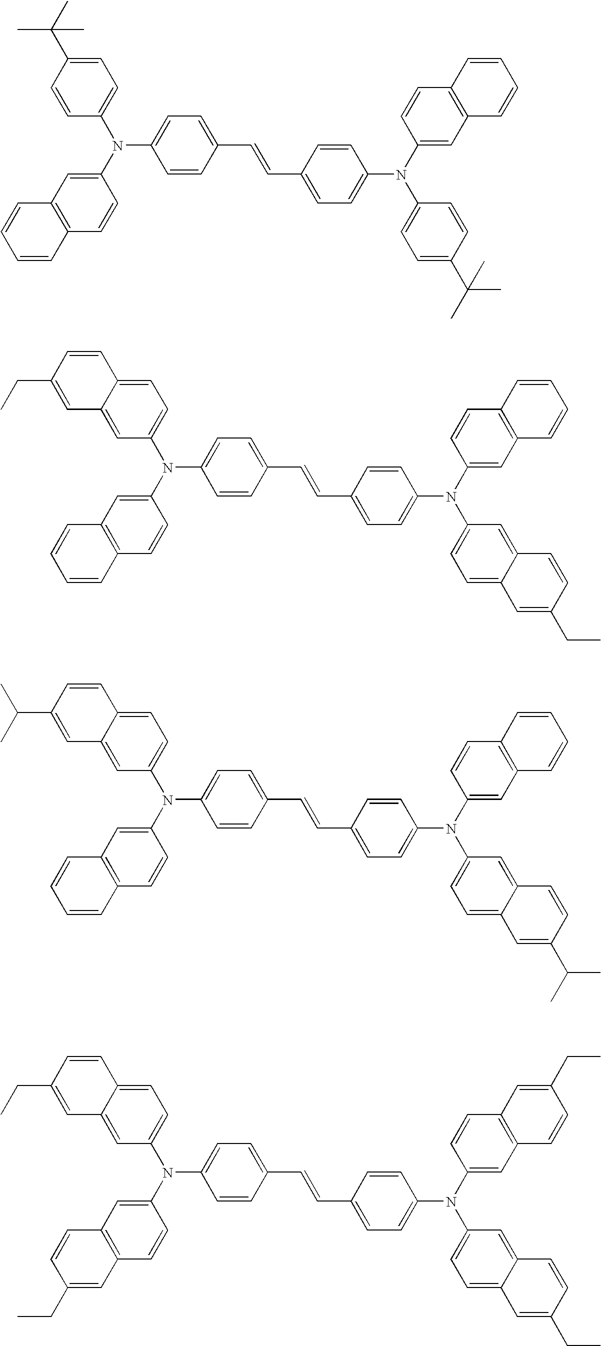

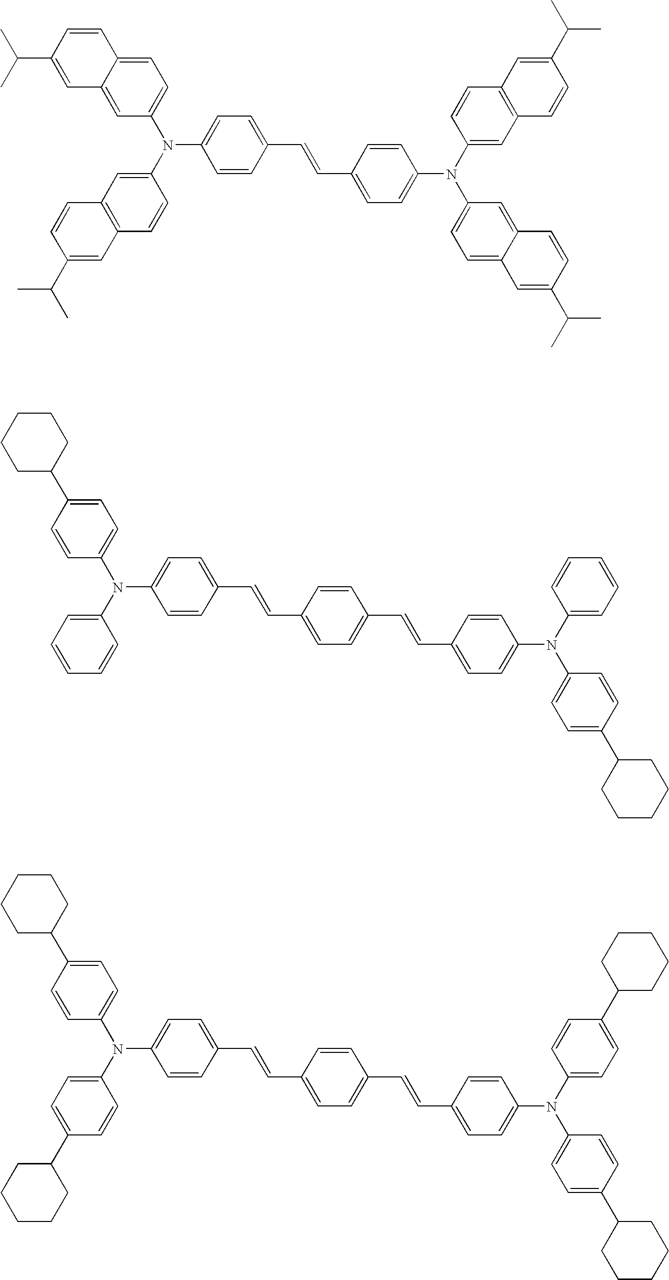

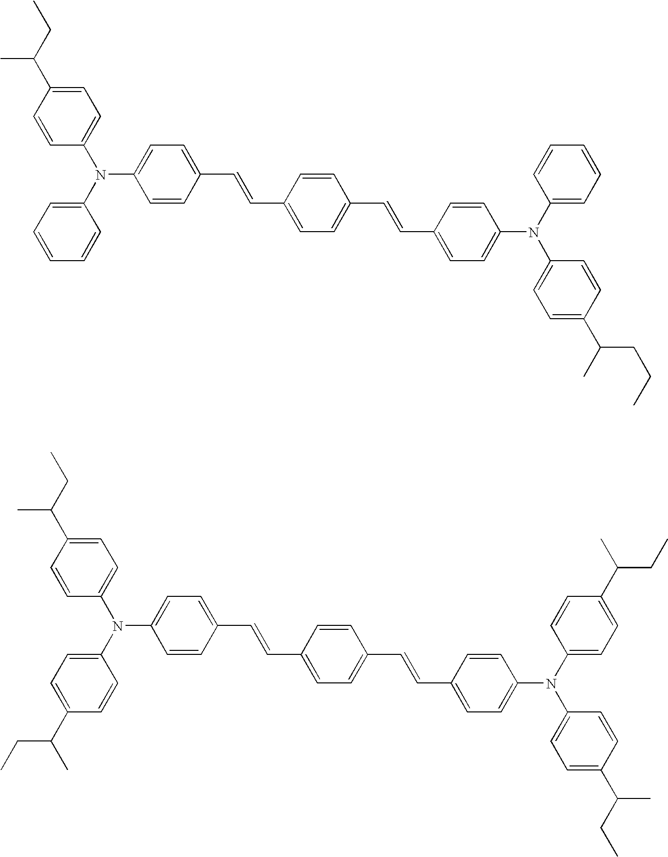

### (5) Hole Injecting/Transporting Layers (Hole Transporting Zone)

The hole injecting/transporting layer(s) helps injection of the holes into the emitting layer and transports the holes to an emitting region. In the hole injecting/transporting layer(s), the hole mobility is large while the energy of ionization is typically small (5.5 eV or smaller). A material of the hole injecting/transporting layer(s) is preferably such a material that transports the holes to the emitting layer with a lower field intensity, and more preferably such a material that transports the holes with the hole mobility of at least 10⁻⁴ cm²/Vs when the exemplary electrical field of 10⁴ to 10⁶ V/cm is applied.

In the organic electroluminescence device according to the present embodiment, the hole injecting layer contains poly(alkylene dioxythiophene) and at least one fluorine-containing colloid-forming polymer acid.

The poly(alkylene dioxythiophene) is poly(3,4-dioxythiophene).

The fluorine-containing colloid-forming polymer acid is a fluorine-containing polymer sulfonic acid, a fluorine-containing polymer carboxylic acid, a fluorine-containing polymer phosphoric acid, a fluorine-containing polymer acrylic acid or a mixture of the above.

The fluorine-containing colloid-forming polymer acid is preferably a perfluorinated polymer acid.

A colloid-forming polymer acid usable in implementing the present invention is insoluble in water. When dispersed in an aqueous medium, the colloid-forming polymer acid forms a colloid. A molecular weight of a polymer acid is typically in a range of approximately 10,000 to approximately 4,000,000. In one embodiment, the molecular weight of a polymer acid is in a range of approximately 100,000 to approximately 2,000,000. A diameter of a colloid particle is typically in a range of 2 nanometer (nm) to approximately 140 nm. In one embodiment, the diameter of a colloid particle is in a range of 2 nm to approximately 30 nm. Any polymer acid may be preferably used in implementing the present invention as long as the polymer acid forms a colloid when dispersed in water. In one embodiment, the colloid-forming polymer acid is a polymer sulfonic acid. Examples of another usable polymer acid are a polymer phosphoric acid, a polymer carboxylic acid and a polymer acrylic acid. Mixtures of the above polymer acids, an example of which is a mixture containing a polymer sulfonic acid, are also usable. In another embodiment, the colloid-forming polymer sulfonic acid is perfluorinated. In a still further embodiment, the colloid-forming polymer sulfonic acid is a perfluoro alkylene sulfonic acid.

In a still further embodiment, the colloid-forming polymer acid is a highly-fluorinated sulfonate polymer (FSA polymer). “highly-fluorinated” means that: at least approximately 50% of the total halogens and hydrogen atoms contained in the polymer are substituted by fluorine atoms; at least approximately 75% thereof are substituted by fluorine atoms in one embodiment; and at least approximately 90% thereof are substituted by fluorine atoms in another embodiment. In one embodiment, the polymer is perfluorinated. A term “sulfonate functional group” herein means either one of a sulfonate group and a salt of a sulfonate group. In one embodiment, the term means either one of an alkali metal and an ammonium salt. The functional group is represented by a formula of —SO₃X (where X represents a cation, which is also known as “counterion”). X may be H, Li, Na, K or N(R₁)(R₂)(R₃)(R₄), in which R₁, R₂, R₃ and R₄ may be the same or different from one another. In one embodiment, R₁, R₂, R₃ and R₄ are H, CH₃ or C₂H₅. In another embodiment, X is H. In such an embodiment, the polymer is said to be in an “acid form”. In addition, X may be multivalent as represented by an ion such as Ca⁺⁺ and Al⁺⁺⁺. When a multivalent counterion as generally represented by Mn⁺ is concerned, a person skilled in the art will clearly understand that the number of sulfonate functional group(s) per counterion is equal to the valence number “n” of the counterion.

In one embodiment, the FSA polymer contains a polymer main chain in which a repeated side chain(s) having a cation-exchange group is bonded to a main chain. The polymer may be a homopolymer or a copolymer of plural monomers. The copolymer is typically formed from a non-functionalized monomer and a second monomer having a cation-exchange group or its precursor such as a sulfonyl fluoride group (—SO₂F) that can be subsequently hydrolyzed to sulfonate functional group. For instance, a copolymer of a first fluorinated vinyl monomer and a second fluorinated vinyl monomer having a sulfonyl fluoride group (—SO₂F) may be used as the copolymer. Examples of a monomer usable as the first monomer are tetrafluoroethylene (TFE), hexafluoropropylene, fluorinated vinyl, fluorinated vinylidene, trifluoroethylene, chlorotrifluoroethylene, perfluoro(alkyl vinyl ether) and a combination of the above monomers. The first monomer is preferably TFE.

In another embodiment, a monomer usable as the second monomer may be fluorinated vinyl ether having a sulfonate functional group or a precursor group capable of providing a desirable side chain(s) to the polymer. An additional monomer such as ethylene, propylene and R—CH═CH₂ (where R is a perfluorinated alkyl group having 1 to 10 carbon atoms) may be added into the above polymers as necessary. The polymer may be a copolymer that is herein called a random copolymer, i.e., a copolymer manufactured by polymerization where a relative concentration of the comonomer is kept as constant as possible so that a distribution of monomer units along the polymer chain consequently corresponds to relative concentrations and relative reactivity of the monomer units. A less random copolymer manufactured by changing the relative concentrations of monomers during polymerization is also usable. Such a polymer as disclosed in Document 2, which is called a block copolymer, is also usable.

According to one embodiment, the FSA polymer to be used in the present invention contains a highly-fluorinated carbon main chain and side chain(s) represented by a formula as follows while the carbon main chain may be perfluorinated in another embodiment:

—(O—CF₂CFR_{f})ₐ—O—CF₂CFR′_{f}SO₃X

(In the formula: R_{f} and R′_{f} are each selected from a group consisting of F, Cl and a perfluorinated alkyl group having 1 to 10 carbon atoms; “a” is any one of 0, 1 and 2; and X is any one of H, Li, Na, K and N(R₁)(R₂)(R₃)(R₄), in which the R₁, R₂, R₃ and R₄ may be mutually the same or different, the R₁, R₂, R₃ and R₄ being H, CH₃ or C₂H₅ in one embodiment). In another embodiment, the X is H. As described above, the X may also be multivalent.

In one embodiment, the FSA polymer contains such a polymer as disclosed in U.S. Pat. No. 3,282,875, U.S. Pat. No. 4,358,545 and U.S. Pat. No. 4,940,525. A preferable example of the FSA polymer contains a perfluorocarbon main chain and a side chain(s) represented by a formula as follows:

—O—CF₂CF(CF₃)—O—CF₂CF₂SO₃X

(where X is defined as above). The above type of the FSA polymer, which is disclosed in U.S. Pat. No. 3,282,875, can be manufactured by: copolymerizing tetrafluoroethylene (TFE) and perfluorinated vinyl ether CF₂═CF—O—CF₂CF(CF₃)—O—CF₂CF₂SO₂F (perfluoro(3,6-dioxa-4-methyl-7-octene sulfonyl fluoride)) (PDMOF); subsequently converting the sulfonyl fluoride group into a sulfonate group by hydrolysis; and converting the above into desirable ion form by ion exchange as necessary. Such a polymer as disclosed in U.S. Pat. No. 4,358,545 and U.S. Pat. No. 4,940,525 contains side chain(s) represented by —O—CF₂CF₂SO₃X where X is defined as above. Such a polymer can be manufactured by: copolymerizing tetrafluoroethylene (TFE) and perfluorinated vinyl ether CF₂═CF—O—CF₂CF₂SO₂F (perfluoro(3-oxa-4-pentene sulfonyl fluoride)) (POPF); subsequently hydrolyzing the above; and further performing ion exchange as necessary.

In one embodiment, the FSA polymer to be used in the present invention typically has an ion-exchange ratio of less than approximately 33. The “ion-exchange ratio” or “IXR” herein is defined as the number of carbon atoms included in a polymer main chains in relation to a cation-exchange group. IXR may be changed within a range of less than approximately 33 to be suitable for a specific use. IXR is in a range of approximately 3 to 33 in one embodiment while in a range of approximately 8 to 23 in another embodiment.

Cation-exchange capacity of the polymer is frequently represented in equivalent weight (EW). The equivalent weight (EW) herein is defined as a weight of a polymer in an acid form required for neutralizing 1 equivalent weight of sodium hydrate. When a polymer is a sulfonate polymer that has a perfluorocarbon main chain and side chain(s) of —O—CF₂—CF(CF₃)—O—CF₂—CF₂—SO₃H (or a salt thereof), the IXR in the range of approximately 8 to 23 corresponds to an equivalent-weight range of approximately 750 to 1500 EW. The IXR of this polymer can be related to the equivalent weight by using a formula of 50 IXR+344=EW. Although the same IXR range may be used for, for instance, polymer(s) containing the side chain(s) of —O—CF₂CF₂SO₃H (or a salt thereof) among the sulfonate polymers disclosed in U.S. Pat. No. 4,358,545 and U.S. Pat. No. 4,940,525, the equivalent weights thereof are lowered by some degree due to lower molecular weights of monomer units containing cation-exchange groups. The preferable IXR range of approximately 8 to 23 corresponds to an equivalent-weight range of approximately 575 to 1325 EW. The IXR of this polymer can be related to the equivalent weight by using a formula of 50+IXR 178=EW.

The FSA polymer may be manufactured as a colloidal aqueous dispersion solution. The polymer may be a dispersion solution using another medium. Such medium are exemplarily water-soluble ether such as alcohol and tetrahydrofuran, a mixture of water-soluble ether and combinations thereof but are not limited to the above. In manufacturing a dispersion solution, the polymer may be used in acid form. U.S. Pat. No. 4,433,082, U.S. Pat. No. 6,150,426 and International Publication No. 03/006537 disclose a manufacturing method of an aqueous alcoholic dispersion solution. After a dispersion solution is manufactured, the concentration of the solution and compositions made therefrom can be adjusted by a method publicly known in the art.

An aqueous dispersion solution of a colloid-forming polymer acid such as the FSA polymer typically forms colloid of as small particle diameter as possible and has as small EW as possible, as long as stable colloid is formed.

An aqueous dispersion solution of the FSA polymer is commercially available as Nafion (Registered Trademark) dispersion solution from E.I. du Pont de Nemours and Company (Wilmington, Del.).

### (6) Electron Injecting/Transporting Layers (Electron Transporting Zone)

The electron injecting/transporting layer may further be laminated between the organic emitting layer and the cathode. The electron injecting/transporting layer, which helps injection of the electron into the emitting layer, has a high electron mobility.

In the organic electroluminescence device, since emitted light is reflected by an electrode (the cathode, in this case), light directly provided through the anode and the light provided after being reflected by the electrode are known to interfere with each other. In order to efficiently utilize the interference, the thickness of the electron transporting layer is suitably selected from the range of several nanometers to several micrometers. However, especially when the thickness of the layer is large, the electron mobility is preferably at least 10⁻⁵ cm²/Vs or higher so as to prevent voltage rise when the electrical field of 10⁴ to 10⁶ V/cm is applied.

In the organic electroluminescence device according to the present embodiment, the electron transporting layer contains a compound having electron mobility of 1×10⁻⁴ to 1×10⁻² cm²/Vs at an electric field intensity of 2.5×10⁵V/cm. Particularly, the electron transporting layer preferably contains a nitrogen-containing heterocycle derivative represented by the following formula (1).

HAr-L-Ar¹—Ar² (1)

In the above formula (1): HAr represents a substituted or unsubstituted nitrogen-containing heterocycle group having 3 to 40 carbon atoms;

L represents a single bond, a substituted or unsubstituted arylene group having 6 to 60 carbon atoms, a substituted or unsubstituted heteroarylene group having 3 to 60 carbon atoms, or a substituted or unsubstituted fluorenylene group;

Ar¹ represents a substituted or unsubstituted divalent aromatic hydrocarbon group having 6 to 60 carbon atoms; and

Ar² represents a substituted or unsubstituted aryl group having 3 to 60 carbon atoms.

Examples of such a nitrogen-containing heterocycle derivative are shown below. However, the present invention is not limited to exemplification as follows.

HAr-L-Ar¹—Ar²

| | HAr | L | Ar¹ | Ar² |
|---|---|---|---|---|
| 1-1 | 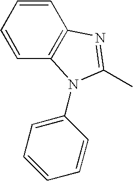 | 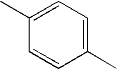 | 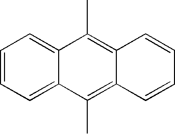 | 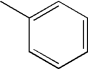 |
| 2 | 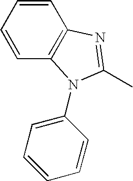 | 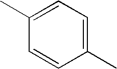 | 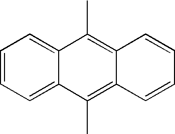 | 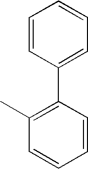 |
| 3 | 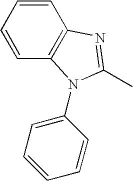 | 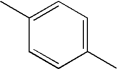 | 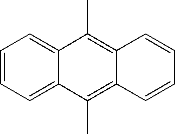 | 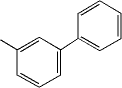 |
| 4 | 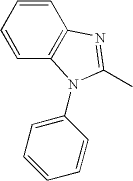 | 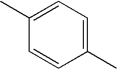 | 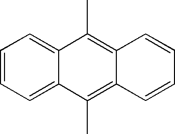 | 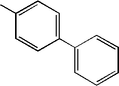 |
| 5 | 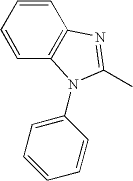 | 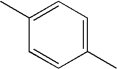 | 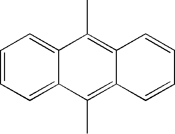 | 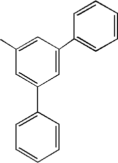 |
| 6 | 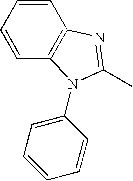 | 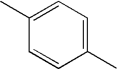 | 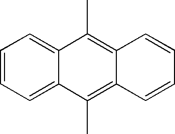 | 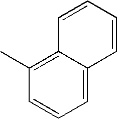 |
| 7 | 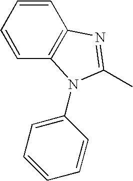 | 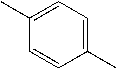 | 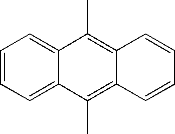 | 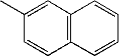 |
| 8 | 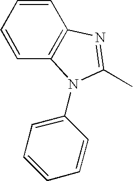 | 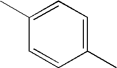 | 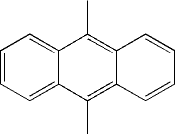 | 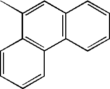 |
| 9 | 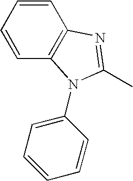 | 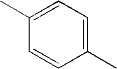 | 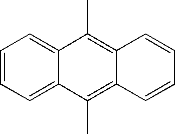 | 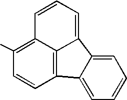 |
| 10 | 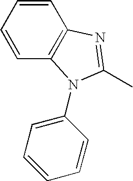 | 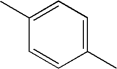 | 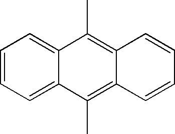 | 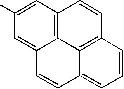 |
| 11 | 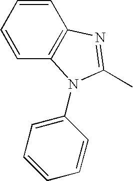 | 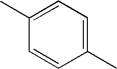 | 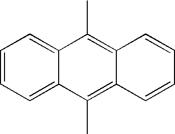 | 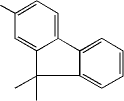 |
| 12 | 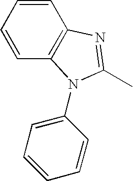 | 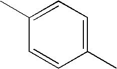 | 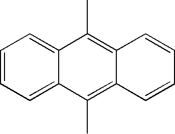 | 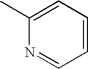 |
| 13 | 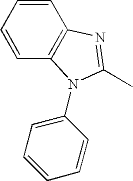 | 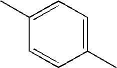 | 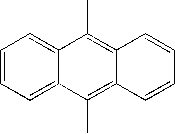 | 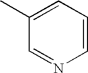 |
| 14 | 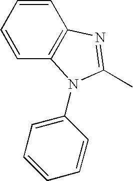 | 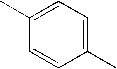 | 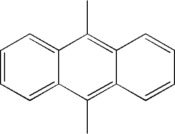 | 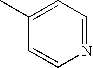 |
| 2-1 | 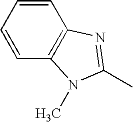 | 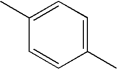 | 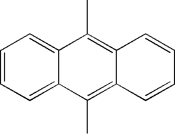 | 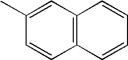 |
| 2 | 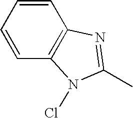 | 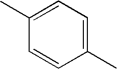 | 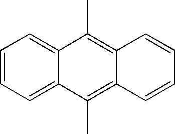 | 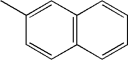 |
| 3 | 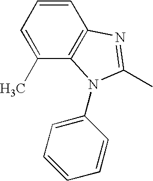 | 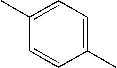 | 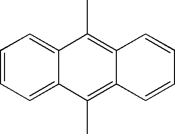 | 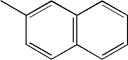 |
| 4 | 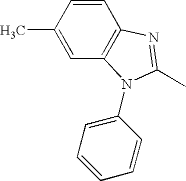 | 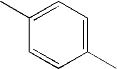 | 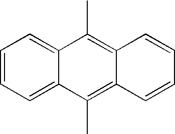 | 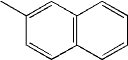 |
| 5 | 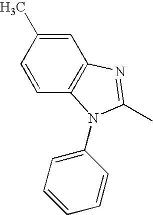 | 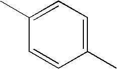 | 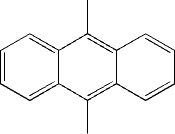 | 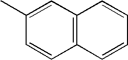 |
| 6 | 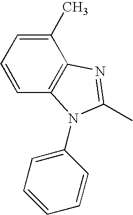 | 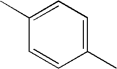 | 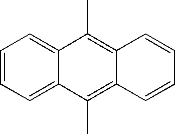 | 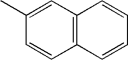 |
| 7 | 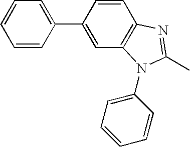 | 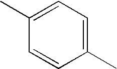 | 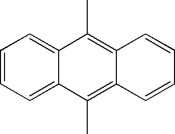 | 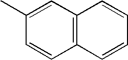 |
| 8 | 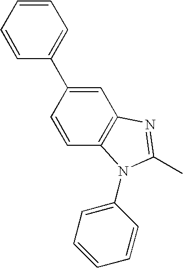 | 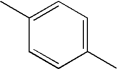 | 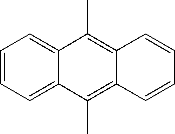 | 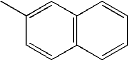 |
| 9 | 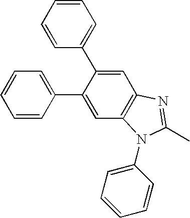 | 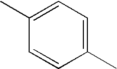 | 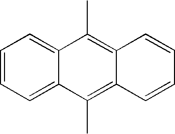 | 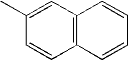 |
| 3-1 | 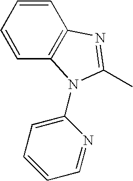 | 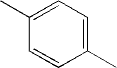 | 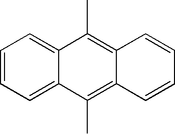 | 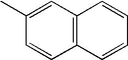 |
| 2 | 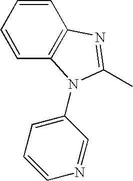 | 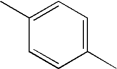 | 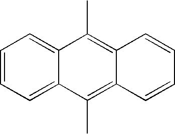 | 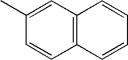 |
| 3 | 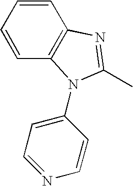 | 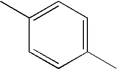 | 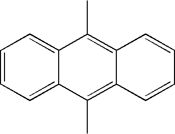 | 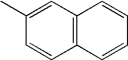 |
| 4 | 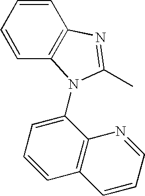 | 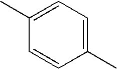 | 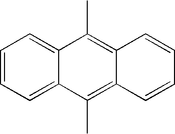 | 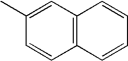 |
| 5 | 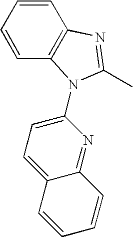 | 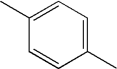 | 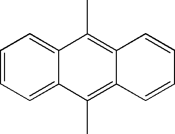 | 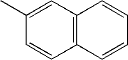 |
| 6 | 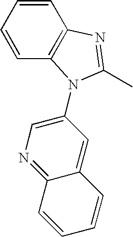 | 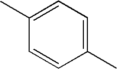 | 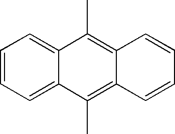 | 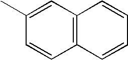 |
| 4-1 | 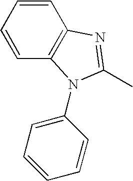 | 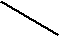 | 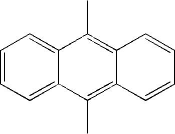 | 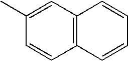 |
| 2 | 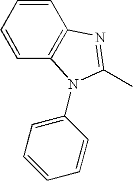 | 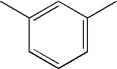 | 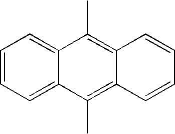 | 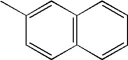 |
| 3 | 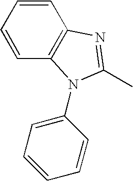 | 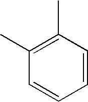 | 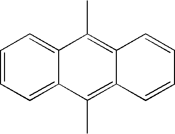 | 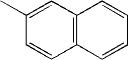 |
| 4 | 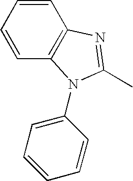 | 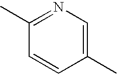 | 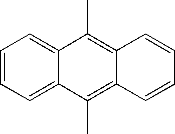 | 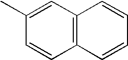 |
| 5 | 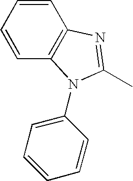 | 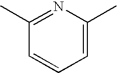 | 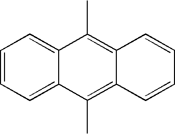 | 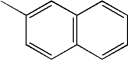 |
| 6 | 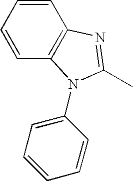 | 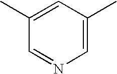 | 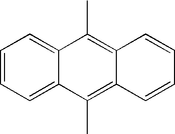 | 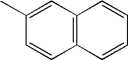 |
| 7 | 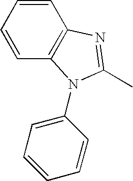 | 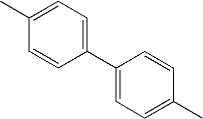 | 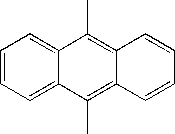 | 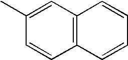 |
| 8 | 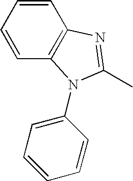 | 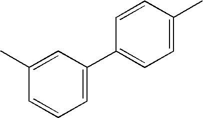 | 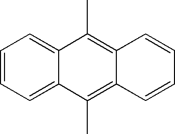 | 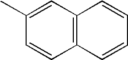 |
| 9 | 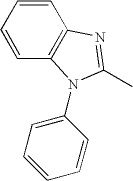 | 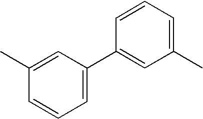 | 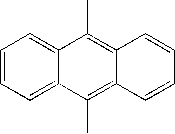 | 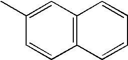 |
| 10 | 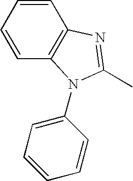 | 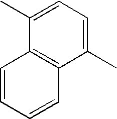 | 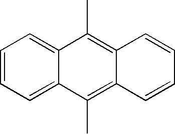 | 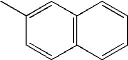 |
| 11 | 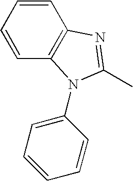 | 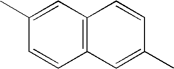 | 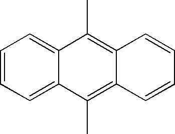 | 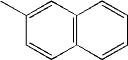 |
| 12 | 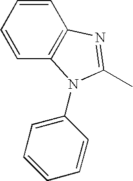 | 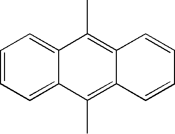 | 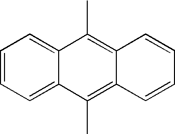 | 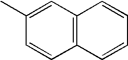 |
| 5-1 | 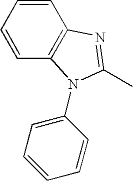 | 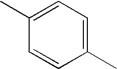 | 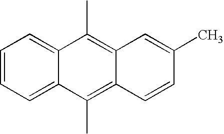 | 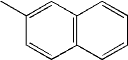 |
| 2 | 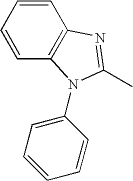 | 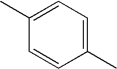 | 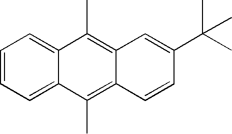 | 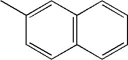 |
| 3 | 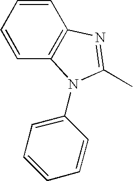 | 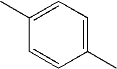 | 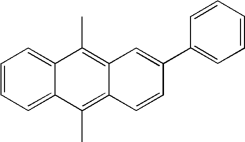 | 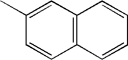 |
| 4 | 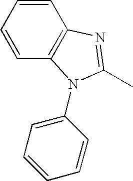 | 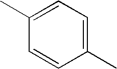 | 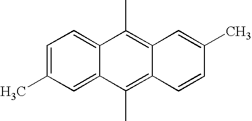 | 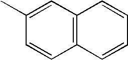 |
| 5 | 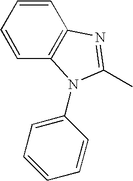 | 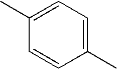 | 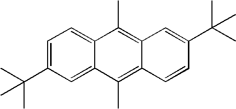 | 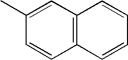 |
| 6 | 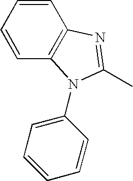 | 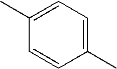 | 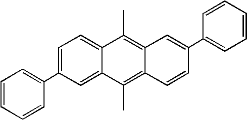 | 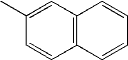 |
| 6-1 | 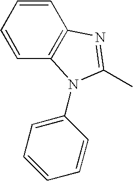 | 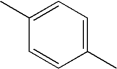 | 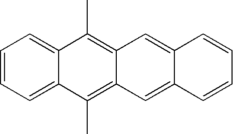 | 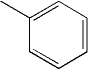 |
| 2 | 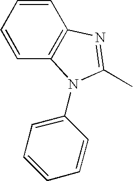 | 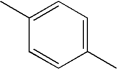 | 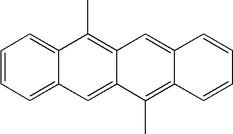 | 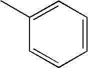 |
| 3 | 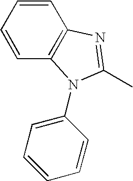 | 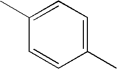 | 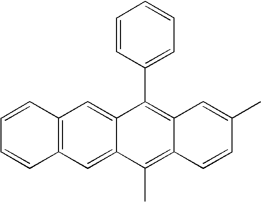 | 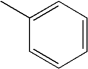 |
| 4 | 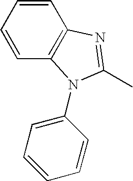 | 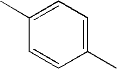 | 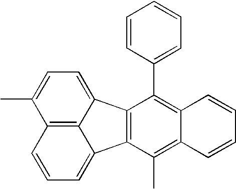 | 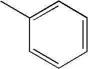 |
| 5 | 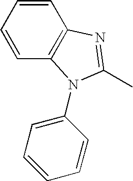 | 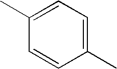 | 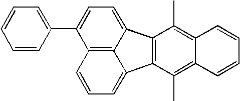 | 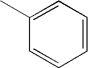 |
| 7-1 | 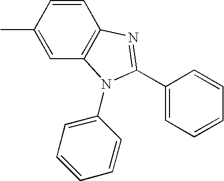 | 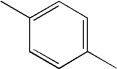 | 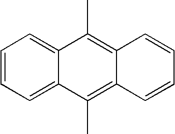 | 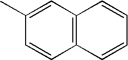 |
| 2 | 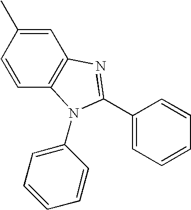 | 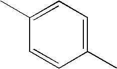 | 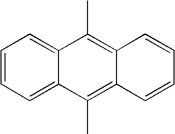 | 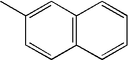 |
| 3 | 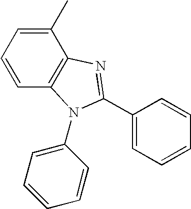 | 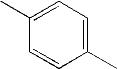 | 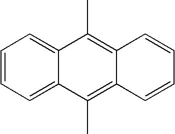 | 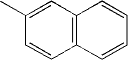 |
| 4 | 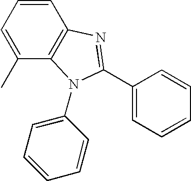 | 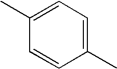 | 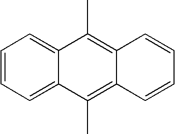 | 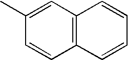 |
| 5 | 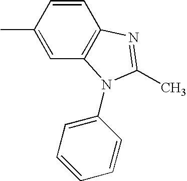 | 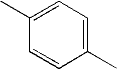 | 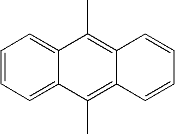 | 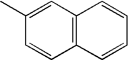 |
| 6 | 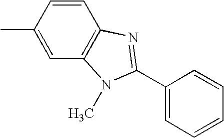 | 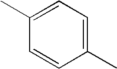 | 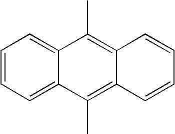 | 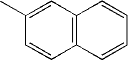 |
| 7 | 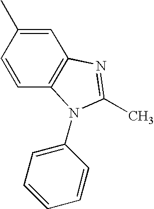 | 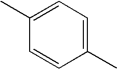 | 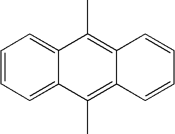 | 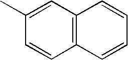 |
| 8 | 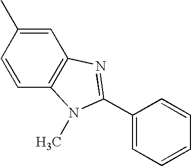 | 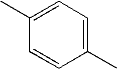 | 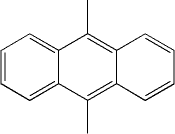 | 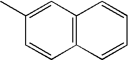 |
| 9 | 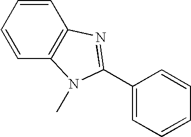 | 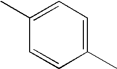 | 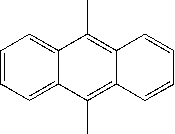 | 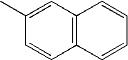 |
| 10 | 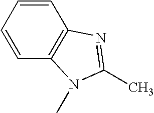 | 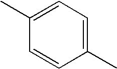 | 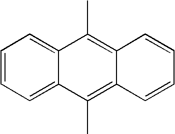 | 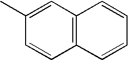 |
| 8-1 | 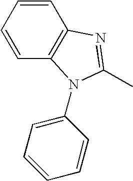 | 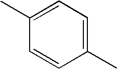 | 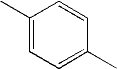 | 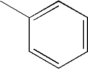 |
| 2 | 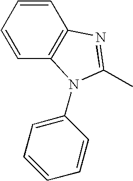 | 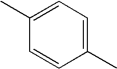 | 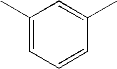 | 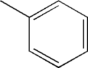 |
| 3 | 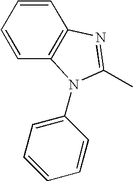 | 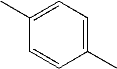 | 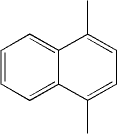 | 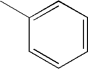 |
| 4 | 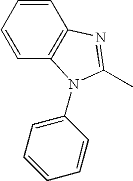 | 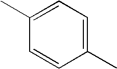 | 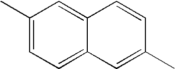 | 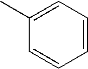 |
| 5 | 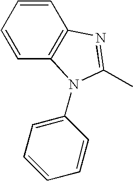 | 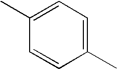 | 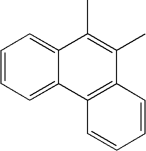 | 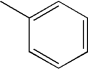 |
| 6 | 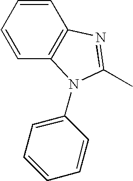 | 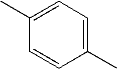 | 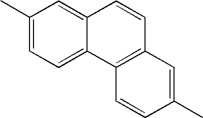 | 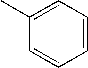 |
| 7 | 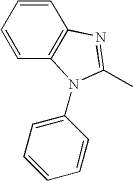 | 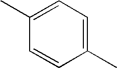 | 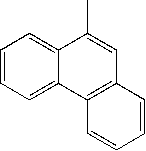 | 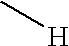 |
| 8 | 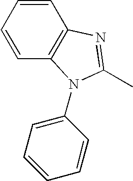 | 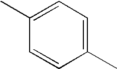 | 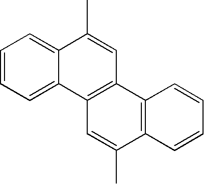 | 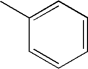 |
| 9 | 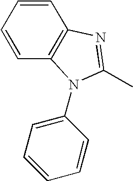 | 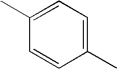 | 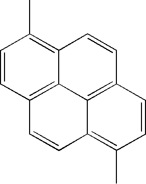 | 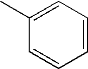 |
| 10 | 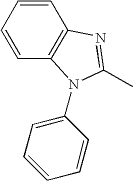 | 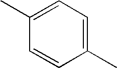 | 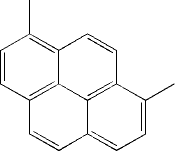 | 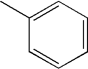 |
| 11 | 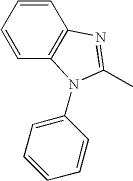 | 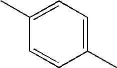 | 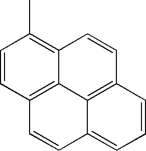 | 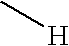 |
| 12 | 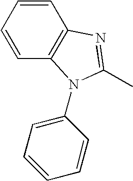 | 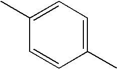 | 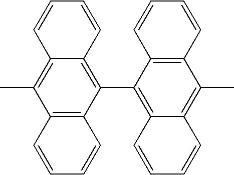 | 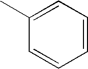 |
| 13 | 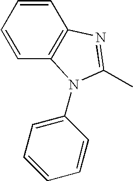 | 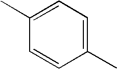 | 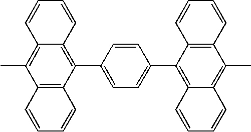 | 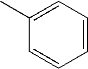 |
| 9-1 | 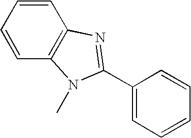 | 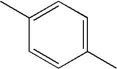 | 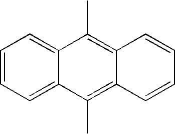 | 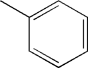 |
| 2 | 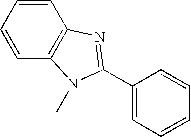 | 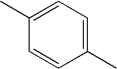 | 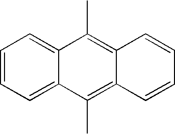 | 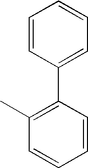 |
| 3 | 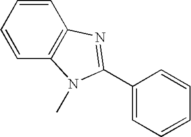 | 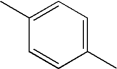 | 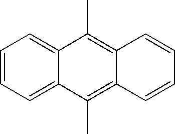 | 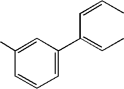 |
| 4 | 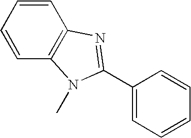 | 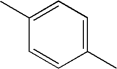 | 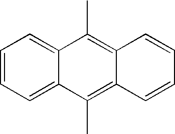 | 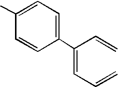 |
| 5 | 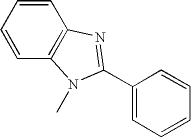 | 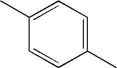 | 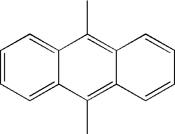 | 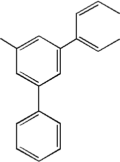 |
| 6 | 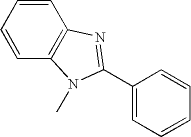 | 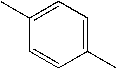 | 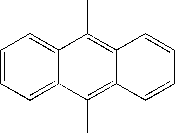 | 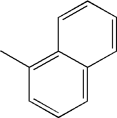 |
| 7 | 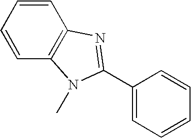 | 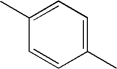 | 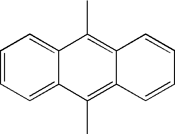 | 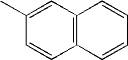 |
| 8 | 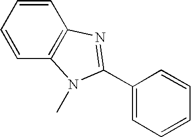 | 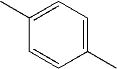 | 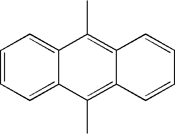 | 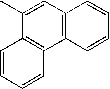 |
| 9 | 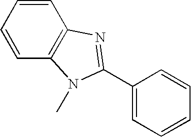 | 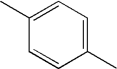 | 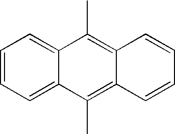 | 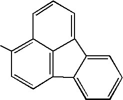 |
| 10 | 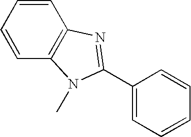 | 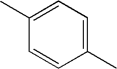 | 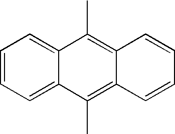 | 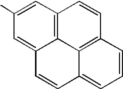 |
| 11 | 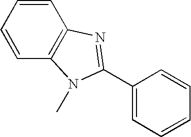 | 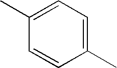 | 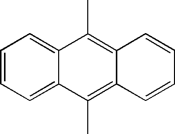 | 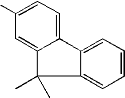 |
| 12 | 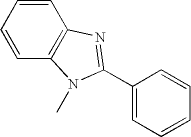 | 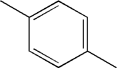 | 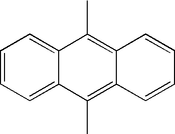 | 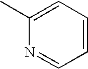 |
| 13 | 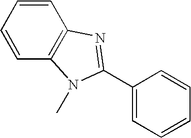 | 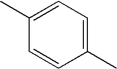 | 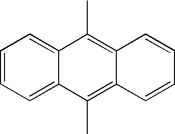 | 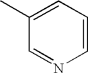 |
| 14 | 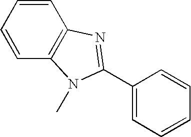 | 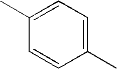 | 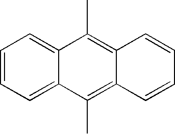 | 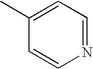 |
| 10-1 | 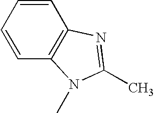 | 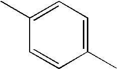 | 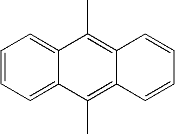 | 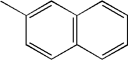 |
| 2 | 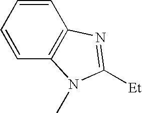 | 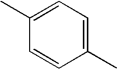 | 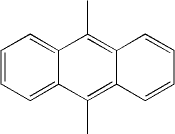 | 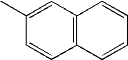 |
| 3 | 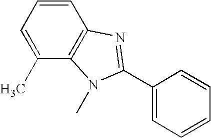 | 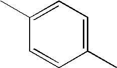 | 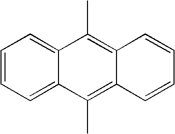 | 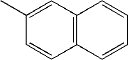 |
| 4 | 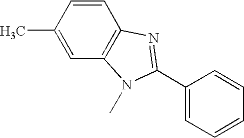 | 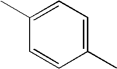 | 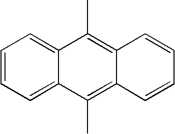 | 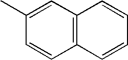 |
| 5 | 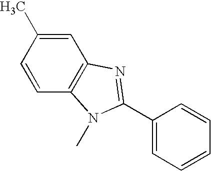 | 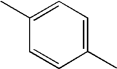 | 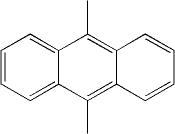 | 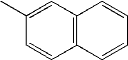 |
| 6 | 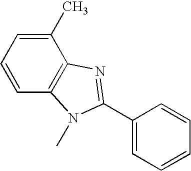 | 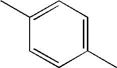 | 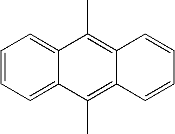 | 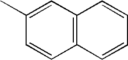 |
| 7 | 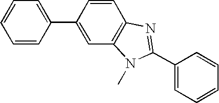 | 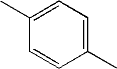 | 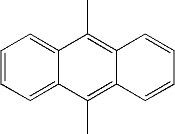 | 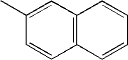 |
| 8 | 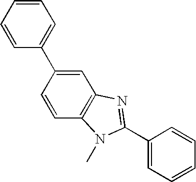 | 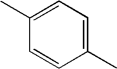 | 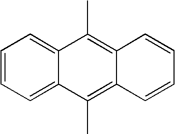 | 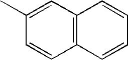 |
| 9 | 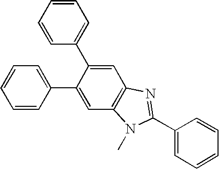 | 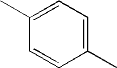 | 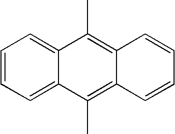 | 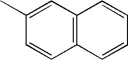 |
| 11-1 | 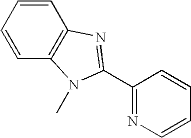 | 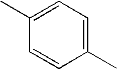 | 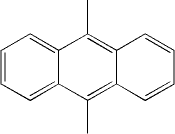 | 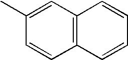 |
| 2 | 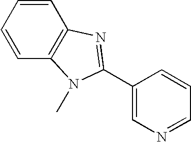 | 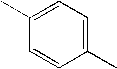 | 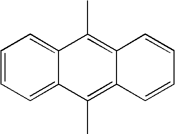 | 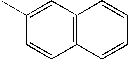 |
| 3 | 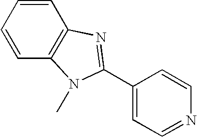 | 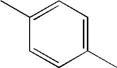 | 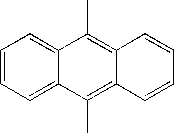 | 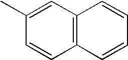 |
| 4 | 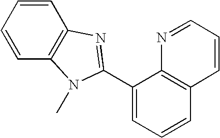 | 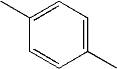 | 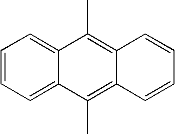 | 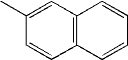 |
| 5 | 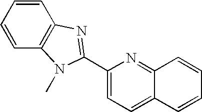 | 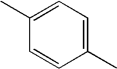 | 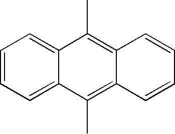 | 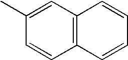 |
| 6 | 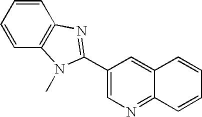 | 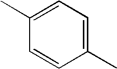 | 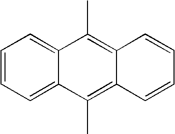 | 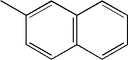 |
| 12-1 | 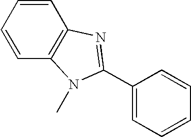 | 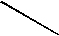 | 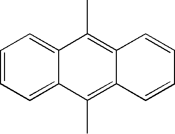 | 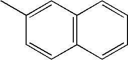 |
| 2 | 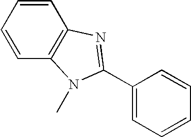 | 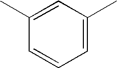 | 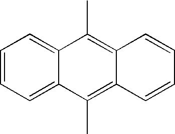 | 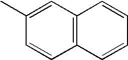 |
| 3 | 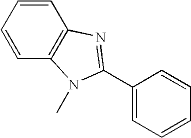 | 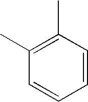 | 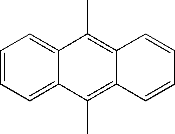 | 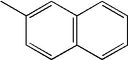 |
| 4 | 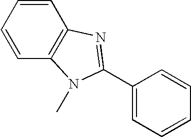 | 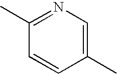 | 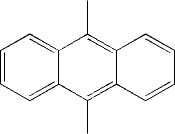 | 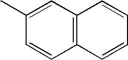 |
| 5 | 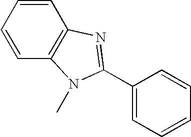 | 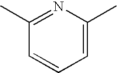 | 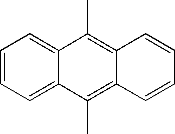 | 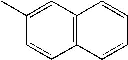 |
| 6 | 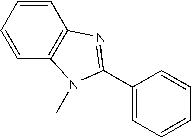 | 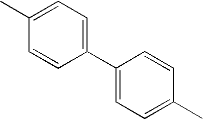 | 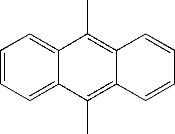 | 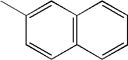 |
| 7 | 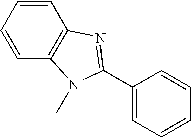 | 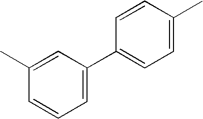 | 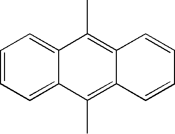 | 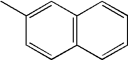 |
| 8 | 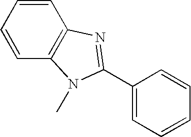 | 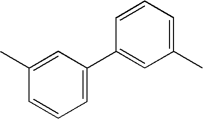 | 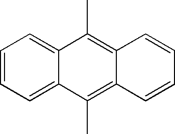 | 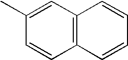 |
| 9 | 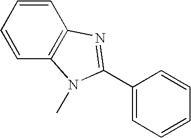 | 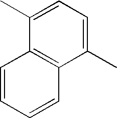 | 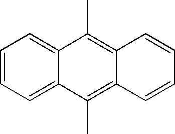 | 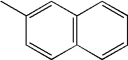 |
| 10 | 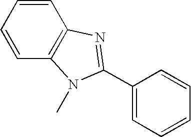 | 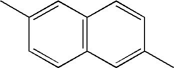 | 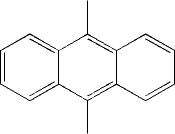 | 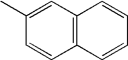 |
| 11 | 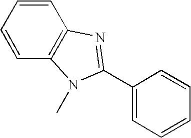 | 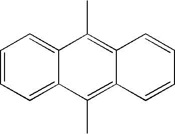 | 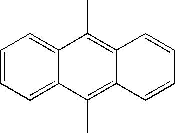 | 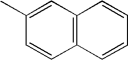 |
| 13-1 | 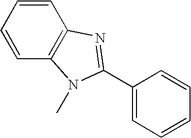 | 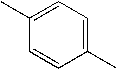 | 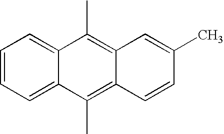 | 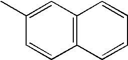 |
| 2 | 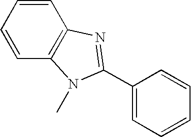 | 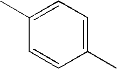 | 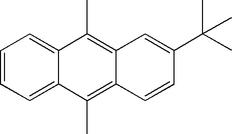 | 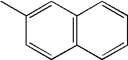 |
| 3 | 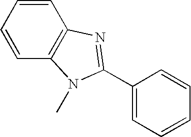 | 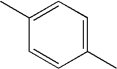 | 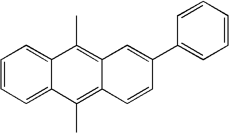 | 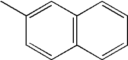 |
| 4 | 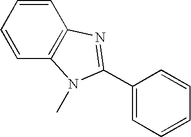 | 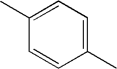 | 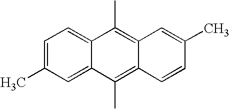 | 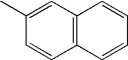 |
| 5 | 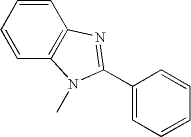 | 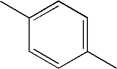 | 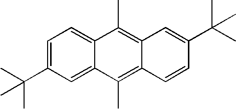 | 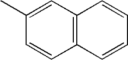 |
| 6 | 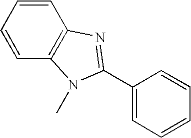 | 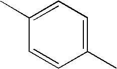 | 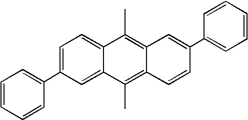 | 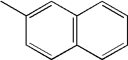 |
| 14-1 | 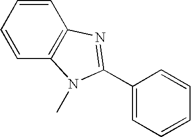 | 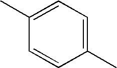 | 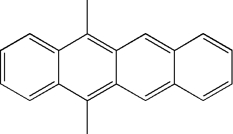 | 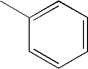 |
| 2 | 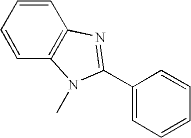 | 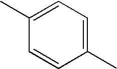 | 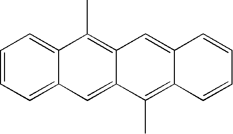 | 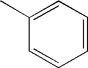 |
| 3 | 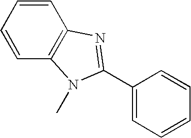 | 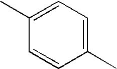 | 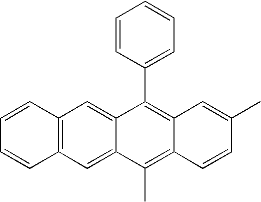 | 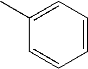 |
| 4 | 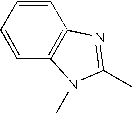 | 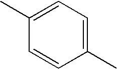 | 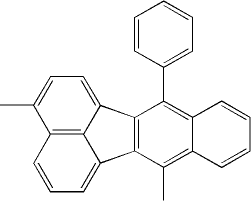 | 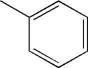 |
| 5 | 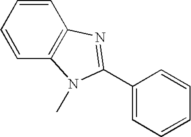 | 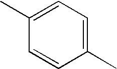 | 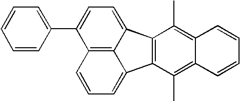 | 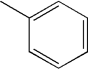 |
| 15-1 | 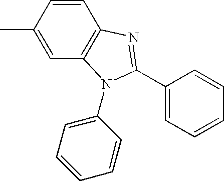 | 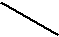 | 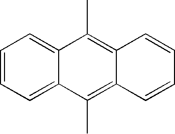 | 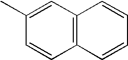 |
| 2 | 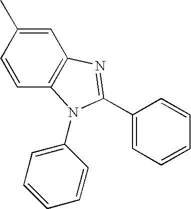 | 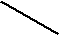 | 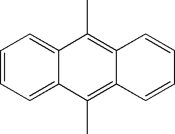 | 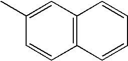 |
| 3 | 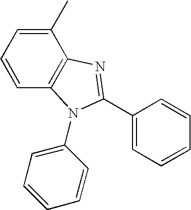 | 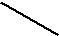 | 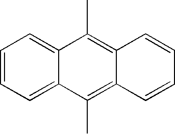 | 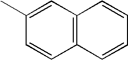 |
| 4 | 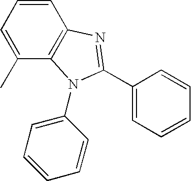 | 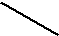 | 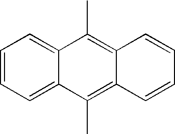 | 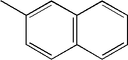 |
| 5 | 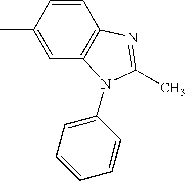 | 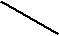 | 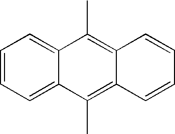 | 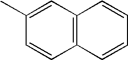 |
| 6 | 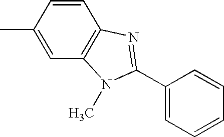 | 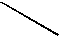 | 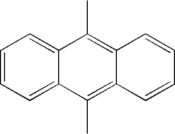 | 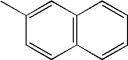 |
| 7 | 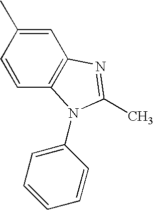 | 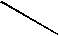 | 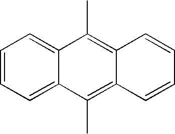 | 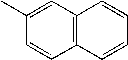 |
| 8 | 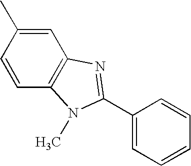 | 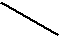 | 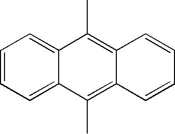 | 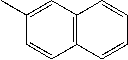 |
| 9 | 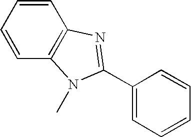 | 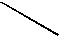 | 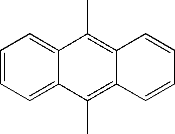 | 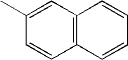 |
| 10 | 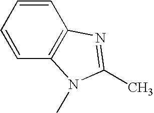 | 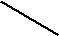 | 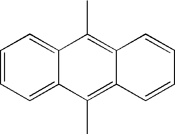 | 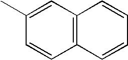 |
| 16-1 | 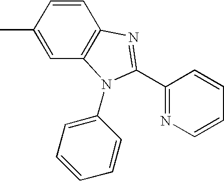 | 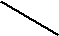 | 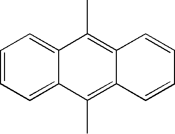 | 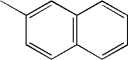 |
| 2 | 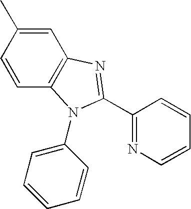 | 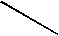 | 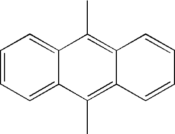 | 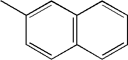 |
| 3 | 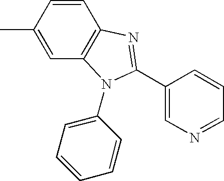 | 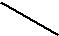 | 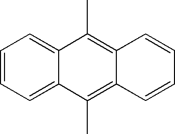 | 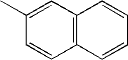 |
| 4 | 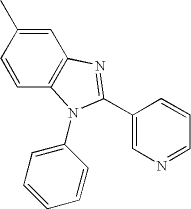 | 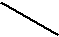 | 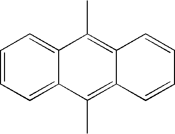 | 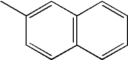 |
| 5 | 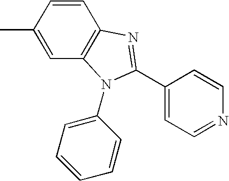 | 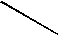 | 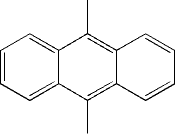 | 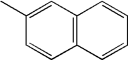 |
| 6 | 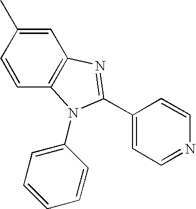 | 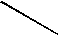 | 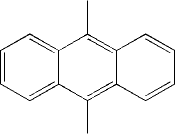 | 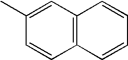 |
| 7 | 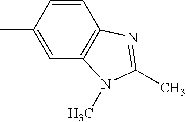 | 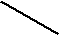 | 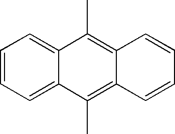 | 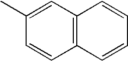 |
| 8 | 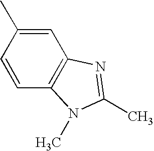 | 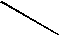 | 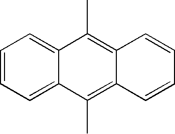 | 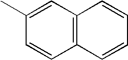 |
| 17-1 | 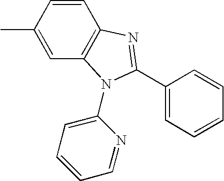 | 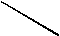 | 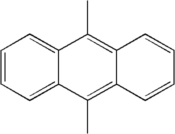 | 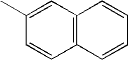 |
| 2 | 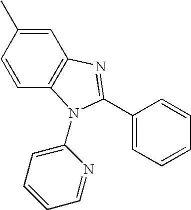 | 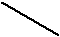 | 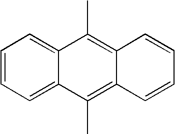 | 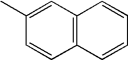 |
| 3 | 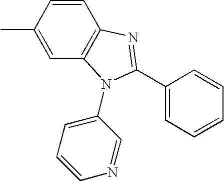 | 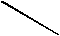 | 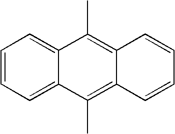 | 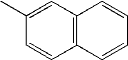 |
| 4 | 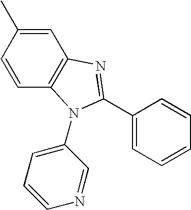 | 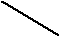 | 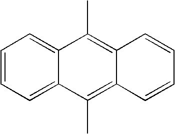 | 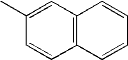 |
| 5 | 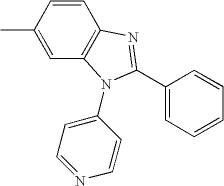 | 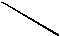 | 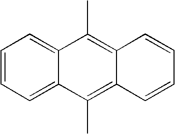 | 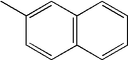 |
| 6 | 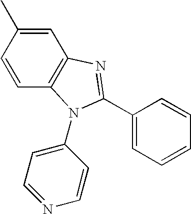 | 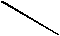 | 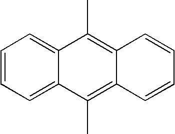 | 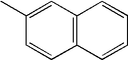 |
| 7 | 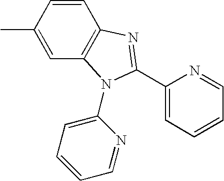 | 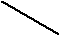 | 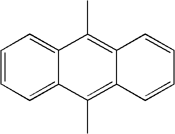 | 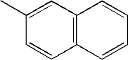 |
| 8 | 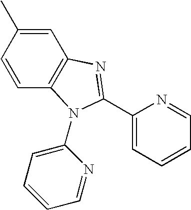 | 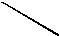 | 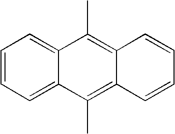 | 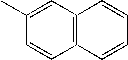 |

Among the above examples, examples (1-1), (1-5), (1-7), (2-1), (3-1), (4-2), (4-6), (7-2), (7-7), (7-8), (7-9) and (9-7) are particularly preferred.

As a preferred embodiment of the organic electroluminescence device, there is known a device containing a reductive dopant at a boundary between a region transporting the electron or the cathode and an organic layer. Here, the reductive dopant is defined as a substance capable of reducing an electron transporting compound. Thus, various substances having a certain level of reducibility can be used, preferable examples of which are at least one substance selected from a group consisting of: alkali metal, an oxide of the alkali metal, a halogenide of the alkali metal, an organic complex of the alkali metal, alkali earth metal, an oxide of the alkali earth metal, a halogenide of the alkali earth metal, an organic complex of the alkali earth metal, rare earth metal, an oxide of the rare earth metal, a halogenide of the rare earth metal and an organic complex of the rare earth metal.

Specifically, reductive dopant is preferably a substance(s) having the work function of 2.9 eV or lower, which is exemplified by at least one alkali metal selected from a group consisting of Li (work function: 2.9 eV), Na (work function: 2.36 eV), K (work function: 2.28 eV), Rb (work function: 2.16 eV) and Cs (work function: 1.95 eV) or at least one alkali earth metal selected from a group consisting of Ca (work function: 2.9 eV), Sr (work function: 2 to 2.5 eV) and Ba (work function: 2.52 eV), and the substances having the work function of 2.9 eV or lower are particularly preferable. Among these, more preferable reductive dopant is at least one alkali metal selected from a group consisting of K, Rb and Cs, in which Rb and Cs are even more preferable and Cs is the most preferable. These alkali metals have particularly high reducibility, so that addition of a relatively small amount of these alkali metals to an electron injecting zone can enhance luminescence intensity and lifecycle of the organic electroluminescence device. In addition, as the reductive dopant having the work function of 2.9 eV or lower, a combination of two or more of these alkali metals is also preferable, and a combination including Cs is particularly preferable (e.g. combinations of Cs and Na, Cs and K, Cs and Rb or Cs, Na and K). The combinations including Cs can effectively exert the reducibility, so that the addition of such reductive dopant to the electron injecting zone can enhance the luminescence intensity and the lifecycle of the organic electroluminescence device.

An electron injecting layer formed from an insulator or a semiconductor may be provided between the cathode and the organic layer. With the arrangement, leak of electric current can be effectively prevented and the electron injecting capability can be enhanced. As the insulator, it is preferable to use at least one metal compound selected from a group consisting of an alkali metal chalcogenide, an alkali earth metal chalcogenide, a halogenide of alkali metal and a halogenide of alkali earth metal. By forming the electron injecting layer from the alkali metal chalcogenide or the like, the electron injecting capability can preferably be further enhanced. Specifically, preferable examples of the alkali metal chalcogenide are Li₂O, K₂O, Na₂S, Na₂Se and Na₂O, while preferable example of the alkali earth metal chalcogenide are CaO, BaO, SrO, BeO, BaS and CaSe. Preferable examples of the halogenide of the alkali metal are LiF, NaF, KF, LiCl, KCl and NaCl. Preferable examples of the halogenide of the alkali earth metal are fluorides such as CaF₂, BaF₂, SrF₂, MgF₂ and BeF₂, and halogenides other than the fluoride.

Examples of the semiconductor for forming the electron transporting layer are one of or a combination of two or more of an oxide, a nitride or an oxidized nitride containing at least one element selected from a group consisting of Ba, Ca, Sr, Yb, Al, Ga, In, Li, Na, Cd, Mg, Si, Ta, Sb and Zn. An inorganic compound for forming the electron transporting layer is preferably a microcrystalline or amorphous semiconductor film. When the electron transporting layer is formed of such semiconductor film, more uniform thin film can be formed, thereby reducing pixel defects such as a dark spot. Examples of such an inorganic compound are the above-described alkali metal chalcogenide, alkali earth metal chalcogenide, halogenide of the alkali metal and halogenide of the alkali earth metal.

### (7) Cathode

In order to inject the electrons into the electron injecting/transporting layer or the emitting layer, a material whose work function is small (4 eV or lower) is used as an electrode material for the cathode, examples of the material being metals, alloys, electrically conductive compounds and mixtures thereof. Examples of the electrode material are sodium, a sodium-potassium alloy, magnesium, lithium, a magnesium-silver alloy, aluminium/aluminium oxide, an aluminium-lithium alloy, indium, rare earth metal and the like.

The cathode may be made by forming a thin film from the electrode material by vapor deposition and sputtering.

When luminescence from the emitting layer is provided through the cathode, the cathode preferably transmits more than 10% of the luminescence.

The sheet resistance as the cathode is preferably several hundreds Ω/square or lower, and the thickness of the film is typically in a range from 10 nm to 1 μm, preferably 50 to 200 nm.

### (8) Insulating Layer

Since the electrical field is applied to ultra thin films in the organic electroluminescence device, pixel defects resulted from leak or short circuit are likely to occur. In order to prevent such defects, it is preferable to interpose an insulating thin film layer between a pair of electrodes.

Examples of a material used for the insulating layer are aluminum oxide, lithium fluoride, lithium oxide, cesium fluoride, cesium oxide, magnesium oxide, magnesium fluoride, calcium oxide, calcium fluoride, aluminium nitride, titanium oxide, silicon oxide, germanium oxide, silicon nitride, boron nitride, molybdenum oxide, ruthenium oxide, vanadium oxide and the like.

Mixtures or laminates thereof may also be used.

### (9) Manufacturing Method of Organic Electroluminescence Device

The organic electroluminescence device can be manufactured by forming the anode, the emitting layer, the hole injecting layer (as necessary), the electron injecting layer (as necessary) and the cathode form the materials listed above by the above-described formation methods. The organic electroluminescence device can also be manufactured by forming the above elements in the inverse order of the above, namely from the cathode to the anode.

The following is an example of a manufacturing method of the organic electroluminescence device in which the anode, the hole injecting layer, the emitting layer, the electron injecting layer and the cathode are sequentially formed on the light-transmissive substrate.

A thin film is formed of the anode material on a suitable light-transmissive substrate by vapor deposition or sputtering such that the thickness of the thin film is 1 μm or smaller, preferably in a range from 10 nm to 200 nm, thereby forming the anode.

Then, the hole injecting layer is formed on the formed anode.

The hole injecting layer can be formed by vacuum deposition, spin coating, casting method, LB method or the like. The thickness of the hole injecting layer is suitably determined within a range of 5 nm to 5 μm.

Then, the emitting layer is formed on the hole injecting layer by forming a thin film from an organic luminescent material by a dry process represented by the vacuum deposition or a wet process such as spin coating and casting method.

Then, the electron injecting layer is formed on the emitting layer.

The electron injecting layer may be exemplarily formed by vacuum deposition.

Lastly, the cathode is laminated on the electron injecting layer, whereby the organic electroluminescence device can be obtained.

The cathode can be formed from a metal by a method such as vapor deposition and sputtering.

In order to protect the organic layers deposited under the cathode from being damaged, the vacuum deposition is preferable.

The methods for forming each of the layers in the organic electroluminescence device are not particularly limited.

Conventional methods such as vacuum deposition and spin coating can be employed for forming the organic film layers. Specifically, the organic film layers may be formed by a conventional coating method such as vacuum deposition, molecular beam epitaxy (MBE method) and coating methods using a solution such as a dipping, spin coating, casting, bar coating, roll coating and ink jet printing.

Although the thickness of each organic layer of the organic electroluminescence device is not particularly limited, the thickness is generally preferably in a range of several nanometers to 1 μm because excessively-thinned film likely entails defects such as a pin hole while excessively-thickened film requires high voltage to be applied and deteriorates efficiency.

When a direct current is applied to the organic electroluminescence device, the luminescence can be observed by applying a voltage of 5 to 40V with the anode having the positive polarity and the cathode having the negative polarity. When the voltage is applied with the inversed polarity, no current flows, so that the luminescence is not generated. When an alternating current is applied, the uniform luminescence can be observed only when the anode has the positive polarity and the cathode has the negative polarity. A waveform of the alternating current to be applied may be suitably selected.

### EXAMPLE

Example(s) of the present invention will be described.

### (Measurement of Electron Mobility)

Electron mobility was measured with a time-of-flight measuring machine TOF-401 manufactured by Sumitomo Heavy Industries Advanced Machinery.

Using a translucent metal electrode (Al: 10 nm) as the anode while using a transparent oxide electrode (ITO: 130 nm) as the cathode, a sample was laminated on the machine by 3 μm so as to measure the mobility. The ITO substrate used as the cathode was cleaned in the same manner as in later-described Example 1. In addition, each material was laminated by vapor deposition as in Example 1.

The sample was set on a sample chamber of the time-of-flight measuring machine TOF-401, and the sample was connected to the anode and the cathode both by a gold-coated probe. Signal current was detected by observing terminal voltages of parallely-connected load resistors with an oscilloscope.

Observation of the signal current is conducted simultaneously with irradiation of laser beam. The current is decreased after some time has lapsed. The decrease in the current means that a sheet of electrons has reached the anode. The inflection time (movement time) is represented by t_{T}.

Electron mobility μₑ is defined as in a following formula.

μₑ=d/t_{T}×E

In the formula, “d” represents a film thickness of the sample while E represents an electric field intensity.

In general, the electron mobility depends on the electric field intensity. When the mobility is plotted with the square root of the electric field intensity, a linear shape is frequently observed. Accordingly, when the mobility is defined as a numeric value, conditions of the electric field intensity should be specified when the mobility is measured. A value when the electric field intensity was 2.5×10⁵ (V/cm) was used as the value of the mobility (cm²/Vs) herein.

### (Manufacturing of Hole Injecting Material)

40 g of a poly(3,4-ethylenedioxythiophene)/polystyrene sulfonate solution with a concentration of 1.32% (manufactured by H.C. StarckGmbH, product name: Baytron™ P, TPAI4083, in which a mass ratio of PEDOT to PSS was 1:6) was mixed with 9.96 g of a solution prepared by dissolving Nafion™ in a mixture of lower aliphatic alcohol and water with a concentration of 5.30 mass % (a solution in which Nafion™ perfluorinated ion-exchange resin was dissolved in a mixture of lower aliphatic alcohol/H₂O with a concentration of 5 mass %, CAS-No. 66796-30-3, Aldrich order No. 27, 470-4, a verified solid content of 5.30 mass %). The mass ratio between PEDOT, PSS and Nafion™ was 1:6:7.

### Example 1

A glass substrate (size: 25 mm×75 mm×1.1 mm thick) having an ITO transparent electrode (manufactured by Geomatics) was ultrasonic-cleaned in isopropyl alcohol for five minutes, and then UV/ozone-cleaned for 30 minutes.

A mixture of PEDOT and Nafion™ prepared as described above was applied on the substrate by spin coating to form a film of 50 nm. The layer serves as the hole injecting layer.

N,N,N′,N′-tetra(4-biphenyl)-diamine biphenylene (hereinafter called, “TBDB layer”) was deposited on the layer by vacuum deposition to form a film of 20 nm. The layer serves as the hole transporting layer.

Then, the compounds AN-1 and BD-1 (mass ratio of AN-1 to BD-1 was 20:1) were simultaneously deposited thereon to form an emitting layer of 40 nm thickness.

An electron transporting material (ET-1, electron mobility: 1.1×10⁻⁴ cm²/Vs, hereinafter abbreviated as “ET film”) was deposited on the film to form a film of 20 nm thickness. The ET film serves as the electron transporting layer.

Subsequently, LiF was deposited thereon to form a film of 1 nm thickness, such that 150 nm thick Al was deposited on the LiF film to form a metal cathode, thereby providing an organic electroluminescence device. Luminous efficiency, voltage and chromaticity at 10 mA/cm² of the obtained organic electroluminescence device were measured. In addition, a room temperature when the initial luminescence intensity was 5000 cd/m² and time elapsed until a half-life of the luminescence intensity when the device was driven by DC constant current were measured.

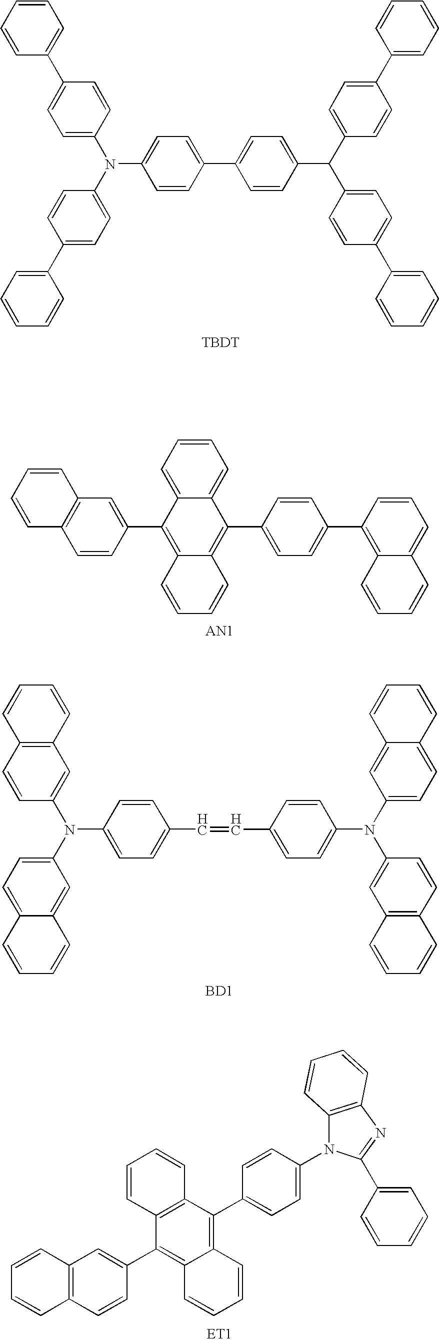

### (Comparative 1)

In place of the mixture of PEDOT and Nafion™ described in the above Example 1, copper phthalocyanine (CuPc) was deposited to form a film of 100 nm, and in place of the electron transporting material (ET), an aluminum quinolinol complex (Alq3, electron mobility: 5×10⁻⁶ cm²/Vs) was deposited to form a film of 20 nm.

### (Comparative 2)

In place of the electron transporting material (ET-1) described in the above Example 1, an aluminum quinolinol complex (Alq3) was deposited to form a film of 20 nm.

### (Comparative 3)

In place of the mixture of PEDOT and Nafion described in the above Example 1, copper phthalocyanine (CuPc) was deposited to form a film of 50 nm.

### (Comparative 4)

In place of the mixture of PEDOT and Nafion™ described in the above Example 1, PEDOT-PSS was deposited to form a film of 50 nm.

### (Comparative 5)

In place of the compounds AN-1 and BD-1 described in the above Example 1, compounds RH and RD as follows (weight ratio of RH:RD=40:0.4) were deposited to form an emitting layer of 40 nm thickness.

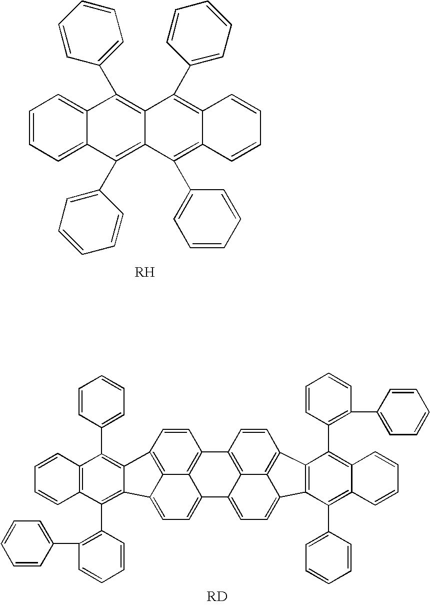

### (Comparative 6)

In place of the mixture of REDOT and Nafion™ described in the above Example 1, PEDOT-PSS was deposited to form a film of 50 nm, and in place of the compounds AN-1 and BD-1, the compounds RH and RD (weight ratio of RH:RD=40:0.4) were deposited to form an emitting layer of 40 nm thickness.

Evaluation results of the Example 1 and Comparatives 1 to 6 are shown in Table 1.

Table 1

| | | | Electron | | | | |
|---|---|---|---|---|---|---|---|
| | Hole Injecting | Emitting | Transporting | Voltage | Efficiency | Chromaticity | Lifetime |
| | Layer | Layer | Layer | (V) | (cd/A) | (x, y) | (h) |
| Example 1 | PEDOT:PSS: | AN-1:BD-1 | ET1 | 5.5 | 6.0 | (0.14, 0.18) | 500 |
| | Nafion ™ | | | | | | |
| Comparative 1 | CuPc | AN-1:BD-1 | Alq | 8.0 | 4.4 | (0.14, 0.17) | 300 |
| Comparative 2 | PEDOT:PSS: | AN-1:BD-1 | Alq | 6.5 | 4.8 | (0.14, 0.20) | 300 |
| | Nafion ™ | | | | | | |
| Comparative 3 | CuPc | AN-1:BD-1 | ET1 | 6.0 | 4.9 | (0.14, 0.17) | 100 |
| Comparative 4 | PEDOT:PSS | AN-1:BD-1 | ET1 | 5.9 | 4.6 | (0.14, 0.18) | 350 |
| Comparative 5 | PEDOT:PSS: | RH:RD | Alq | 4.9 | 7.4 | (0.65, 0.35) | |
| | Nafion ™ | | | | | | |
| Comparative 6 | PEDOT:PSS | RH:RD | Alq | 5.1 | 6.9 | (0.64, 0.35) | |

As is understood from Table 1, the blue-emitting organic electroluminescence device of Example 1 is much more excellent in driving voltage, luminous efficiency, chromatic purity and lifetime than the blue-emitting organic electroluminescence devices of Comparatives 1 to 4 arranged in the same manner as a conventional device.

In contrast, although the organic electroluminescence device of Comparative 1 exhibits the chromaticity of almost the same level as that of Example 1, the driving voltage required by Comparative 1 is high because its hole injecting layer is CuPc. In addition, since its electron transporting layer is made of an Alq complex whose electron mobility is low, Comparative 1 is inferior in luminous efficiency and lifetime.

The organic electroluminescence device of Comparative 2 requires lower driving voltage than that of Comparative 1 because its hole injecting layer uses the mixture of PEDOT and Nafion™ as in Example 1. However, since its electron transporting layer is an Alq complex whose electron mobility is low, the emitting region in the emitting layer is shifted toward the cathode. Thus, the value of chromaticity y-coordinate of Comparative 2 is large, and luminous efficiency and lifetime of Comparative 2 are inferior.

The organic electroluminescence device of Comparative 3 requires a lower driving voltage than that of Comparative 1 because its electron transporting layer is formed of ET1. However, since its hole injecting layer is CuPc, Comparative 3 exhibits much shorter lifetime.

In the organic electroluminescence device of Comparative 4, the hole injecting layer only contains the mixture of PEDOT and PSS and does not contain Nafion™. Nafion™, which is a perfluorinated polymer, contains a lot of fluorine. Thus, a hole injecting layer containing Nafion™ exhibits lower refractivity. Example 1, where the hole injecting layer containing Nafion™ was used, employs a structure of a high reflectivity layer (emitting layer+hole transporting layer)/a low reflectivity layer (hole injecting layer)/a high reflectivity layer (ITO), thereby increasing optical interference modes and enhancing light-extraction efficiency of blue-emitting wavelength. As a consequence, luminous efficiency is enhanced. On the other hand, Comparative 4, where the hole injecting layer does not contain Nafion™, hardly produces the above effects, thereby exhibiting lower luminous efficiency.

Comparatives 5 and 6 show a difference between the hole injecting layers with and without Nafion™ in a red-emitting organic electroluminescence device. Compared as the luminous efficiency of Comparative 6 that does not contain Nafion™, Comparative 5 containing Nafion™ exhibits merely slightly-improved luminous efficiency. Materials used for the emitting layer and the hole transporting layer (i.e., low-molecular material), which generally exhibits high reflectivity in a blue short-wavelength region, exhibits lower and lower reflectivity as the wavelength becomes longer than the blue region. The transparent conductive material used for anode exhibits a similar tendency. On the other hand, reflectivity of polymer materials for hole injecting used in Example 1 and Comparatives 2 to 6 is less dependant on the wavelength. Accordingly, a reflectivity difference between the emitting layer, the hole transporting layer and ITO and the hole injecting layer in the red-emitting wavelength region is smaller than the reflectivity difference in the blue-emitting wavelength region, such that the light-extraction efficiency is less improved. Thus, the presence of Nafion is less effective on such a red-emitting device.

The priority application Number JP2007-050857 upon which this patent application is based is hereby incorporated by reference.

What is claimed is:

1. An organic electroluminescence device, comprising an anode, a hole injecting layer, an emitting layer, an electron transporting layer and a cathode in this order, wherein
the hole injecting layer comprises: substituted or unsubstituted poly(alkylene dioxythiophene); and a fluorine-containing colloid-forming polymer acid, and
the electron transporting layer comprises a compound having electron mobility of 1.0×10⁻⁴ cm²/Vs or more at an electric field intensity of 2.5×10⁵V/cm.

2. The organic electroluminescence device according to claim 1, wherein the electron transporting layer comprises a nitrogen-containing heterocycle derivative represented by a formula (1) as follows,
HAr-L-Ar¹—Ar² (1)
(where: HAr represents a substituted or unsubstituted nitrogen-containing heterocycle group having 3 to 40 carbon atoms;
L represents a single bond, a substituted or unsubstituted arylene group having 6 to 60 carbon atoms, a substituted or unsubstituted heteroarylene group having 3 to 60 carbon atoms, or a substituted or unsubstituted fluorenylene group;
Ar¹ represents a substituted or unsubstituted divalent aromatic hydrocarbon group having 6 to 60 carbon atoms; and
Ar² represents a substituted or unsubstituted aryl group having 3 to 60 carbon atoms.)

3. The organic electroluminescence device according to claim 1, wherein
the emitting layer comprises a host and a dopant, and
the host is formed of a material having a molecular weight of 4000 or less.

4. The organic electroluminescence device according to claim 3, wherein the host comprises a condensed-ring compound having at least three rings.

5. The organic electroluminescence device according to claim 4, wherein the condensed-ring compound having at least three rings is an anthracene derivative.

6. The organic electroluminescence device according to claim 5, wherein the anthracene derivative is represented by a formula (2) as follows, 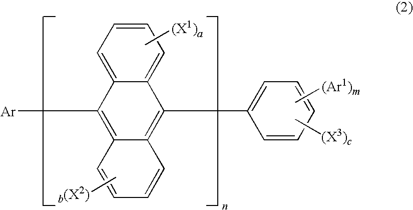
(where: Ar represents a substituted or unsubstituted condensed aromatic group having 10 to 50 carbon atoms forming the aromatic ring;
Ar′ represents a substituted or unsubstituted aromatic group having 6 to 50 carbon atoms forming the aromatic ring;
X¹ to X³ each represent a substituted or unsubstituted aromatic group having 6 to 50 carbon atoms forming the aromatic ring, a substituted or unsubstituted aromatic heterocyclic group having 5 to 50 carbon atoms forming the aromatic ring, a substituted or unsubstituted alkyl group having 1 to 50 carbon atoms, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 carbon atoms, a substituted or unsubstituted arylthio group having 5 to 50 carbon atoms, a substituted or unsubstituted alkoxycarbonyl group having 1 to 50 carbon atoms, a carboxyl group, a halogen group, a cyano group, a nitro group and a hydroxyl group;
a, b and c are each an integer in a range of 0 to 4, a plurality of X¹ being mutually the same or different when a is 2 or more, a plurality of X² being mutually the same or different when b is 2 or more, a plurality of X³ being mutually the same or different when c is 2 or more; and
n is an integer in a range of 1 to 3 while m is 0 or 1, a plurality of such structures shown in the brackets [ ] as represented by a formula below being mutually the same or different when n is 2 or more.)

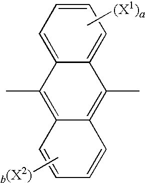

7. The organic electroluminescence device according to claim 5, wherein the anthracene derivative is an asymmetric monoanthracene derivative represented by a formula (3) as follows, 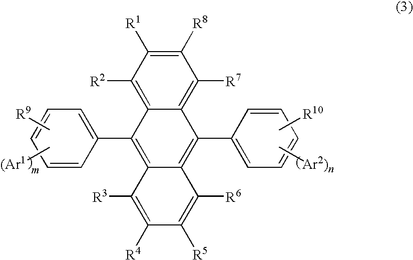
(where: Ar¹ and Ar² are each a substituted or unsubstituted aromatic ring group having 6 to 50 carbon atoms forming the aromatic ring while m and n are each an integer in a range of 1 to 4, Ar¹ and Ar² being mutually different when: m and n are both equal to 1; and positions at which Ar¹ and Ar² are respectively bonded to benzene rings are symmetric, m and n being mutually different when m or n is an integer in a range of 2 to 4; and
R¹ to R¹⁰ are each a hydrogen atom, a substituted or unsubstituted aromatic ring group having 6 to 50 carbon atoms forming the aromatic ring, a substituted or unsubstituted aromatic heterocycle group having 5 to 50 atoms forming the aromatic ring, a substituted or unsubstituted alkyl group having 1 to 50 carbon atoms, a substituted or unsubstituted cycloalkyl group, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 atoms forming the aromatic ring, a substituted or unsubstituted arylthio group having 5 to 50 atoms forming the aromatic ring, a substituted or unsubstituted alkoxycarbonyl group having 1 to 50 carbon atoms, substituted or unsubstituted silyl group, a carboxyl group, a halogen atom, a cyano group, a nitro group and a hydroxy group.)

8. The organic electroluminescence device according to claim 5, wherein the anthracene derivative is represented by a formula (4) as follows, 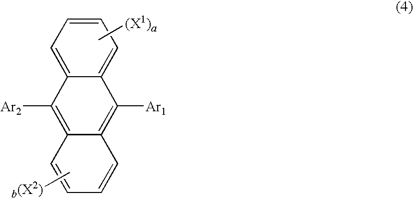
(where: at least either one of Ar¹ and Ar² is a substituent having a substituted or unsubstituted condensed ring group with 10 to 30 carbon atoms forming the aromatic ring;
X¹ and X² are each a substituted or unsubstituted aromatic group having 6 to 50 carbon atoms forming the aromatic ring, a substituted or unsubstituted aromatic heterocycle group having 5 to 50 carbon atoms forming the aromatic ring, a substituted or unsubstituted alkyl group having 1 to 50 carbon atoms, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 carbon atoms, a substituted or unsubstituted arylthio group having 5 to 50 carbon atoms, a substituted or unsubstituted alkoxycarbonyl group having 1 to 50 carbon atoms, a carboxyl group, a halogen group, a cyano group, a nitro group and hydroxyl group; and
a and b are each an integer in a range of 0 to 4, a plurality of X¹ being mutually the same or different when a is 2 or more, a plurality of X² being mutually the same or different when b is 2 or more.)

9. The organic electroluminescence device according to claim 1, wherein the substituted or unsubstituted poly(alkylene dioxythiophene) is poly(3,4-ethylenedioxythiophene).

10. The organic electroluminescence device according to claim 1, wherein the fluorine-containing colloid-forming polymer acid is selected from a group consisting of a fluorine-containing polymer sulfonic acid, a fluorine-containing polymer carboxylic acid, a fluorine-containing polymer phosphoric acid, a fluorine-containing polymer acrylic acid and a mixture of the acids.

11. The organic electroluminescence device according to claim 1, wherein the fluorine-containing colloid-forming polymer acid is a perfluorinated polymer sulfonic acid.
